(19) United States
(12) Patent Application Publication
(10) Pub. No.: US 2026/0293461 A1
(43) Pub. Date: Sep. 24, 2026

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Fei FANG, Beijing (CN); Ling SHI, Beijing (CN); Zhongman ZHAO, Beijing (CN); Zhu WANG, Beijing (CN); Yanyang SHANG, Beijing (CN); Zhenglong YAN, Beijing (CN); Bo PENG, Beijing (CN); Ke LIANG, Beijing (CN)

(21) Appl. No.: 19/474,191

(22) PCT Filed: Oct. 24, 2024
(86) PCT No.: PCT/CN2024/127140

§ 371 Date: Oct. 10, 2025

(30) Foreign Application Priority Data
Nov. 28, 2023 (CN) 202311605913.1

(51) Int. Cl. H10K 59/131; G09G 3/3233; H10K 59/35

(52) U.S. Cl. CPC H10K 59/131; G09G 3/3233; H10K 59/353; G09G 2300/0426; G09G 2300/0819; G09G 2300/0842; G09G 2310/08; G09G 2330/021

(57) ABSTRACT

A display substrate, including: a base, a plurality of sub-pixels and a plurality of first power lines which are located in a display area, and M first voltage supply groups which are located in a first frame area. The plurality of sub-pixels are divided into N sub-pixel groups, wherein each sub-pixel group includes a plurality of sub-pixels emitting light of the same color, different sub-pixel groups are configured to emit light of different colors, and each first power line is connected to a plurality of sub-pixels emitting light of the same color. The M first voltage supply groups are configured to provide different first voltage signals; and each first voltage supply group is configured to provide a first voltage signal for a pixel circuit in at least one sub-pixel group by means of at least one first power line.

### CROSS-REFERENCE TO RELATED APPLICATION

The present application is a U.S. National Phase Entry of International Application No. PCT/CN2024/127140 having an international filing date of Oct. 24, 2024, which claims the priority to Chinese Patent Application No. 202311605913.1, entitled “Display Substrate and Display Apparatus”, filed on Nov. 28, 2023, to the China National Intellectual Property Administration, the contents of which should be regarded as being incorporated herein by reference.

### TECHNICAL FIELD

The present disclosure relates to, but is not limited to, the field of display technologies, in particular to a display substrate and a display apparatus.

### BACKGROUND

An Organic Light Emitting Diode (OLED) and a Quantum dot Light Emitting Diode (QLED) are active light emitting display devices, and have advantages of self-illumination, a wide viewing angle, a high contrast ratio, low power consumption, an extremely high reaction speed, lightness and thinness, flexibility, and a low cost, etc.

### SUMMARY

The following is a summary of subject matters described herein in detail. This summary is not intended to limit the protection scope of claims.

Embodiments of the present disclosure provide a display substrate and a display apparatus.

In one aspect, the present embodiment provides a display substrate including a base substrate, a plurality of sub-pixels, a plurality of first power lines, and M first voltage power supply groups. The base substrate includes a display region and a first bezel region located on a side of the display region. A plurality of sub-pixels and a plurality of first power lines are located in the display region, the plurality of sub-pixels are divided into N sub-pixel groups, each sub-pixel group includes a plurality of sub-pixels emitting light of a same color, and different sub-pixel groups are configured to emit light of different colors. At least one of a plurality of sub-pixels includes: a pixel circuit and a light emitting element connected to a pixel circuit, each first power line is connected to pixel circuits of a plurality of sub-pixels emitting light of the same color. M first voltage power supply groups are located in the first bezel region, the M first voltage power supply groups are configured to provide different first voltage signals. Each first voltage power supply group is configured to provide a first voltage signal to a pixel circuit in at least one sub-pixel group through at least one first power line, wherein M and N are both integers greater than 1, and M is less than or equal to N.

In some exemplary implementations, the first bezel region includes: a first fan-out region and a first signal access region disposed sequentially along a direction away from the display region. Each first voltage power supply group at least includes: at least one first power supply line located in the first fan-out region and at least one first voltage contact pad located in the first signal access region; and the at least one first power supply line is connected to the at least one first voltage contact pad.

In some exemplary implementations, the first bezel region further includes: a second fan-out region and a bend region, the second fan-out region and the bend region are located on a side of the first fan-out region close to the display region, and the bend region is connected to the first fan-out region and the second fan-out region. Each first voltage power supply group further includes: at least one second power supply line located in the second fan-out region, at least one first power supply bend line located in the bend region; the at least one second power supply line is connected to a plurality of first power lines that transmit a same first voltage signal, and the at least one first power supply bend line is connected to the at least one first power supply line and the at least one second power supply line.

In some exemplary implementations, the second power supply line extends at least along a first direction, the first power supply bend line extends at least along a second direction, the first power line extends at least along the second direction, and the first direction intersects with the second direction; the at least one first power supply line is disposed symmetrically with respect to a centerline of the first bezel region along the first direction.

In some exemplary implementations, the second power supply line is connected to a plurality of first power lines through a first-type voltage transfer electrode, and the at least one first power supply bend line is connected to the second power supply line and the plurality of first power lines through a second-type voltage transfer electrode; wherein the first-type voltage transfer electrode and the second-type voltage transfer electrode are in the same layer.

In some exemplary implementations, a distance between orthographic projections of the first power supply lines of at least two of the M first voltage power supply groups is greater than 0, and the first power supply lines include at least two lines connected to each other.

In some exemplary implementations, in a direction perpendicular to a display substrate, the display substrate includes: a first semiconductor layer, a first gate metal layer, a second gate metal layer, a second semiconductor layer, a third gate metal layer, a first source-drain metal layer, a second source-drain metal layer, and a third source-drain metal layer disposed on the base substrate. The first power supply line of at least one of the M first voltage power supply groups includes lines located on at least two metal layers of the first source-drain metal layer, the second source-drain metal layer, and the third source-drain metal layer.

In some exemplary implementations, the first power supply lines of different first voltage power supply groups are located on different conductive layers, and the orthographic projections of the first power supply lines of at least two first voltage power supply groups on the base substrate partially overlap.

In some exemplary implementations, the line segments of the first power supply lines of the M first voltage power supply groups in the same extending direction have the same width.

In some exemplary implementations, the line segments of first power supply lines of at least two adjacent first voltage power supply groups in the same extension direction have different widths.

In some exemplary implementations, the N sub-pixel groups include: a first sub-pixel group emitting light of a first color, a second sub-pixel group emitting light of a second color, and a third sub-pixel group emitting light of a third color. The M first voltage power supply groups include: a first first voltage power supply group providing a first type of first voltage signal, a second first voltage power supply group providing a second type of first voltage signal, and a third first voltage power supply group providing a third type of first voltage signal. The first first voltage power supply group is configured to provide a first type of first voltage signal to the first sub-pixel group; the second first voltage power supply group is configured to provide a second type of first voltage signal to the second sub-pixel group; and the third first voltage power supply group is configured to provide a third type of first voltage signal to the third sub-pixel group.

In some exemplary implementations, the first color light is blue light, the second color light is red light, and the third color light is green light; the first type of first voltage signal is greater than the second type of first voltage signal, and the second type of first voltage signal is greater than the third type of first voltage signal.

In some exemplary implementations, the display substrate further includes: a bottom shield layer connected to the first first voltage power supply group.

In some exemplary implementations, the first bezel region includes: a first fan-out region and a first signal access region disposed sequentially along a direction away from the display region. Each first voltage power supply group at least includes: at least one first power supply line located in the first fan-out region and at least one first voltage contact pad located in the first signal access region; and the at least one first power supply line is connected to the at least one first voltage contact pad. An average width of the first power supply lines of the first first voltage power supply group is greater than an average width of the first power supply lines of the second first voltage power supply group; and the average width of the first power supply lines of the second first voltage power supply group is greater than an average width of the first power supply lines of the third first voltage power supply group.

In some exemplary implementations, the first bezel region includes: a first fan-out region and a first signal access region disposed sequentially along a direction away from the display region. Each first voltage power supply group at least includes: at least one first power supply line located in the first fan-out region and at least one first voltage contact pad located in the first signal access region; and the at least one first power supply line is connected to the at least one first voltage contact pad. The first power supply line of the first first voltage power supply group, the first power supply line of the second first voltage power supply group, and the first power supply line of the third first voltage power supply group are single-layer lines and their orthographic projections on the base substrate partially overlap.

In some exemplary implementations, in a direction perpendicular to a display substrate, the display substrate includes at least: a first source-drain metal layer, a second source-drain metal layer, and a third source-drain metal layer disposed on the base substrate. The first power supply line of the first first voltage power supply group is located in the first source-drain metal layer, the first power supply line of the second first voltage power supply group is located in the second source-drain metal layer, and the first power supply line of the third first voltage power supply group is located in the third source-drain metal layer.

In some exemplary implementations, the display substrate further includes: L second voltage power supply groups located in the first bezel region, the L second voltage power supply groups are configured to provide different second voltage signals, each second voltage power supply group is configured to provide a second voltage signal to a light emitting element in at least one sub-pixel group, wherein L is an integer greater than 1 and L is less than or equal to N; and the second voltage signal is different from the first voltage signal.

In some exemplary implementations, the N sub-pixel groups include: a first sub-pixel group emitting light of a first color, a second sub-pixel group emitting light of a second color, and a third sub-pixel group emitting light of a third color. The L second voltage power supply groups include: a first second voltage power supply group providing a first type of second voltage signal, a second second voltage power supply group providing a second type of second voltage signal, and a third second voltage power supply group providing a third type of second voltage signal. The first second voltage power supply group is configured to provide a first type of second voltage signal to the first sub-pixel group; the second second voltage power supply group is configured to provide a second type of second voltage signal to the second sub-pixel group; and the third second voltage power supply group is configured to provide a third type of second voltage signal to the third sub-pixel group.

In some exemplary implementations, the first color light is blue light, the second color light is red light, and the third color light is green light; the first type of second voltage signal is less than the second type of second voltage signal, and the second type of second voltage signal is less than the third type of second voltage signal.

In some exemplary implementations, the light emitting element includes an anode and a cathode; the cathodes of the plurality of light emitting elements emitting light of a same color are connected to each other and are connected to a second voltage power supply group through at least a third-type voltage transfer electrode.

In another aspect, an embodiment provides a display apparatus, which includes the aforementioned display substrate.

In another aspect, an embodiment provides a display substrate, including: a base substrate, a plurality of sub-pixels, a plurality of second power lines; and L second voltage power supply groups. The base substrate includes a display region and a first bezel region located on a side of the display region. A plurality of sub-pixels and a plurality of second power lines are located in the display region, the plurality of sub-pixels are divided into N sub-pixel groups, each sub-pixel group includes a plurality of sub-pixels emitting light of a same color, different sub-pixel groups are configured to emit light of different colors. At least one of the plurality of sub-pixels includes: a pixel circuit and a light emitting element connected to the pixel circuit. Each second power line is connected to the light emitting elements of the plurality of sub-pixels emitting light of the same color. L second voltage power supply groups are located in the first bezel region, the L second voltage power supply groups are configured to provide different second voltage signals. Each second voltage power supply group is configured to provide a second voltage signal to a light emitting element in at least one sub-pixel group through at least one second power line; wherein, L and N are both integers greater than 1, and L is less than or equal to N.

In some exemplary implementations, the N sub-pixel groups include: a first sub-pixel group emitting light of a first color, a second sub-pixel group emitting light of a second color, and a third sub-pixel group emitting light of a third color. The L second voltage power supply groups include: a first second voltage power supply group providing a first type of second voltage signal, a second second voltage power supply group providing a second type of second voltage signal, and a third second voltage power supply group providing a third type of second voltage signal. The first second voltage power supply group is configured to provide a first type of second voltage signal to the first sub-pixel group. The second second voltage power supply group is configured to provide a second type of second voltage signal to the second sub-pixel group. The third second voltage power supply group is configured to provide a third type of second voltage signal to the third sub-pixel group.

In some exemplary implementations, the first color light is blue light, the second color light is red light, and the third color light is green light; the first type of second voltage signal is less than the second type of second voltage signal, and the second type of second voltage signal is less than the third type of second voltage signal.

Other aspects of the present disclosure may be comprehended after the drawings and the detailed descriptions are read and understood.

### BRIEF DESCRIPTION OF DRAWINGS

Accompanying drawings are intended to provide an understanding of technical solutions of the present application and constitute a part of the specification, and are used to explain the technical solutions of the present application together with embodiments of the present application, and do not constitute limitations on the technical solutions of the present application.

FIG. 1 is a schematic diagram of a display substrate according to at least one embodiment of the present disclosure.

FIG. 2 is an equivalent circuit diagram of a pixel circuit according to at least one embodiment of the present disclosure.

FIG. 3 is a working timing diagram of a pixel circuit provided in FIG. 2.

FIG. 4 is a schematic diagram of transmission of a first voltage signal according to at least one embodiment of the present disclosure.

FIG. 5 is a schematic diagram of wiring of a first bezel region according to at least one embodiment of the present disclosure.

FIG. 6 is a partially enlarged schematic diagram of C1 region in FIG. 5.

FIG. 7 is a schematic partial view of a display substrate after a shield layer is formed in FIG. 6.

FIG. 8 is a schematic partial view of a display substrate after a first semiconductor layer is formed in FIG. 6.

FIG. 9A is a schematic partial view of a display substrate after a first conductive layer is formed in FIG. 6.

FIG. 9B is a schematic diagram of a first conductive layer in FIG. 9A.

FIG. 10A is a schematic partial view of a display substrate after a second conductive layer is formed in FIG. 6.

FIG. 10B is a schematic diagram of a second conductive layer in FIG. 10A.

FIG. 11 is a schematic partial view of a display substrate after a second semiconductor layer is formed in FIG. 6.

FIG. 12A is a schematic partial view of a display substrate after a third conductive layer is formed in FIG. 6.

FIG. 12B is a schematic diagram of a third conductive layer in FIG. 12A.

FIG. 13 is a schematic partial view of a display substrate after a sixth insulation layer is formed in FIG. 6.

FIG. 14A is a schematic partial view of a display substrate after a fourth conductive layer is formed in FIG. 6.

FIG. 14B is a schematic diagram of a fourth conductive layer in FIG. 14A.

FIG. 15 is a schematic partial view of a display substrate after an eighth insulation layer is formed in FIG. 6.

FIG. 16A is a schematic partial view of a display substrate after a fifth conductive layer is formed in FIG. 6.

FIG. 16B is a schematic diagram of a fifth conductive layer in FIG. 16A.

FIG. 17 is a schematic partial view of a display substrate after a ninth insulation layer is formed in FIG. 6.

FIG. 18A is a schematic partial view of a display substrate after a sixth conductive layer is formed in FIG. 6.

FIG. 18B is a schematic diagram of a sixth conductive layer in FIG. 18A.

FIG. 19 is a schematic diagram of an anode layer in FIG. 6.

FIG. 20A is a partially enlarged schematic diagram of C2 region in FIG. 5.

FIG. 20B is a schematic diagram of a fourth conductive layer in FIG. 20A.

FIG. 20C is a schematic diagram of FIG. 20A after an eighth insulation layer is formed.

FIG. 20D is a schematic diagram of a fifth conductive layer in FIG. 20A.

FIG. 21A is a partially enlarged schematic diagram of C2 region in FIG. 5.

FIG. 21B is a schematic diagram of a fourth conductive layer in FIG. 21A.

FIG. 21C is a schematic diagram of FIG. 21A after an eighth insulation layer is formed.

FIG. 21D is a schematic diagram of a fifth conductive layer in FIG. 21A.

FIG. 22A is a partially enlarged schematic diagram of C2 region in FIG. 5.

FIG. 22B is a schematic diagram of a fourth conductive layer in FIG. 22A.

FIG. 22C is a schematic diagram of FIG. 22A after an eighth insulation layer is formed.

FIG. 22D is a schematic diagram of a fifth conductive layer in FIG. 22A.

FIG. 23A is a partially enlarged schematic diagram of C3 region in FIG. 5.

FIG. 23B is a schematic diagram of a fourth conductive layer in FIG. 23A.

FIG. 23C is a schematic diagram of FIG. 23A after an eighth insulation layer is formed.

FIG. 23D is a schematic diagram of a fifth conductive layer in FIG. 23A.

FIG. 23E is a schematic diagram of FIG. 23A after a ninth insulation layer is formed.

FIG. 23F is a schematic diagram of a sixth conductive layer in FIG. 23A.

FIG. 24A is a partially enlarged schematic diagram of C4 region in FIG. 5.

FIG. 24B is a schematic diagram of a fourth conductive layer in FIG. 24A.

FIG. 24C is a schematic diagram of FIG. 24A after an eighth insulation layer is formed.

FIG. 24D is a schematic diagram of a fifth conductive layer in FIG. 24A.

FIG. 24E is a schematic diagram of a sixth conductive layer in FIG. 24A.

FIG. 25 is a partially enlarged schematic diagram of C5 region in FIG. 24A.

FIG. 26 is another schematic diagram of wiring of a first bezel region according to at least one embodiment of the present disclosure.

FIG. 27 is a partially enlarged schematic diagram of C6 region in FIG. 26.

FIG. 28 is another schematic diagram of wiring of a first bezel region according to at least one embodiment of the present disclosure.

FIG. 29 is a partially enlarged schematic diagram of C7 region in FIG. 28.

FIG. 30A is a partially enlarged schematic diagram of C8 region in FIG. 28.

FIG. 30B is a schematic diagram of a fourth conductive layer and a fifth conductive layer of FIG. 30A.

FIG. 30C is a schematic diagram of a fifth conductive layer in FIG. 30A.

FIG. 31A is a partially enlarged schematic diagram of C9 region in FIG. 28.

FIG. 31B is a schematic diagram of a fourth conductive layer and a fifth conductive layer of FIG. 31A.

FIG. 31C is a schematic diagram of a fifth conductive layer in FIG. 31A.

FIG. 32 is a schematic diagram of transmission of a second voltage signal according to at least one embodiment of the present disclosure.

FIG. 33 is a schematic diagram of wiring of a first bezel region according to at least one embodiment of the present disclosure.

FIG. 34A is a partially enlarged schematic diagram of C10 region in FIG. 33.

FIG. 34B is a schematic diagram of a fourth conductive layer in FIG. 34A.

FIG. 34C is a schematic diagram after a fifth conductive layer is formed in FIG. 34A.

FIG. 34D is a schematic diagram after an anode layer is formed in FIG. 34A.

FIG. 35 is a schematic diagram of a display apparatus according to at least one embodiment of the present disclosure.

### DETAILED DESCRIPTION

The embodiments of the present disclosure will be described below with reference to the drawings in detail. Implementations may be implemented in a plurality of different forms. Those of ordinary skills in the art may easily understand such a fact that modes and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one mode of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third” and the like in the specification are set not to form limits in numbers but only to avoid confusion between constituent elements. In the present disclosure, “plurality” represents two or more than two.

In the specification, for convenience, expressions “central”, “above”, “below”, “front”, “back”, “vertical”, “horizontal”, “top”, “bottom”, “inside”, “outside” and the like for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise specified and defined explicitly, terms “mount”, “mutually connect”, “connect”, and “couple” should be understood in a broad sense. For example, it may be a fixed connection, a detachable connection, or an integral connection; it may be a mechanical connection or a connection; it may be a direct connection, an indirect connection through a middleware, or an internal communication between two elements. Those of ordinary skills in the art may understand meanings of the aforementioned terms in the present disclosure according to situations.

In the specification, an “electrical connection” includes a case that constituent elements are connected together through an element with a certain electrical action. The “element with a certain electrical effect” is not particularly limited as long as electrical signals between the connected constituent elements can be transmitted. Examples of the “element with a certain electrical effect” not only include an electrode and a wiring, but also include a switching element such as a transistor, a resistor, an inductor, a capacitor, and other elements with a plurality of functions, etc.

In the specification, a transistor refers to an element that at least includes three terminals, i.e., a gate electrode, a drain electrode, and a source electrode. The transistor has a channel region between the drain electrode (drain electrode terminal, drain electrode region, or drain electrode) and the source electrode (source electrode terminal, source electrode region, or source electrode), and a current can flow through the drain electrode, the channel region, and the source electrode. In the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification. In addition, the gate electrode may also be referred to as a control electrode.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a circle, oval, triangle, rectangle, trapezoid, pentagon, or hexagon, or the like is not strictly defined, but may be an approximate circle, oval, triangle, rectangle, trapezoid, pentagon, or hexagon, or the like. Some small deformations due to tolerances may exist, for example, chamfers, arc edges, and deformations may exist.

In the present disclosure, “about” and “substantially” means that a boundary is not defined strictly and a case within a range of process and measurement errors is allowed. In the present disclosure, “same” includes completely same and substantially same cases, and “substantially the same” refers to a case where a value differs by less than 10%.

In the specification, “A extends along a B direction” means that A may include a main body portion and a secondary portion connected to the main body portion, the main body portion is a line, a line segment, or a strip-shaped body, the main body portion extends along the B direction, and a length of the main body portion extending along the B direction is greater than a length of the secondary portion extending along another direction. “A extends along B direction” in the specification always means “a main body portion of A extends along B direction”.

In the specification, “A and B are of a same layer structure” and “A and B are disposed in a same layer” means that A and B are formed simultaneously through a same patterning process or that distances between surfaces of A and B close to a base substrate and the base substrate are substantially the same, or that the surfaces of A and B close to the base substrate are in direct contact with a same film layer. A “same layer” does not always mean that thicknesses of layers or heights of layers are the same in a section diagram. A “thickness” of a film layer is a dimension of the film layer in a direction perpendicular to the display substrate. “An orthographic projection of A contains an orthographic projection of B” means that the orthographic projection of B falls within a range of the orthographic projection of A, or the orthographic projection of A covers the orthographic projection of B.

With the development of display technology, how to reduce the power consumption of display substrates becomes a problem that needs to be considered.

The present embodiments provide a display substrate and a display apparatus, which can reduce the overall power consumption of a display substrate.

A present embodiment provides a display substrate including a base substrate, a plurality of sub-pixels, a plurality of first power lines, and M first voltage power supply groups. The base substrate includes a display region and a first bezel region located on a side of the display region. A plurality of sub-pixels and a plurality of first power lines are located in the display region, the plurality of sub-pixels are divided into N sub-pixel groups. Each sub-pixel group includes a plurality of sub-pixels emitting light of a same color, and different sub-pixel groups are configured to emit light of different colors. At least one sub-pixel includes: a pixel circuit and a light emitting element connected to the pixel circuit, each first power line is connected to pixel circuits of a plurality of sub-pixels emitting light of the same color. M first voltage power supply groups are located in the first bezel region, and the M first voltage power supply groups are configured to provide different first voltage signals. Each first voltage power supply group is configured to provide a first voltage signal to a pixel circuit in at least one sub-pixel group through at least one first power line. Wherein, M and N are both integers greater than 1, and M is less than or equal to N.

In some examples, the quantity of sub-pixel groups may be the same as the quantity of the first voltage power supply groups, i.e., M may be equal to N. Each first voltage power supply group may provide a first voltage signal to one sub-pixel group. Wherein, different sub-pixel groups receive different first voltage signals. In other examples, M may be less than N, and the at least one first voltage power supply group may provide a first voltage signal to at least two sub-pixel groups. Wherein, the first voltage signals received by the at least two sub-pixel groups may be the same. For example, one of the M first voltage power supply groups may be configured to provide the same first voltage signal to pixel circuits in two sub-pixel groups. The present embodiment is not limited thereto.

In some examples, each of the M first voltage power supply groups may be configured to provide a first voltage signal different from the remaining first voltage power supply groups. In other words, the M first voltage power supply groups may provide M different first voltage signals. In other examples, at least two of the M first voltage power supply groups may be configured to provide different first voltage signals. For example, the M first voltage power supply groups may be configured to provide M-1 different first voltage signals, two of the M first voltage power supply groups may provide the same first voltage signal, and the remaining first voltage power supply groups may be configured to provide different first voltage signals. The present embodiment is not limited thereto.

In some examples, a plurality of pixel circuits in a sub-pixel group may be connected to a plurality of first power lines, and a first voltage power supply group may be configured to provide a first voltage signal to pixel circuits in the sub-pixel group through the plurality of first power lines. In other examples, a plurality of pixel circuits in a sub-pixel group may be connected to a first power line, and a first voltage power supply group may be configured to provide a first voltage signal to the pixel circuits in the sub-pixel group through a first power line. The present embodiment is not limited thereto.

In some examples, a pixel circuit of a sub-pixel may include at least a drive transistor, a first light emitting control transistor, and a storage capacitor. A first electrode of the first light emitting control transistor may be connected to a first power line, and a second electrode of the first light emitting control transistor may be connected to a first electrode of the drive transistor. A first electrode of the storage capacitor may be connected to a gate of the drive transistor, and a second electrode may be connected to the first power line. A first power line may be electrically connected to a first electrode of a first light emitting control transistor and a second electrode of a storage capacitor of pixel circuits of a plurality of sub-pixels emitting light of the same color.

In the display substrate provided in the present embodiment, by providing first voltage signals to the sub-pixels in groups, different sub-pixel groups in the display region can receive different first voltage signals, which contributes to reducing power consumption of the display substrate.

In some exemplary implementations, the first bezel region may include a first fan-out region and a first signal access region sequentially disposed along a direction away from a display region. Each first voltage power supply group may at least include: at least one first power supply line located in the first fan-out region and at least one first voltage contact pad located in the first signal access region; and the at least one first power supply line is connected to the at least one first voltage contact pad. In some examples, the first bezel region may further include: a second fan-out region and a bend region, the second fan-out region and the bend region may be located on a side of the first fan-out region close to the display region, and the bend region connects the first fan-out region and the second fan-out region. Each first voltage power supply group may further include at least one second power supply line located in the second fan-out region and at least one first power supply bend line located in the bend region. At least one second power supply line is connected to a plurality of first power lines that transmit a same first voltage signal, and at least one first power supply bend line is connected to at least one first power supply line and at least one second power supply line. In this example, the wiring arrangement of a first voltage power supply group may be configured according to the structure of a first bezel region, which is beneficial to the wiring spatial arrangement.

In some exemplary embodiments, a second power supply line may extend at least in a first direction, a first power supply bend line may extend at least in a second direction, and a first power line may extend at least in the second direction, wherein, the first direction intersects with the second direction. At least one first power supply line may be disposed symmetrically with respect to a centerline of a first bezel region along the first direction. The wiring arrangement of this example can advantageously save the arrangement space

In some exemplary implementations, a second power supply line may be connected to a plurality of first power lines through a first-type voltage transfer electrode, and at least one first power supply bend line may be connected to the second power supply line and the plurality of first power lines through a second-type voltage transfer electrode; wherein the first-type voltage transfer electrode and the second-type voltage transfer electrode may be in the same layer. In this example, the wiring connection mode of the first voltage power supply group can advantageously save the arrangement space and facilitate the uniformed design of the film pattern.

In some exemplary embodiments, a distance between the orthographic projections of first power supply lines of at least two of the M first voltage power supply groups on the base substrate may be greater than 0, in other words, the orthographic projections of first power supply lines of at least two first voltage power supply groups on the base substrate may not overlap. The first power supply line may include at least two lines connected to each other. For example, the first power supply line may have a double-layer wiring structure or a three-layer wiring structure. For example, in a direction perpendicular to the display substrate, the display substrate may include: a first semiconductor layer, a first gate metal layer, a second gate metal layer, a second semiconductor layer, a third gate metal layer, a first source-drain metal layer, a second source-drain metal layer, and a third source-drain metal layer disposed on the base substrate. A first power supply line of at least one first voltage power supply group may include sub-lines located in at least two metal layers of the first source-drain metal layer, the second source-drain metal layer, and the third source-drain metal layer. For example, the first power supply lines of the plurality of first voltage power supply groups may each include a double-layer lines or may each include a three-layer lines. For another example, the first power supply line of at least one first voltage power supply group may include a three-layer lines, and the first power supply lines of the remaining first voltage power supply groups may include a double-layer lines to meet the voltage drop requirements of different first power supply lines. The first power supply line of the present example adopts a multi-layer wiring design, which can reduce the voltage drop of the first power supply line.

In some exemplary implementations, the first power supply lines of different first voltage power supply groups may be located on different conductive layers, and the orthographic projections of the first power supply lines of at least two first voltage power supply groups on the base substrate may partially overlap. For example, the first power supply line of at least one first voltage power supply group may be located in a first source-drain metal layer, a second source-drain metal layer, or a third source-drain metal layer. The first power supply lines of the plurality of first voltage power supply groups of the present example may adopt single-layer wirings, thereby reducing hole-digging connection and simplifying the preparation process.

In some exemplary implementations, line segments of the first power supply lines of M first voltage power supply groups in a same extending direction have the same width. In this example, by configuring the first power supply lines of the plurality of first voltage power supply groups with a same width design, it is not only beneficial to reduce the impedance of the first power supply lines, but also beneficial to optimize the wiring arrangement space.

In some exemplary implementations, the line segments of first power supply lines of at least two adjacent first voltage power supply groups in a same extending direction may have different widths. In this example, by configuring the first power supply lines of the plurality of first voltage power supply groups with a non-equal width design, the voltage drop of different first power supply lines may be adjusted according to requirement, and the differentiated design of different first power supply lines may be met.

In some exemplary implementations, N sub-pixel groups may include: a first sub-pixel group emitting light of a first color, a second sub-pixel group emitting light of a second color, and a third sub-pixel group emitting light of a third color. M first voltage power supply groups may include: a first first voltage power supply group providing a first type of first voltage signal, a second first voltage power supply group providing a second type of first voltage signal, and a third first voltage power supply group providing a third type of first voltage signal. A first first voltage power supply group is configured to provide a first type of first voltage signal to the first sub-pixel group. A second first voltage power supply group is configured to provide a second type of first voltage signal to the second sub-pixel group. A third first voltage power supply group is configured to provide a third type of first voltage signal to the third sub-pixel group. In this example, M may be equal to N, and both are three. In some examples, a first color light may be blue light (B), a second color light may be red light (R), and a third color light may be green light (G). A first type of first voltage signal may be greater than a second type of first voltage signal, and a second type of first voltage signal may be greater than a third type of first voltage signal. However, the present embodiment is not limited thereto. In other examples, the quantity of sub-pixel groups may be three, the quantity of first voltage power supply groups may be two. A first first voltage power supply group may be configured to provide a first type of first voltage signal to a first sub-pixel group (e.g. including blue sub-pixels), and a second first voltage power supply group may be configured to provide a second type of first voltage signal to a second sub-pixel group (e.g. including red sub-pixels) and a third sub-pixel group (e.g. including green sub-pixels). In this example, the RGB brightness grouping control may be achieved through the grouping design of the first voltage signal, so as to achieve the purpose of saving power consumption of the first voltage signal.

In some exemplary embodiments, the display substrate may further include a bottom shield layer, and the bottom shield layer may be connected to a first first voltage power supply group. In this example, the impedance of the first first voltage power supply line group may be reduced by configuring the first first voltage power supply line group to be connected to the bottom shield layer.

In some exemplary implementations, an average width of a first power supply line of a first first voltage power supply group may be greater than an average width of a first power supply line of a second first voltage power supply group; and an average width of a first power supply line of a second first voltage power supply group may be greater than an average width of a first power supply line of a third first voltage power supply group. An average width of a first power supply line of the present example refers to an average value of widths of a plurality of line segments of the first power supply line. In some examples, a first power supply line of each first voltage power supply group may adopt a non-equal width design. In this example, by setting an average width of first power supply lines of a plurality of first voltage power supply groups, a differentiated design of different first power supply lines may be met.

In some exemplary embodiments, the display substrate may further include L second voltage power supply groups located in the first bezel region, the L second voltage power supply groups may be configured to provide different second voltage signals, each second voltage power supply group may be configured to provide a second voltage signal to a light emitting element in at least one sub-pixel group, wherein L is an integer greater than 1 and L is less than or equal to N. The second voltage signal is different from the first voltage signal, for example, the second voltage signal may be less than the first voltage signal. In some examples, lighting voltages of sub-pixels emitting light of different colors are different, and by grouping the second voltage signal, the brightness of sub-pixels emitting light of different colors may be accurately controlled, thereby achieving the purpose of reducing power consumption.

In some examples, the quantity of sub-pixel groups may be the same as the quantity of the second voltage power supply groups, i.e., L may be equal to N. Each second voltage power supply group may provide a second voltage signal to one sub-pixel group. Wherein, different sub-pixel groups receive different second voltage signals. In other examples, L may be less than N, and at least one second voltage power supply group may provide a first voltage signal to at least two sub-pixel groups. Wherein, the second voltage signals received by at least two sub-pixel groups may be the same. For example, one of the L second voltage power supply groups may be configured to provide the same second voltage signal to two sub-pixel groups. However, the present embodiment is not limited thereto.

In some examples, each of the L second voltage power supply groups may be configured to provide a second voltage signal different from the remaining second voltage power supply groups. In other words, the L second voltage power supply groups may provide L different second voltage signals. In other examples, at least two of the L second voltage power supply groups may be configured to provide different second voltage signals. For example, the L second voltage power supply groups may be configured to provide L-1 different second voltage signals, two of the L second voltage power supply groups may provide the same second voltage signal, and the remaining second voltage power supply groups may be configured to provide different second voltage signals. The present embodiment is not limited thereto.

In some examples, the display region may include a plurality of second power lines, and each second power line may be connected to a light emitting element of a plurality of sub-pixels emitting light of the same color. For example, the light emitting element of the sub-pixel may include an anode and a cathode. The cathode of the light emitting element may be connected to the second power line.

In some examples, a plurality of light emitting elements in a sub-pixel group may be connected to a plurality of second power lines, and a second voltage power supply group may be configured to provide a second voltage signal to the light emitting elements in the sub-pixel group through the plurality of second power lines. In other examples, a plurality of light emitting elements in a sub-pixel group may be connected to a second power line, and a second voltage power supply group may be configured to provide a second voltage signal to the light emitting elements in the sub-pixel group through the second power line. The present embodiment is not limited thereto.

The display substrate of the present embodiment will now be described through some examples. The display substrate is described in the following exemplary embodiments taking an OLED display substrate as an example. Herein, since the quantity of certain types of lines in the display region and the first bezel region is generally large, the accompanying drawings only schematically illustrate a few such lines or provide a generalized representation, and do not define the quantity of any specific type of lines.

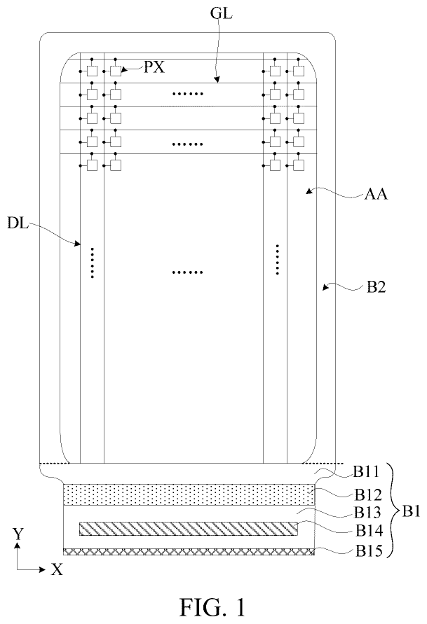

FIG. 1 is a schematic diagram of a display substrate according to at least one embodiment of the present disclosure. In some examples, as shown in FIG. 1, the display substrate of this example may include a display region AA and a bezel region located around the display region AA. The bezel region may include a first bezel region B1 located on a side of the display region AA and a second bezel region B2 located on remaining sides of the display region AA. The first bezel region B1 and the second bezel region B2 may surround the display region AA after being communicated. In some examples, the first bezel region B1 is a lower bezel of the display substrate, and the second bezel region B2 may include an upper bezel, a left bezel, and a right bezel of the display substrate. However, the present embodiment is not limited thereto.

In some examples, as shown in FIG. 1, the display region AA may include a plurality of sub-pixels PX forming a pixel array, the plurality of sub-pixels PX may be configured to display a dynamic picture or a static image, and the display region AA may be referred to as an Active Area (AA). In some examples, a display substrate may be a flexible substrate. Accordingly, the display substrate may be deformable, for example, may be crimped, bent, folded, or curled.

In some examples, as shown in FIG. 1, the display region AA may further include a plurality of gate lines GL and a plurality of data lines DL. The gate lines GL may extend in a first direction X, and the data lines DL may extend in a second direction Y. The first direction X may intersect with the second direction Y. For example, the first direction X may be perpendicular to the second direction Y. Orthographic projections of the plurality of gate lines GL and the plurality of data lines DL on the base substrate may intersect to form a plurality of sub-pixel regions, with one sub-pixel PX being disposed in each sub-pixel region. The plurality of data lines DL are electrically connected to the plurality of sub-pixels PX, and may be configured to provide data signals to the plurality of sub-pixels PX. The plurality of gate lines GL are electrically connected to the plurality of sub-pixels PX, and the plurality of gate lines GL may be configured to provide a scan signal to the plurality of sub-pixels PX.

In some examples, one pixel unit may include four sub-pixels, which may include one red (R) sub-pixel, one blue (B) sub-pixel, and two green (G) sub-pixels. Alternatively, one pixel unit may include three sub-pixels, which are red (R) sub-pixels, green (G) sub-pixels, and blue (B) sub-pixels, respectively. However, the present embodiment is not limited thereto. In some other examples, one pixel unit may include four sub-pixels which are a red sub-pixel, a green sub-pixel, a blue sub-pixel, and a white sub-pixel, respectively.

In some examples, at least one sub-pixel may include a pixel circuit and a light emitting element. The pixel circuit may be configured to drive a light emitting element connected thereto. For example, the pixel circuit may be configured to provide a drive current for driving the light emitting element to emit light. The pixel circuit may include a plurality of transistors and at least one capacitor. For example, the pixel circuit may have a 3TIC, 4TIC, 5T1C, 5T2C, 6TIC, 7TIC, or 8TIC structure. In the aforementioned circuit structures, T refers to a thin film transistor, C refers to a capacitor, a digit before T represents a quantity of thin film transistors in the circuit, and a digit before C represents a quantity of capacitors in the circuit.

In some examples, the light emitting element may be any one of a Light Emitting Diode (LED), an Organic Light Emitting Diode (OLED), a Quantum dot Light Emitting Diode (QLED), a micro LED (including: mini-LED or micro-LED), and the like. For example, the light emitting element may be an OLED, and the light emitting element may emit red light, green light, blue light, or white light, or the like under drive of a pixel circuit corresponding to the light emitting element. A color of light emitted by the light emitting element may be determined as needed. In some examples, the light emitting element may include an anode, a cathode, and an organic emitting layer located between the anode and the cathode. The anode of the light emitting element may be electrically connected to a corresponding pixel circuit. However, the present embodiment is not limited thereto.

In some examples, a shape of the light emitting element may be a rectangle, a rhombus, a pentagon, or a hexagon. When one pixel unit includes three sub-pixels, light emitting elements of the three sub-pixels may be arranged side by side horizontally, side by side vertically, or in a delta shape. When one pixel unit includes four sub-pixels, light emitting elements of the four sub-pixels may be arranged side by side horizontally, side by side vertically, or in a square arrangement. However, the present embodiment is not limited thereto.

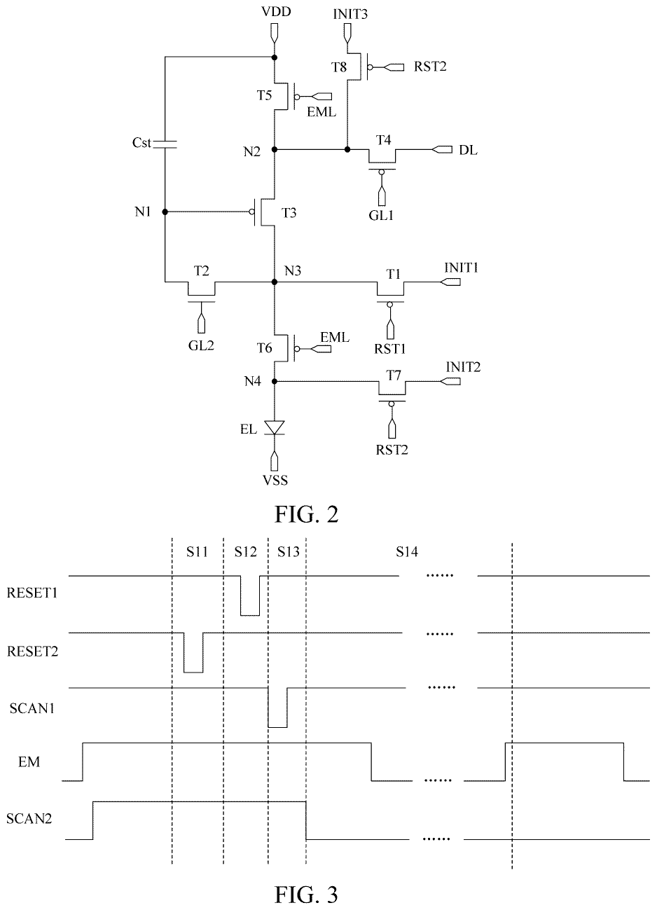

FIG. 2 is an equivalent circuit diagram of a pixel circuit according to at least one embodiment of the present disclosure. The pixel circuit in this example is described by taking an 8TIC structure as an example. In some examples as, shown in FIG. 2, the pixel circuit of this example may include eight transistors (i.e., a first transistor T1 to an eighth transistor T8) and one storage capacitor Cst. The first transistor T1 may be referred to as a first reset transistor, the second transistor T2 may be referred to as a threshold compensation transistor, the third transistor T3 may be referred to as a drive transistor, the fourth transistor T4 may be referred to as a data writing transistor, the fifth transistor T5 may be referred to as a first light emitting control transistor, the sixth transistor T6 may be referred to as a second light emitting control transistor, the seventh transistor T7 may be referred to as a second reset transistor, and the eighth transistor T8 may be referred to as a third reset transistor. A light emitting element EL may include an anode, a cathode and an organic light emitting layer disposed between the anode and the cathode.

In some examples, the first transistor T1, the third transistor T3 to the eighth transistor T8 may be first-type transistors, which may be, for example, P-type transistors, and the second transistor T2 may be a second-type transistor, which may be, for example, an N-type transistor. However, the present embodiment is not limited thereto. For example, the plurality of transistors of the pixel circuit may all be P-type transistors, or may all be N-type transistors. Using the same type of transistor in the pixel circuit may simplify the process flow, reduce the process difficulty of the display substrate, and improve the yield of a product.

In some examples, for the first-type transistors (e.g., including the first transistor T1 and the third transistor T3 to the eighth transistor T8) of the pixel circuit, a low temperature poly silicon thin film transistor may be used, and for the second-type transistor (e.g., including the second transistor T2) of the pixel circuit, an oxide thin film transistor may be used. Low Temperature Poly Silicon (LTPS) is adopted for an active layer of a low temperature poly silicon thin film transistor and an oxide semiconductor (Oxide) is adopted for an active layer of an oxide thin film transistor. A low temperature poly silicon thin film transistor has advantages such as a high mobility rate and fast charging, and an oxide thin film transistor has advantages such as a low leakage current. The low temperature poly silicon thin film transistor and the oxide thin film transistor are integrated on one display substrate to form a Low Temperature Polycrystalline Oxide (LTPS+Oxide) display substrate, and advantages of both the low temperature poly silicon thin film transistor and the oxide thin film transistor may be utilized, which may achieve low-frequency drive, power consumption reducing, and display quality being improved.

In some examples, as shown in FIG. 2, the pixel circuit may be electrically connected to the first scan line GL1, the second scan line GL2, the data line DL, the first power line VDD, the second power line VSS, the light emitting control line EML, the first initial signal line INIT1, the second initial signal line INIT2, the third initial signal line INIT3, the first reset control line RST1, and the second reset control line RST2. The first power line VDD may be configured to provide a constant first voltage signal Vdd to the pixel circuit, the second power line VSS may be configured to provide a constant second voltage signal Vss to the pixel circuit, and the first voltage signal Vdd may be greater than the second voltage signal Vss. The first scan line GL1 may be configured to provide a first scan signal SCAN1 to the pixel circuit. The second scan line GL2 may be configured to provide a second scan signal SCAN2 to the pixel circuit. The data line DL may be configured to provide a data signal to the pixel circuit. The light emitting control line EML may be configured to provide a light emitting control signal EM to the pixel circuit. The first reset control line RST1 may be configured to provide a first reset control signal RESET1 to the pixel circuit. The second reset control line may be configured to provide a second reset control signal RESET2 to the pixel circuit.

In some examples, as shown in FIG. 2, a gate of the third transistor T3 is electrically connected to a first node N1, a first electrode of the third transistor T3 is electrically connected to a second node N2, and a second electrode of the third transistor T3 is electrically connected to a third node N3. A gate of the fourth transistor T4 is electrically connected to the first scan line GL1, a first electrode of the fourth transistor T4 is electrically connected to the data line DL, and a second electrode of the fourth transistor T4 is electrically connected to the second node N2. A gate of the second transistor T2 is connected to the second scan signal line GL2, a second electrode of the second transistor T2 is electrically connected to the first node N1, and a first electrode of the second transistor T2 is electrically connected to the third node N3. A gate of the fifth transistor T5 is electrically connected to the light emitting control line EML, a first electrode of the fifth transistor T5 is electrically connected to the first power line VDD, and a second electrode of the fifth transistor T5 is electrically connected to the second node N2. A gate of a sixth transistor T6 is electrically connected to the light emitting control line EML, a first electrode of the sixth transistor T6 is electrically connected to the third node N3, and a second electrode of the sixth transistor T6 is electrically connected to a fourth node N4. A gate of the first transistor T1 is electrically connected to the first reset control line RST1, a first electrode of the first transistor T1 is electrically connected to the first initial signal line INIT1, and a second electrode of the first transistor T1 is electrically connected to the third node N3. The first transistor T1 may be configured to reset the third node N3. A gate of a seventh transistor T7 is electrically connected to the second reset control line RST2, a first electrode of the seventh transistor T7 is electrically connected to the second initial signal line INIT2, and a second electrode of the seventh transistor T7 is electrically connected to the fourth node N4. The seventh transistor T7 may be configured to reset the fourth node N4. A gate of the eighth transistor T8 is electrically connected to the second reset control line RST2, a first electrode of the eighth transistor T8 is electrically connected to the third initial signal line INIT3, and a second electrode of the eighth transistor T8 is electrically connected to the second node N2. The eighth transistor T8 may be configured to reset the second node N2. A first electrode of the storage capacitor Cst is electrically connected to the first node N1, and a second electrode of the storage capacitor Cst is electrically connected to the first power line VDD. An anode of the light emitting element EL may be electrically connected to the fourth node N4, and a cathode of the light emitting element EL may be electrically connected to the second power line VSS.

In the example, the first node N1 is a connection point of the storage capacitor Cst, the second transistor T2, and the third transistor T3. The second node N2 is a connection point of the fifth transistor T5, the fourth transistor T4, the eighth transistor T8, and the third transistor T3. The third node N3 is a connection point of the first transistor T1, the third transistor T3, the second transistor T2, and the sixth transistor T6. The fourth node N4 is a connection point of the sixth transistor T6, the seventh transistor T7, and the light emitting element EL.

FIG. 3 is a working timing diagram of a pixel circuit provided in FIG. 2. A working process of the pixel circuit shown in FIG. 2 will be described below with reference to FIG. 3. Herein, the first transistor T1, the third transistor T3 to the eighth transistor T8 of the pixel circuit are P-type transistors, and the second transistor T2 is an N-type transistor.

In some examples, as shown in FIGS. 2 and 3, during one frame of display period, the working process of the pixel circuit may at least include a first stage S11, a second stage S12, a third stage S13, and a fourth stage S14.

The first stage S11 is referred to as a first reset stage. In the first stage S1, the second reset control signal RESET2 provided by the second reset control line RST2 is a low-level signal, used to turn on the seventh transistor T7 and the eighth transistor T8, and the second scan signal SCAN2 provided by the second scan line GL2 is a high-level signal, used to turn on the second transistor T2. The eighth transistor T8 is turned on so that the third initial signal provided by the third initial signal line INIT3 is provided to the second node N2. The seventh transistor T7 is turned on so that the second initial signal provided by the second initial signal line INIT2 is provided to the fourth node N4 to initialize the fourth node N4. The first scan signal SCAN1 provided by the first scan line GL1 is a high-level signal, the first reset control signal RESET1 provided by the first reset control line RST1 is a high-level signal, and the light emitting control signal EM provided by the light emitting control line EML is a high-level signal, so that the fourth transistor T4, the first transistor T1, the fifth transistor T5 and the sixth transistor T6 are turned off. In this stage, the light emitting element EL does not emit light.

The second stage S12 is referred to as a second reset stage. In the second stage S2, the first reset control signal RESET1 provided by the first reset control line RST1 is a low-level signal, and the first transistor T1 is turned on. The second scan signal SCAN2 provided by the second scan line GL2 is a high-level signal, and the second transistor T2 is turned on. The first transistor T1 and the second transistor T2 are turned on such that a first initial signal provided by the first initial signal line INIT1 is provided to the first node N1 to initialize the first node N1. The second reset control signal RESET2 provided by the second reset control line RST2 is a high-level signal, the first scan signal SCAN1 provided by the first scan line GL1 is a high-level signal, and the light emitting control signal EM provided by the light emitting control line EML is a high-level signal, so that the seventh transistor T7, the eighth transistor T8, the fourth transistor T4, the fifth transistor T5, and the sixth transistor T6 are turned off. In this stage, the light emitting element EL does not emit light.

The third stage S13 is referred to as a data writing stage or a threshold compensation stage. The first scan signal SCAN1 provided by the first scan line GL1 is a low-level signal, and the fourth transistor T4 is turned on. The second scan signal SCAN2 provided by the second scan line GL2 is a high-level signal, and the second transistor T2 is turned on. In this stage, the first electrode of the storage capacitor Cst is at a low level and the third transistor T3 is turned on. The second transistor T2, the fourth transistor T4 and the third transistor T3 are turned on, so that a data voltage Vdata output by the data line DL is provided to the first node N1 through the second node N2, the turned-on third transistor T3, the third node N3, and the turned-on second transistor T2, and the storage capacitor Cst is charged with a difference between the data voltage Vdata output by the data line DL and a threshold voltage of the third transistor T3. A voltage of the first electrode (i.e., the first node N1) of the storage capacitor Cst is Vdata-|Vth|, wherein Vdata is the data voltage output by the data line DL, and Vth is the threshold voltage of the third transistor T3. The first reset control signal RESET1 provided by the first reset control line RST1 is a high-level signal, the second reset control signal RESET2 provided by the second reset control line RST2 is a high-level signal, and the light emitting control signal EM provided by the light emitting control line EML is a high-level signal, so that the first transistor T1, the seventh transistor T7, the eighth transistor T8, the fifth transistor T5 and the sixth transistor T6 are turned off.

In the fourth stage S14, the light emitting control signal EM provided by the light emitting control line EML may be switched from the high-level signal to a low-level signal, so that the fifth transistor T5 and the sixth transistor T6 are turned on. The second scan signal SCAN2 provided by the second scan line GL2 is a low-level signal, so that the second transistor T2 is turned off. The first scan signal SCAN1 provided by the first scan line GL1, the first reset control signal RESET1 provided by the first reset control line RST1, and the second reset control signal RESET2 provided by the second reset control line RST2 are high-level signals, so that the fourth transistor T4, the first transistor T1, the seventh transistor T7, and the eighth transistor T8 are turned off. The first voltage signal Vdd outputted by the first power line VDD may provide a drive voltage to the anode of the light emitting element EL through the fifth transistor T5, the third transistor T3, and the sixth transistor T6 which are turned on, to drive the light emitting element EL to emit light.

In a driving process for the pixel circuit, a drive current flowing through the third transistor T3 is determined by a voltage difference between the gate and the first electrode of the third transistor T3. Since a voltage of the first node N1 is Vdata-|Vth|, the drive current of the third transistor T3 is as follows:

$$I = K \times {( V gs - V th )}^{2} = K \times {[ ( V dd - V data + \vert V th \vert ) - V th ]}^{2} = K \times {[ V dd - V data ]}^{2} .$$

Wherein, I is the drive current flowing through the third transistor T3, that is, a drive current for driving the light emitting element, K is a constant, Vgs is the voltage difference between the gate electrode and the first electrode of the third transistor T3, Vth is the threshold voltage of the third transistor T3, Vdata is the data voltage output by the data line DL, and Vdd is the first voltage signal output by the first power line VDD.

It may be seen from the above formula that a current flowing through the light emitting element is independent of the threshold voltage of the third transistor T3. Therefore, the pixel circuit according to this embodiment may better compensate the threshold voltage of the third transistor T3. Moreover, the pixel circuit provided in the present embodiment may improve display defect caused by low frequency and improve a display effect of the light emitting element.

In some examples, the Data Range required for sub-pixels emitting different colors of light varies. Further, according to the above equation for calculating the drive current, it may be seen that the drive current of the sub-pixel is related to the data voltage and the first voltage signal, and thus, the sub-pixels (including, for example, a red sub-pixel, a blue sub-pixel, and a green sub-pixel) emitting light of different colors have different requirements for the first voltage signal. In this embodiment, the first voltage signals may be grouped to provide first voltage signals satisfying actual requirements for sub-pixels emitting light of different colors, so as to achieve the purpose of saving power consumption.

In some examples, as shown in FIG. 1, the first bezel region B1 may include a second fan-out region B11, a bend region B12, a first fan-out region B13, a second signal access region B14, and a first signal access region B15 disposed sequentially along a direction away from the display region AA. The second fan-out region B11 may be communicated with the second bezel region B2 and be located on a side of the display region AA. The bend region B12 may be communicated with the second fan-out region B11 and the first fan-out region B13, and are located on a side of the second fan-out region B11 away from the display region AA. The bend region B12 may enable the first fan-out region B13, the first signal access region B15, and the second signal access region B14 to be bent to a back of the display region AA. The bend region B12 may include a plurality of bend connection lines to achieve a connection between lines for transmitting a same signal in the second fan-out region B11 and the first fan-out region B13. The first fan-out region B13 may be located on a side of the bend region B12 away from the display region AA.

In some examples, as shown in FIG. 1, the second signal access region B14 may be located on a side of the first fan-out region B13 away from the display region AA. The second signal access region B14 may be configured to provide a drive chip (such as an Integrated Circuit (IC)), for example, the drive chip provided in the second signal access region B14 may be a Touch and Display Driver Integration (TDDI) chip. The second signal access region B14 may also be referred to as a drive chip disposing region. For example, the drive chip may be configured to generate a data signal required for driving sub-pixels.

In some examples, as shown in FIG. 1, the first signal access region B15 may be located on a side of the second signal access region B14 away from the display region AA. The first signal access region B15 may be provided with a plurality of contact pads, which may be configured to bond a Flexible Printed Circuit (FPC), such that a plurality of signal lines (e.g., power lines, control signal lines, etc.) are connected to an external control apparatus through the plurality of contact pads. The first signal access region B15 may also be referred to as a circuit bonding region.

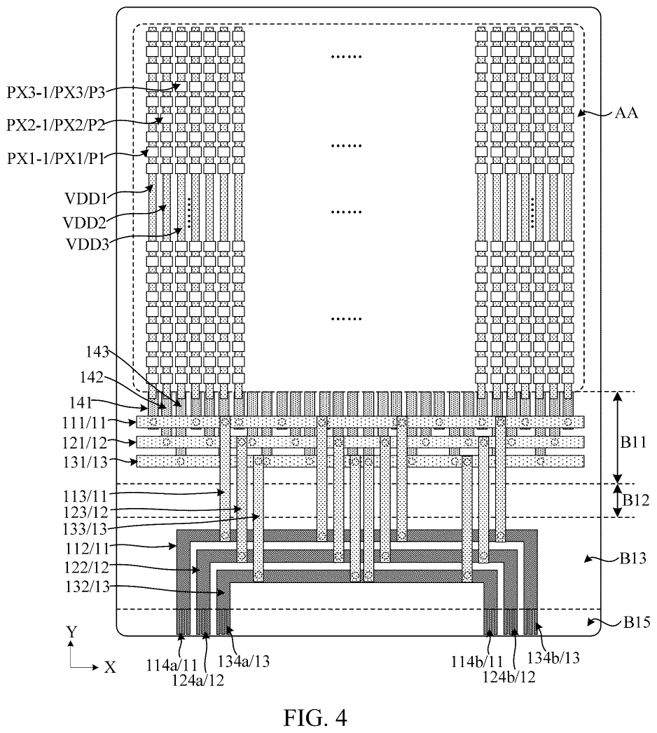

FIG. 4 is a schematic diagram of transmission of a first voltage signal according to at least one embodiment of the present disclosure. In some examples, the display region AA may include a plurality of sub-pixels and a plurality of first power lines. The plurality of sub-pixels of the display region AA may be divided into N sub-pixel groups, each sub-pixel group may include a plurality of sub-pixels emitting light of the same color, and different sub-pixel groups may be configured to emit light of different colors. In this example, a plurality of sub-pixels of the display region AA being divided into three sub-pixel groups is taken as an example. The display region AA may include a first sub-pixel group P1, a second sub-pixel group P2, and a third sub-pixel group P3. The first sub-pixel group P1 may include a plurality of sub-pixels PX1 emitting light of a first color, the second sub-pixel group P2 may include a plurality of sub-pixels PX2 emitting light of a second color, and the third sub-pixel group P3 may include a plurality of sub-pixels PX3 emitting light of a third color. For example, the first color light may be blue light, the second color light may be red light, and the third color light may be green light. In other words, the first sub-pixel group P1 may be a blue sub-pixel group, the second sub-pixel group P2 may be a red sub-pixel group, and the third sub-pixel group P3 may be a green sub-pixel group. The present embodiment is not limited thereto.

In some examples, one sub-pixel may include a pixel circuit and a light emitting element electrically connected to the pixel circuit. FIG. 4 illustrates a pixel circuit of a sub-pixel in the display region AA as an example, while the light emitting element of the sub-pixel is omitted from the diagram. As shown in FIG. 4, a plurality of pixel circuits in the display region AA may be arranged in an array in a plurality of rows and columns. One row of pixel circuits may include a plurality of pixel circuits arranged in a first direction X, and one column of pixel circuits may include a plurality of pixel circuits arranged in a second direction Y. The first sub-pixel group P1 may include a plurality of columns of pixel circuits, and each column of pixel circuits may include a plurality of pixel circuits PX1-1. The second sub-pixel group P2 may include a plurality of columns of pixel circuits, and each column of pixel circuits may include a plurality of pixel circuits PX2-1. The third sub-pixel group P3 may include a plurality of columns of pixel circuits, and each column of pixel circuits may include a plurality of pixel circuits PX3-1.

In some examples, as illustrated in FIG. 4, the plurality of first power lines of the display region AA may include a plurality of first power lines VDD1, a plurality of first power lines VDD2, and a plurality of first power lines VDD3. The first power line VDD1 may be configured to transmit a first voltage signal Vdd1, the first power line VDD2 may be configured to transmit a first voltage signal Vdd2, and the first power line VDD3 may be configured to transmit a first voltage signal Vdd3. The first voltage signals Vdd1, Vdd2, and Vdd3 may be first voltage signals having different voltage values.

In some examples, as shown in FIG. 4, each column of pixel circuits may be electrically connected to one first power line, and is configured to receive a first voltage signal. A column of pixel circuits PX1-1 of the first sub-pixel group P1 may be electrically connected to one first power line VDD1 and configured to receive a first voltage signal Vdd1; a column of pixel circuits PX2-1 of the second sub-pixel group P2 may be electrically connected to one first power line VDD2 and configured to receive a first voltage signal Vdd2; and a column of pixel circuits PX3-1 of the third sub-pixel group P3 may be electrically connected to one first power line VDD3 and configured to receive a first voltage signal Vdd3. For example, the first sub-pixel group P1 includes blue sub-pixels, the second sub-pixel group P2 includes red sub-pixels, and the third sub-pixel group P3 includes green sub-pixels. The first voltage signal Vdd1 provided to the first sub-pixel group P1 may be greater than the first voltage signal Vdd2 provided to the second sub-pixel group P2, and the first voltage signal Vdd2 provided to the second sub-pixel group P2 may be greater than the first voltage signal Vdd3 provided to the third sub-pixel group P3. In this example, since the first voltage signal required by the blue sub-pixel is rather great, by providing the blue sub-pixel, the red sub-pixel, and the green sub-pixel with the first voltage signal that meets the respective requirements, the loss of power consumption may be avoided, thereby achieving the purpose of saving power consumption.

In some examples, as shown in FIG. 4, the first bezel region B1 may include M first voltage power supply groups, for example, the value of M is 3, and the first bezel region B1 may include a first first voltage power supply group 11, a second first voltage power supply group 12, and a third first voltage power supply group 13. Each first voltage power supply group may be configured to provide a corresponding first voltage signal to at least one sub-pixel group. In the present example, the first voltage power supply group 11 may be configured to provide a first voltage signal Vdd1 to the first sub-pixel group, the first voltage power supply group 12 may be configured to provide a first voltage signal Vdd2 to the second sub-pixel group, and the first voltage power supply group 13 may be configured to provide a first voltage signal Vdd3 to the third sub-pixel group.

In some examples, as shown in FIG. 4, the first voltage power supply group 11 may include a second power supply line 111 located in the second fan-out region B11, a first power supply line 112 located in the first fan-out region B13, a first power supply bend line 113 located in the bend region B12, and first voltage contact pads 114a and 114b located in the first signal access region B15. The first voltage power supply group 12 may include a second power supply line 121 located in the second fan-out region B11, a first power supply line 122 located in the first fan-out region B13, a first power supply bend line 123 located in the bend region B12, and first voltage contact pads 124a and 124b located in the first signal access region B15. The first voltage power supply group 13 may include a second power supply line 131 located in the second fan-out region B11, a first power supply line 132 located in the first fan-out region B13, a first power supply bend line 133 located in the bend region B12, and first voltage contact pads 134a and 134b located in the first signal access region B15.

In some examples, as shown in FIG. 4, the second power supply lines 111, 121, and 131 located in the second fan-out region B11 may be sequentially arranged along an opposite direction of the second direction Y. The second power supply lines 111, 121, and 131 may at least be lines extending in the first direction X. The second power supply line may be connected to the first power line through a first-type voltage transfer electrode. For example, the first-type voltage transfer electrode may include a first voltage transfer electrode 141, a second voltage transfer electrode 142, and a third voltage transfer electrode 143. Wherein, the second power supply line 111 may be connected to the first power line VDD1 through the first voltage transfer electrode 141, the second power supply line 121 may be connected to the first power line VDD2 through the second voltage transfer electrode 142, and the second power supply line 131 may be connected to the first power line VDD3 through the third voltage transfer electrode 143.

In some examples, the second power supply lines 111, 121, and 131 may be in the same layer, the first voltage transfer electrode 141, the second voltage transfer electrode 142, and the third voltage transfer electrode 143 may be in the same layer, and the first power lines VDD1, VDD2, and VDD3 may be in the same layer. For example, the first power lines VDD1, VDD2, and VDD3 may be located on a side of the first voltage transfer electrode 141, the second voltage transfer electrode 142, and the third voltage transfer electrode 143 away from the base substrate, and the second power supply lines 111, 121, and 131 may be located on a side of the first voltage transfer electrode 141, the second voltage transfer electrode 142, and the third voltage transfer electrode 143 away from the base substrate. The first power lines VDD1, VDD2, and VDD3 may be located on a side of the second power supply lines 111, 121, and 131 away from the base substrate. The present embodiment is not limited thereto.

In some examples, as shown in FIG. 4, the first power supply bend lines 113, 123, and 133 located in the bend region B12 may be lines extending at least in the second direction Y. The first power supply bend lines 113, 123, and 133 may be in the same layer. The first power supply bend line 113 may connect the second power supply line 111 and the first power supply line 112, the first power supply bend line 123 may connect the second power supply line 121 and the first power supply line 122, and the first power supply bend line 133 may connect the second power supply line 131 and the first power supply line 132. For example, the first power supply bend line may be connected to the corresponding second power supply line through the second-type voltage transfer electrode, and the first power supply bend line may be directly connected to the first power supply line. However, the present embodiment is not limited thereto. In other examples, the first power supply bend line may be directly connected to both the first power supply line and the second power supply line.

In some examples, as shown in FIG. 4, the first power supply lines 112, 122, and 132 located in the first fan-out region B13 may be sequentially disposed in a direction opposite to the second direction Y. Both terminals of the first power supply line 112 may be connected to the first voltage contact pads 114a and 114b in the first signal access region B15, respectively. Both terminals of the first power supply line 122 may be connected to the first voltage contact pads 124a and 124b in the first signal access region B15, respectively. Both terminals of the first power supply line 132 may be connected to the first voltage contact pads 134a and 134b in the first signal access region B15, respectively. The first voltage contact pads 114a, 124a and 134a may be disposed adjacent to each other, and the first voltage contact pads 114b, 124b and 124b may be disposed adjacent to each other.

In this example, three first voltage power supply groups are provided in the first bezel region to provide three different first voltage signals, and different requirements for the first voltage signals of three sub-pixel groups emitting different color lights in the display region may be met, thereby achieving the purpose of saving power consumption of the first voltage signals.

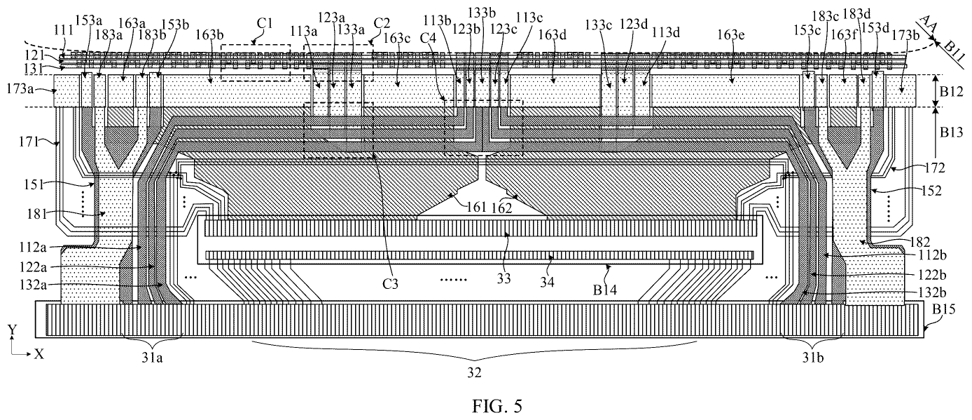

FIG. 5 is a schematic diagram of wiring of a first bezel region according to at least one embodiment of the present disclosure. FIG. 5 mainly illustrates three second power supply lines 111, 121, and 131 of the second fan-out region B11, a plurality of bend connection lines of the bend region B12, and a portion of lines of the first fan-out region B13 (including, for example, first power supply lines 112a and 112b, 122a and 122b, and 132a and 132b). In FIG. 5, a plurality of adjacent lines of the same type are shown as a whole.

In some examples, as shown in FIG. 5, the second fan-out region B11 may at least include: three second power supply lines 111, 121, and 131, a second voltage fan-out line (not shown), a plurality of data fan-out lines (not shown), a plurality of drive fan-out lines (not shown), and a plurality of touch fan-out lines (not shown). The second voltage fan-out line may be configured to transmit a second voltage signal. The plurality of data fan-out lines may be connected to the plurality of data lines in the display region and configured to transmit data signals. The plurality of drive fan-out lines may be connected to a gate drive circuit disposed in the second bezel region, and configured to transmit drive control signals (including, for example, a clock signal, a start signal, etc.). The plurality of data fan-out lines may include a plurality of first data fan-out lines located in the first conductive layer and a plurality of second data fan-out lines located in the second conductive layer.

In some examples, as shown in FIG. 5, the plurality of bend connection lines of the bend region B12 may include a plurality of data bend lines (such as including a first group of data bend lines 163a, a second group of data bend lines 163b, a third group of data bend lines 163c, a fourth group of data bend lines 163d, a fifth group of data bend lines 163e, and a sixth group of data bend lines 163f), a plurality of drive bend lines (such as including a first group of drive bend lines 173a, a second group of drive bend lines 173b), a plurality of touch bend lines (such as including a first group of touch bend lines 183a, a second group of touch bend lines 183b, a third group of touch bend lines 183c, and a fourth group of touch bend lines 183d), a plurality of first power supply bend lines (such as including first power supply bend lines 113a, 113b, 113c, 113d, 123a, 123b, 123c, 123d, 133a, 133b, and 133c), and a plurality of second power supply bend lines (such as including second power supply bend lines 153a, 153b, 153c, and 153d).

In some examples, as shown in FIG. 5, within the bend region B12, the first group of drive bend lines 173a, the second power supply bend line 153a, the first group of touch bend lines 183a, the first group of data bend lines 163a, the second group of touch bend lines 183b, the second power supply bend line 153b, the second group of data bend lines 163b, the first power supply bend lines 113a, 123a, and 133a, the third group of data bend lines 163c, the first power supply bend lines 113b, 123b, 133b, 123c, and 113c, the fourth group of data bend lines 163d, the first power supply bend lines 113c, 123d, and 113d, the fifth group of data bend lines 163c, the second power supply bend line 153c, the third group of touch bend lines 183c, the sixth group of data bend lines 163f, the fourth group of touch bend lines 183d, the second power supply bend line 153d, and the second group of drive bend lines 173b may be arranged sequentially along the first direction X.

In some examples, as shown in FIG. 5, the first fan-out region B13 may include a plurality of first power supply lines (such as including two first power supply lines 112a and 112b, two first power supply lines 122a and 122b, and two first power supply lines 132a and 132b), two second voltage lead-out lines (such as including second voltage lead-out lines 151 and 152), a plurality of data lead-out lines (including a first group of data lead-out lines 161 and a second group of data lead-out lines 162), a plurality of drive lead-out lines (including a first group of drive lead-out lines 171 and a second group of drive lead-out lines 172), and a plurality of touch lead-out lines (including a first group of touch lead-out lines 181 and a second group of touch lead-out lines 182). The first group of drive lead-out lines 171 and the second group of drive lead-out lines 172 may be located on two sides of the plurality of data lead-out lines in the first direction X. The first group of drive lead-out lines 171 may be connected to a plurality of drive fan-out lines in the second fan-out region B11 through the first group of drive bend lines 173a. The second group of drive lead-out lines 172 may be connected to a plurality of drive fan-out lines in the second fan-out region B11 through the second group of drive bend lines 173b. The first group of touch lead-out lines 181 may be connected to a plurality of touch fan-out lines in the second fan-out region B11 through the first group of touch bend lines 183a and the second group of touch bend lines 183b. The second group of touch lead-out lines 182 may be connected to a plurality of touch fan-out lines in the second fan-out region B11 through a third group of touch bend lines 183c and a fourth group of touch bend lines 183d. The second voltage lead-out line 151 may be connected to the second voltage fan-out line in the second fan-out region B11 through the second voltage bend lines 153a and 153b, and the second voltage lead-out line 152 may be connected to the second voltage fan-out line in the second fan-out region B11 through the second voltage bend lines 153c and 153d. The second voltage lead-out lines 151 and 152 may be configured to transmit a second voltage signal.

In some examples, two first power supply lines 112a and 112b may be disposed substantially symmetrically with respect to the centerline of the first bezel region in the first direction X. Two first power supply lines 122a and 122b may be disposed substantially symmetrically with respect to the centerline of the first bezel region in the first direction X. Two first power supply lines 132a and 132b may be disposed substantially symmetrically with respect to the centerline of the first bezel region in the first direction X. The two first power supply lines 132a and 132b may be an integrated structure connected to each other.

In some examples, as shown in FIG. 5, widths of line segments of the plurality of first power supply lines in the same extending direction may be substantially the same. For example, widths (i.e. lengths in the second direction Y) of line segments extending in the first direction X of the first power supply lines 112a, 112b, 122a, 122b, 132a, and 132b may be substantially the same. Widths (i.e. lengths in the first direction X) of the line segments extending in the second direction Y of the first power supply lines 112a, 112b, 122a, 122b, 132a, and 132b may be substantially the same.

In some examples, the first power supply line 112a may be connected to the second power supply line 111 through the first power supply bend lines 113a, 113b, and the first power supply line 112b may be connected to the second power supply line 111 through the first power supply bend lines 113c and 113d. The first power supply line 122a may be connected to the second power supply line 121 through the first power supply bend lines 123a, 123b, and the first power supply line 122b may be connected to the second power supply line 121 through the first power supply bend lines 123c and 123d. The first power supply line 132a may be connected to the second power supply line 131 through the first power supply bend lines 133a, 133b, and the first power supply line 132b may be connected to the second power supply line 131 through the first power supply bend lines 133b and 133c.

In some examples, as shown in FIG. 5, the first signal access region B15 may include a plurality of contact pads, such as a first group of power contact pads 31a and a second group of power contact pads 31b, and a group of middle contact pads 32. The first group of power contact pads 31a and the second group of power contact pads 31b may be located on two opposite sides of one group of middle contact pads 32 along the first direction X. The first group of power contact pads 31a may include: a plurality of first voltage contact pads (such as including the first voltage contact pads 114a, 124a, and 134a as shown in FIG. 4) and at least one second voltage contact pad. The second voltage contact pad may be located on a side of the plurality of first voltage contact pads in an opposite direction of the first direction X. The second group of power contact pads 21b may include a plurality of first voltage contact pads (such as including the first voltage contact pads 114b, 124b, and 134b as shown in FIG. 4) and at least one second voltage contact pad. The second voltage contact pad may be located on a side of the plurality of first voltage contact pads in the first direction X.

In some examples, as shown in FIG. 5, the second signal access region B14 may include a plurality of input contact pads 34 and a plurality of output contact pads 33. The plurality of input contact pads 34 may be located on a side of the plurality of output contact pads 33 away from the bend region B12. The plurality of input contact pads 34 may be connected to a group of middle contact pads 32 through a plurality of contact pad leads. The plurality of output contact pads 33 may be connected to at least a first group of data lead-out lines 161 and a second group of data lead-out lines 162.

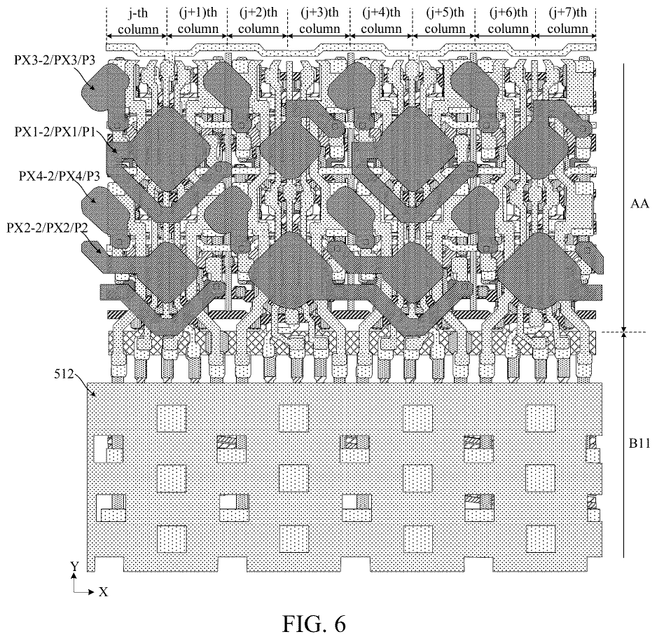

FIG. 6 is a partially enlarged schematic diagram of C1 region in FIG. 5. FIG. 6 schematically illustrates the junction between the display region AA and the first bezel region B1, and mainly illustrates two rows and eight columns of pixel circuits (for example, column j to column j+7, wherein j may be an integer greater than 0) of the display region AA and some light emitting elements to which the pixel circuits are connected, and a partial region of the second fan-out region B11 of the first bezel region B1.

In some examples, as shown in FIG. 6, the plurality of pixel circuits of the display region AA may arranged in an array along the first direction X and the second direction Y. The plurality of light emitting elements in the display region AA may include: a first light emitting element PX1-2 emitting light of a first color, a second light emitting element PX2-2 emitting light of a second color, and a third light emitting element PX3-2 and a fourth light emitting element PX4-2 both emitting light of a third color. The first light emitting element PX1-2 and the second light emitting element PX2-2 may be arranged at intervals in the first direction X and the second direction Y. The third light emitting element PX3-2 and the fourth light emitting element PX4-2 may be arranged at intervals in the first direction X and the second direction Y. The first light emitting element PX1-2 and the second light emitting element PX2-2 may be arranged in different rows and columns from the third light emitting element PX3-2 and the fourth light emitting element PX4-2. The pixel circuits to which the plurality of first light emitting elements PX1-2 are connected may be arranged in the same column, the pixel circuits to which the plurality of second light emitting elements PX2-2 are connected may be arranged in the same column, and the pixel circuits to which the plurality of third light emitting elements PX3-2 and the pixel circuits to which the plurality of fourth light emitting elements PX4-3 are connected may be arranged in the same column. For example, the pixel circuit of the j-th column may be connected to the third light emitting element PX3-2 and the fourth light emitting element PX4-3 emitting light of the third color; the pixel circuit of the (j+1)th column may be connected to the first light emitting element PX1-2; the pixel circuit of the (j+2)th column may be connected to the third light emitting element and the fourth light emitting element; the pixel circuit of the (j+3)th column may be connected to the second light emitting element; the pixel circuit of the (j+4)th column may be connected to the third light emitting element and the fourth light emitting element; the pixel circuits in the (j+5)th column may be connected to the first light emitting elements; the pixel circuits in the (j+6)th column may be connected to the third light emitting element and fourth light emitting element; and the pixel circuits in the (j+7)th column may be connected to the second light emitting element.

In some examples, the first color light may be blue light, the second color light may be red light, and the third color light may be green light. The first light emitting element may be a blue light emitting element, the second light emitting element may be a red light emitting element, and the third light emitting element and the fourth light emitting element may be green light emitting elements. In the present example, each four columns of pixel circuits may form one group, and the four columns of pixel circuits in one group may be sequentially connected to the green light emitting element, the blue light emitting element, the green light emitting element, and the red light emitting element. For example, the j-th column to the (j+3)th column of pixel circuits form one group, and the (j+4)th column to the (j+7)th column of pixel circuits form one group.

In some examples, the sub-pixel PX1 includes a first light emitting element PX1-2, the sub-pixel PX2 includes a second light emitting element PX2-2, the sub-pixel PX3 includes a third light emitting element PX3-2, and the sub-pixel PX4 includes a fourth light emitting element PX4-2. The sub-pixel PX1 belongs to the first sub-pixel group PX1, the sub-pixel PX2 belongs to the second sub-pixel group P2, and the sub-pixel PX3 and the sub-pixel PX4 belong to the third sub-pixel group P3.

In some examples, in a direction perpendicular to the display substrate, the display substrate may include a bottom shield layer, a first semiconductor layer, a first conductive layer, a second conductive layer, a second semiconductor layer, a third conductive layer, a fourth conductive layer, a fifth conductive layer, and a sixth conductive layer which are provided on the base substrate. A first insulation layer may be provided between the bottom shield layer and the first semiconductor layer. A second insulation layer may be provided between the first semiconductor layer and the first conductive layer. A third insulation layer may be provided between the first conductive layer and the second conductive layer. A fourth insulation layer may be provided between the second conductive layer and the second semiconductor layer. A fifth insulation layer may be provided between the second semiconductor layer and the third conductive layer. A sixth insulation layer may be provided between the third conductive layer and the fourth conductive layer. A seventh insulation layer and an eighth insulation layer may be provided between the fourth conductive layer and the fifth conductive layer. A ninth insulation layer may be provided between the fifth conductive layer and the sixth conductive layer. A tenth insulation layer may be provided on a side of the sixth conductive layer away from the base substrate. In some embodiments, the first to seventh insulation layers may be inorganic insulation layers, while the eighth, ninth, and tenth insulation layers may be organic insulation layers. However, the present embodiment is not limited thereto.

The structure of the film or layer of the display substrate of the present example will be illustrated below by a preparation process of the display substrate. A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire preparation process, the “thin film” may also be called a “layer”. If the “thin film” need to be processed through the patterning process in the entire preparation process, the “thin film” is called a “thin film” before the patterning process is performed and is called a “layer” after the patterning process is performed. At least one “pattern” is contained in the “layer” which has been processed through the patterning process. The shape of A may refer to the shape of the orthographic projection of A on the base substrate.

In some examples, the preparing process of the display substrate may include the following operations. In the following example, a film of one pixel circuit (for example, a pixel circuit located in the j-th column of the last row) in the display region will be described as an example.

(1) A base substrate is provided. In some examples, the base substrate may be a rigid substrate or a flexible substrate. For example, the rigid substrate may be made of, but not limited to, one or more of glass and quartz. The flexible substrate may be made of, but not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In some examples, the flexible substrate may include a first flexible material layer, a first inorganic material layer, a second flexible material layer and a second inorganic material layer which are stacked. The first flexible material layer and the second flexible material layer may be made of a material such as polyimide (PI), polyethylene terephthalate (PET), or a polymer soft film on which surface treatment is performed, and materials of the first inorganic material layer and the second inorganic material layer may be silicon nitride (SiNy, y>0) or silicon oxide (SiOx, x>0), etc., which are used to improve resistance to water and oxygen of the base substrate.

(2) A bottom shield layer is formed. In some examples, a shield metal thin film is deposited on the base substrate, and the shield metal thin film is patterned through a patterning process to form a bottom shield layer disposed on the base substrate.

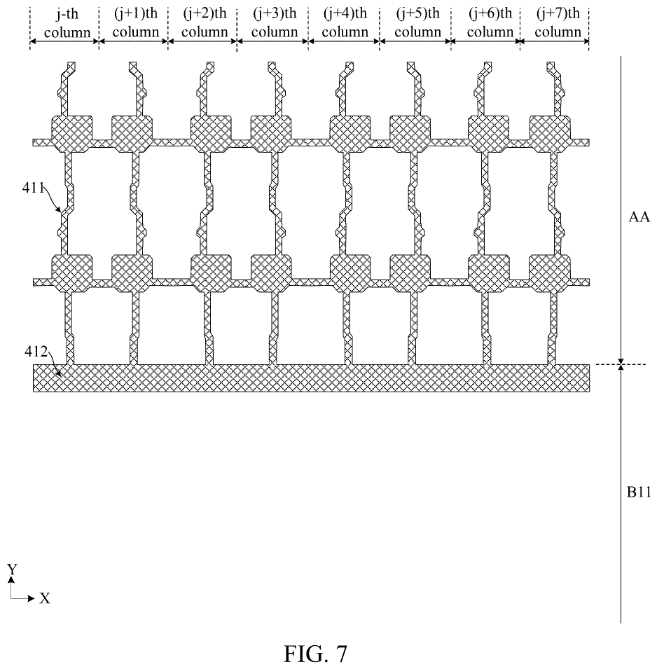

FIG. 7 is a schematic partial view of a display substrate after a shield layer is formed in FIG. 6. In some examples, as shown in FIG. 7, the bottom shield layer may include a first bottom structure 411 located in the display region AA and a second bottom structure 412 located in the second fan-out region B11. The bottom shield layer may have an approximate mesh structure. The first bottom structure 411 and the second bottom structure 412 may be an integrated structure connected to each other. The first bottom structure 411 may have an approximate mesh structure, and the second bottom structure 412 may have an approximate mesh structure extending in the first direction X.

(3) A first semiconductor layer is formed. In some examples, a first insulation thin film and a first semiconductor thin film are deposited sequentially on the base substrate on which the aforementioned structures are formed, and the first semiconductor thin film is patterned through a patterning process to form a first insulation layer and a first semiconductor layer disposed on the first insulation layer. In some examples, a material of the first semiconductor layer may be amorphous silicon (a-Si), polycrystalline silicon (p-Si), hexathiophene or polythiophene, or other materials.

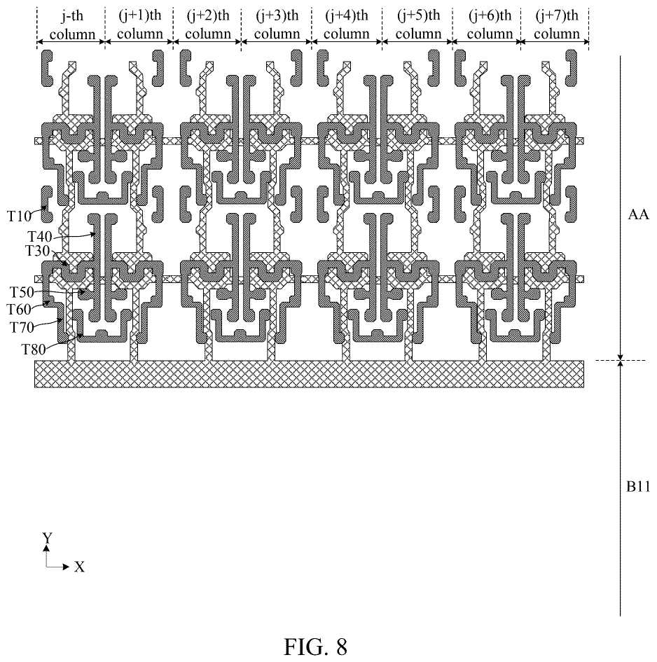

FIG. 8 is a schematic partial view of a display substrate after a first semiconductor layer is formed in FIG. 6. In some examples, as shown in FIG. 8, the first semiconductor layer of the display region AA may at least include: active layers of a plurality of first-type transistors of a plurality of pixel circuits (for example, an active layer T10 of the first transistor T1, an active layer T30 of the third transistor T3, an active layer T40 of the fourth transistor T4, an active layer T50 of the fifth transistor T5, an active layer T60 of the sixth transistor T6, an active layer T70 of the seventh transistor T7 and an active layer T80 of the eighth transistor T8).

In some examples, an active layer of each transistor may include: a first region, a second region, and a channel region located between the first region and the second region. A material of the first semiconductor layer may include, for example, polysilicon. The channel region may be not doped with impurities, and has characteristics of a semiconductor. The first region and the second region may be doped regions on two sides of the channel region, and are doped with impurities, and thus have conductivity. The impurities may be different according to a type of a transistor. In some examples, a doped region of the active layer may be interpreted as a source or a drain of a transistor. A part of active layers between transistors may be interpreted as wiring doped with impurities, and may be used for electrically connecting the transistors. The present embodiment is not limited thereto.

In some examples, as shown in FIG. 8, in the pixel circuit, the active layer T10 of the first transistor T1 and the active layer T40 of the fourth transistor T4 may be located on a side of the active layer T30 of the third transistor T3 in the second direction Y. The active layer T50 of the fifth transistor T5, the active layer T60 of the sixth transistor T6, the active layer T70 of the seventh transistor T7, and the active layer T80 of the eighth transistor T8 may be located on a side of the active layer T30 of the third transistor T3 in an opposite direction of the second direction Y. The active layer T30 of the third transistor T3, the active layer T40 of the fourth transistor T4, the active layer T50 of the fifth transistor T5, the active layer T60 of the sixth transistor T6, and the active layer T70 of the seventh transistor T7 of a single pixel circuit may be of an interconnected integrated structure. A first region of the active layer T30 of the third transistor T3 may simultaneously serve as a second region of the active layer T40 of the fourth transistor T4 and a second region of the active layer T50 of the fifth transistor T5. A second region of the active layer T30 of the third transistor T3 may simultaneously serve as a first region of the active layer T60 of the sixth transistor T6. A second region of the active layer T60 of the sixth transistor T6 may simultaneously serve as a second region of the active layer T70 of the seventh transistor T7.

In some examples, the active layer T10 of the first transistor T1, the active layer T40 of the fourth transistor T4, and the active layer T70 of the seventh transistor T7 may be substantially I-shaped. The active layer T30 of the third transistor T3 may be substantially U-shaped. The active layer T60 of the sixth transistor T6, the active layer T80 of the eighth transistor T8 may be substantially L-shaped. The active layer T50 of the fifth transistor T5 may be substantially F-shaped.

In some examples, as illustrated in FIG. 8, the display region AA may include a plurality of pixel circuit groups, and each pixel circuit group may include two pixel circuits disposed adjacently in the first direction X. Each pixel circuit group may be arranged approximately symmetrically about the centerline of the pixel circuit group along the first direction X. The active layers T80 of the eighth transistors of the two pixel circuits in each pixel circuit group may have an integrated structure connected to each other.

In some examples, an orthographic projection of the first bottom structure 411 on the base substrate and an orthographic projection of the active layer T30 of the third transistor T3 of the pixel circuit on the base substrate may at least partially overlap. For example, the orthographic projection of the first bottom structure 411 on the base substrate may cover an orthographic projection of the channel region of the active layer T30 on the base substrate. The first bottom structure 411 of the present example can shield the channel region of the active layer T30 of the third transistor T3, and can reduce the influence of external light on the third transistor, thereby ensuring the performance of the third transistor.

(4) A first conductive layer is formed. In some examples, a second insulation thin film and a first conductive thin film are deposited sequentially on the base substrate on which the aforementioned structures are formed, and the first conductive thin film is patterned through a patterning process to form a second insulation layer and a first conductive layer disposed on the second insulation layer. In some examples, the first conductive layer may also be referred to as a first gate metal layer, and the second insulation layer may also be referred to as a first gate insulation layer.

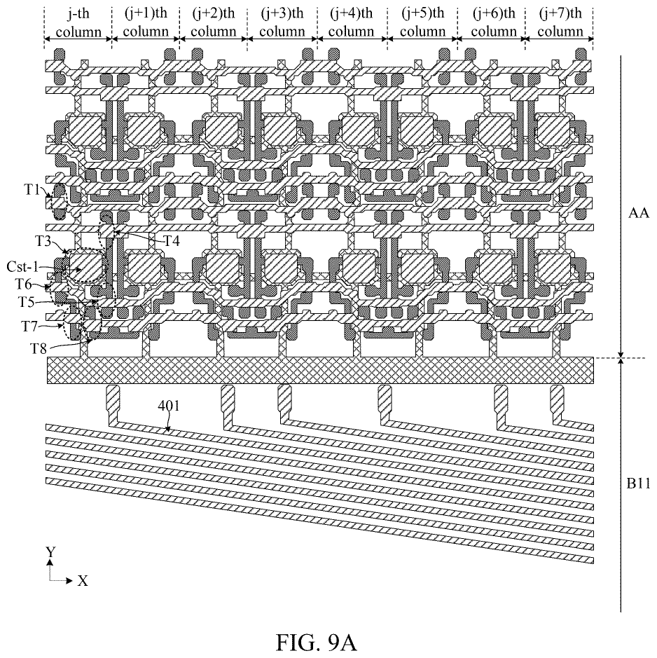

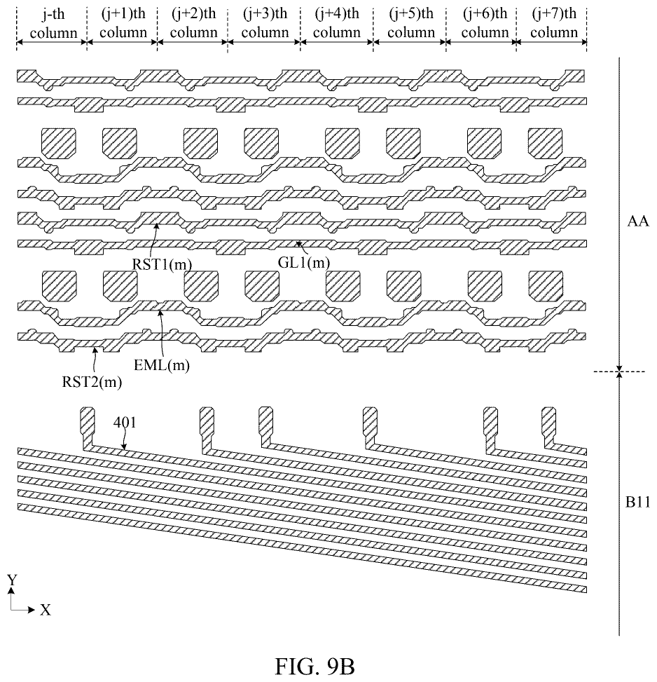

FIG. 9A is a schematic partial view of a display substrate after a first conductive layer is formed in FIG. 6. FIG. 9B is a schematic diagram of a first conductive layer in FIG. 9A. In some examples, as shown in FIGS. 9A and 9B, the first conductive layer in the display region AA may at least include: a first electrode (e.g., a first electrode Cst-1) of the storage capacitor of a plurality of pixel circuits, a plurality of first scan lines (including, for example, a first scan line GL1 (m)), a plurality of first reset control lines (including, for example, a first reset control line RST1 (m)), a plurality of second reset control lines (including, for example, a second reset control line RST2 (m)), and a plurality of light emitting control lines (including, for example, a light emitting control line EML (m)).

In some examples, as shown in FIGS. 9A and 9B, an overlapping region of the first electrode Cst-1 of the storage capacitor with the active layer T30 of the third pixel circuit may serve as a gate of the third transistor T3. An overlapping region of the first scan line GL1 (m) with the active layer T40 of the fourth transistor T4 may serve as a gate of the fourth transistor T4. An overlapping region of the first reset control line RST1 (m) with the active layer T10 of the first transistor T1 may serve as a gate of the first transistor T1. An overlapping region of the second reset control line RST2 (m) with the active layer T70 of the seventh transistor T7 may serve as a gate of the seventh transistor T7, and an overlapping region of the second reset control line RST2 (m) with the active layer T80 of the eighth transistor T8 may serve as a gate of the eighth transistor T8. An overlapping region of the light emitting control line EML (m) with the active layer T50 of the fifth transistor T5 may serve as a gate of the fifth transistor T5, and an overlapping region of the light emitting control line EML (m) with the active layer T60 of the sixth transistor T6 may serve as a gate of the sixth transistor T6.

In some examples, as shown in FIGS. 9A and 9B, the first conductive layer in the second fan-out region B11 may include at least: a plurality of first data fan-out lines 401. The plurality of first data fan-out lines 401 may be sequentially arranged along the first direction X and extend to the side of the bend region.

(5) A second conductive layer is formed. In some examples, a third insulation thin film and a second conductive thin film are sequentially deposited on the base substrate on which the above-mentioned structures are formed, and the second conductive thin film is patterned through a patterning process to form a third insulation layer and a second conductive layer disposed on the third insulation layer. In some examples, the second conductive layer may also be referred to as a second gate metal layer and the third insulation layer may also be referred to as a second gate insulation layer.

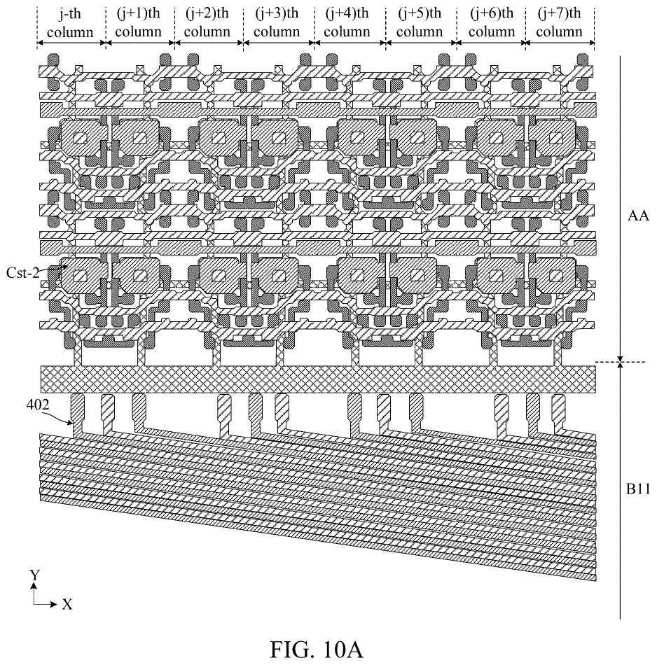

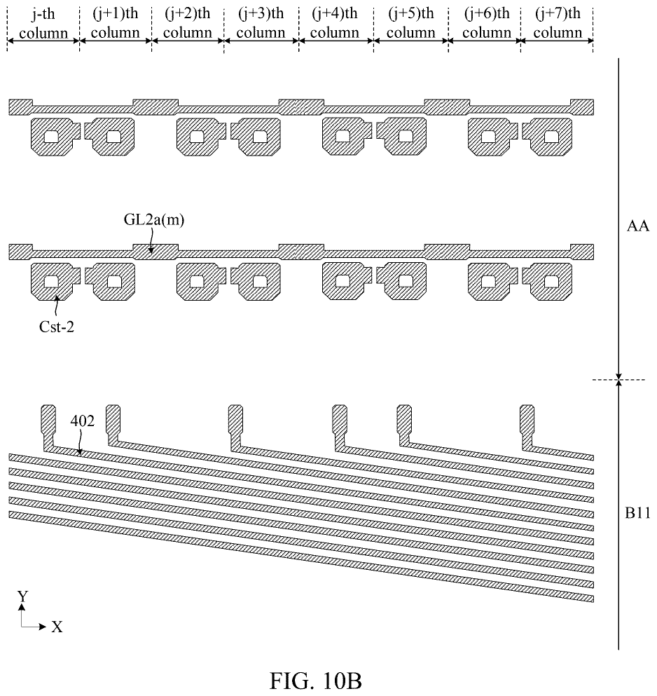

FIG. 10A is a schematic partial view of a display substrate after a second conductive layer is formed in FIG. 6. FIG. 10B is a schematic diagram of a second conductive layer in FIG. 10A. In some examples, as shown in FIGS. 10A and 10B, the second conductive layer of the display region AA may at least include: a second electrode of the storage capacitor of the plurality of pixel circuits (e.g., a second electrode Cst-2), a plurality of second scan auxiliary lines (such as including a second scan auxiliary line GL2a (m)). The second scan auxiliary line GL2a (m) may be located on a side of the second electrode Cst-2 of the storage capacitor of the corresponding pixel circuit in the second direction Y.

In some examples, as shown in FIGS. 10A and 10B, the second conductive layer in the second fan-out region B11 may include at least: a plurality of second data fan-out lines 402. The plurality of second data fan-out lines 402 may be sequentially arranged along the first direction X and extend to one side of the bend region. The plurality of second data fan-out lines 402 and the plurality of first data fan-out lines 401 may be arranged at intervals along the first direction X, and the orthographic projections of the first data fan-out lines 401 and the second data fan-out lines 402 on the base substrate may not overlap.

(6) A second semiconductor layer is formed. In some examples, a fourth insulation thin film and a second semiconductor thin film are sequentially deposited on the base substrate on which the aforementioned patterns are formed, and the second semiconductor thin film is patterned through a patterning process to form a fourth insulation layer and a second semiconductor layer disposed on the fourth insulation layer. In some examples, a material of the second semiconductor layer may include Indium Gallium Zinc Oxide (IGZO). In some examples, the fourth insulation layer may also be referred to as a third gate insulation layer.

FIG. 11 is a schematic partial view of a display substrate after a second semiconductor layer is formed in FIG. 6. In some examples, as shown in FIG. 11, the second semiconductor layer of the display region AA may at least include active layers of second-type transistors of a plurality of pixel circuits, for example, including an active layer T20 of the second transistor T2. The active layer T20 of the second transistor T2 may be in a generally L-shaped. An orthographic projection of the active layer T20 of the second transistor T2 on the base substrate may be located between the active layer T10 of the first transistor T1 and the active layer T50 of the fifth transistor T5 in the second direction Y.

(7) A third conductive layer is formed. In some examples, a fifth insulation thin film and a third conductive thin film are sequentially deposited on the base substrate on which the above-mentioned patterns are formed, and the third conductive thin film is patterned through a patterning process to form a fifth insulation layer and a third conductive layer disposed on the fifth insulation layer. In some examples, the third conductive layer may also be referred to as a third gate metal layer, and the fifth insulation layer may also be referred to as a fourth gate insulation layer.

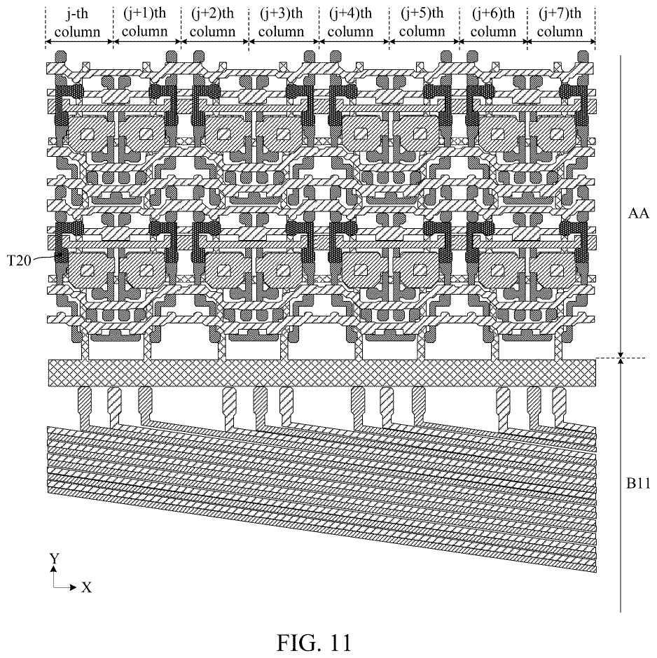

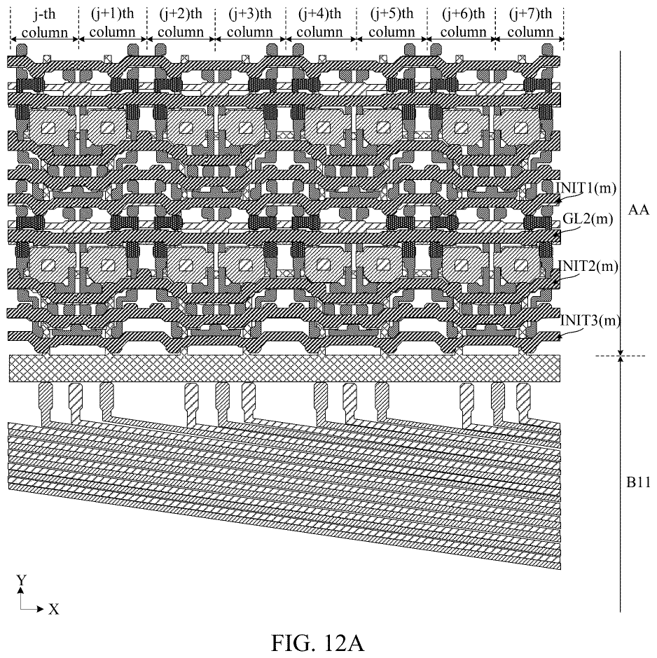

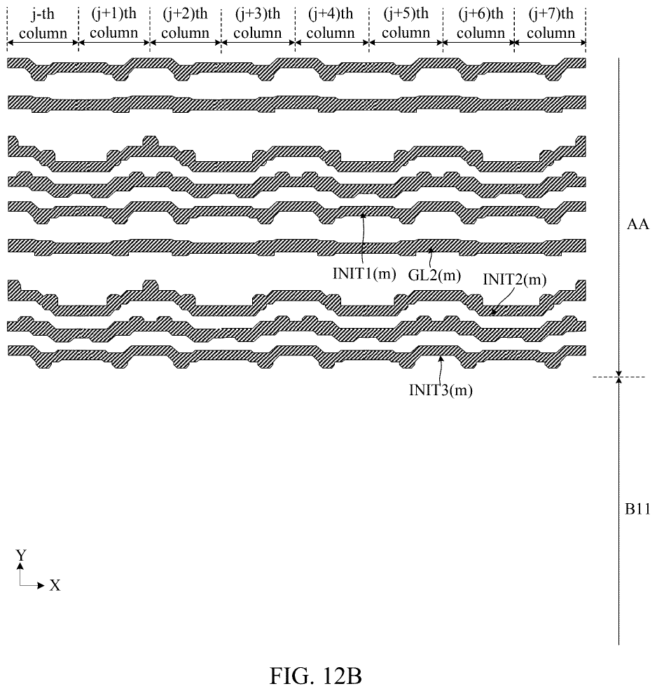

FIG. 12A is a schematic partial view of a display substrate after a third conductive layer is formed in FIG. 6. FIG. 12B is a schematic diagram of a third conductive layer in FIG. 12A. In some embodiments, as shown in FIGS. 12A and 12B, the third conductive layer in the display region AA may at least include: a plurality of first initial signal lines (e.g., including a first initial signal line INIT1 (m)), a plurality of second initial signal lines (e.g., including a second initial signal line INIT2 (m)), a plurality of third initial signal lines (e.g., including a third initial signal line INIT3 (m)), and a plurality of second scan lines (e.g., including a second scan line GL2 (m)).

In some examples, the first initial signal line INIT1 (m), the second initial signal line INIT2 (m), the third initial signal line INIT3 (m), and the second scan line GL2 (m) may have a general bend line shape extending in the first direction X. The first initial signal line INIT1 (m), the second scan line GL2 (m), the second initial signal line INIT2 (m), and the third initial signal line INIT3 (m) may be sequentially arranged in a direction opposite to the second direction Y. An invalid first initial signal line may also be provided between the second initial signal line INIT2 (m) and the third initial signal line INIT3 (m).

In some examples, an overlapping region of the second scan line GL2 (m) and the active layer T20 of the second transistor T2 may serve as a gate of the second transistor T2. An overlapping region of the second scan auxiliary line GL2a (m) and the active layer T20 of the second transistor T2 may serve as a bottom gate of the second transistor T2. The second scan auxiliary line GL2a (m) and the second scan line GL2 (m) may be connected in the second bezel region to transmit the same second scan signal. However, the present embodiment is not limited thereto.

(8) A sixth insulation layer is formed. In some examples, a sixth insulation thin film is deposited on the base substrate on which the aforementioned patterns are formed, and the sixth insulation thin film is patterned through a patterning process to form a sixth insulation layer. In some examples, the sixth insulation layer may also be referred to as an interlayer insulation layer. The sixth insulation layer may be provided with a plurality of vias.

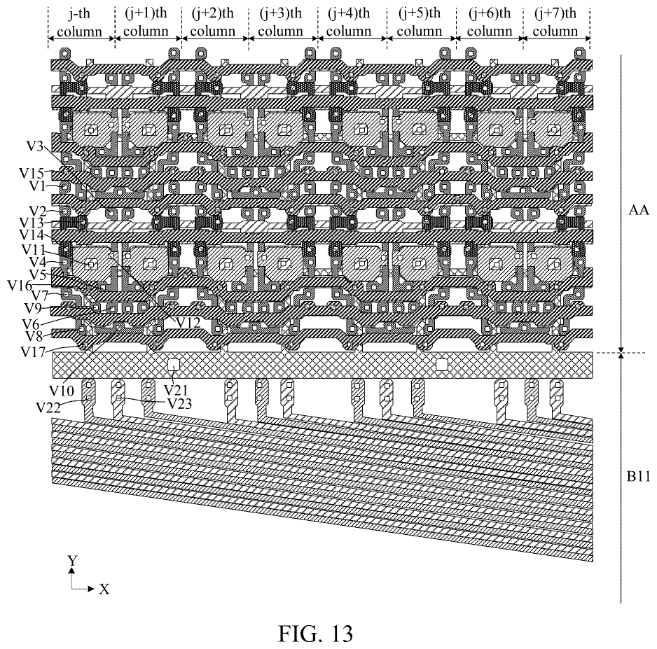

FIG. 13 is a schematic partial view of a display substrate after a sixth insulation layer is formed in FIG. 6. In some examples, as shown in FIG. 13, the plurality of vias formed in the sixth insulation layer of the display region AA may include: a first via V1 to a tenth via V10, an eleventh via V11, a twelfth via V12, a thirteenth via V13, a fourteenth via V14, and a fifteenth via V15 to a seventeenth via V17. In the first via V1 to the tenth via V10, the sixth insulation layer, the fifth insulation layer, the fourth insulation layer, the third insulation layer, and the second insulation layer may be removed, exposing a portion of the surface of the first semiconductor layer. The sixth insulation layer, the fifth insulation layer, the fourth insulation layer, and the third insulation layer in the eleventh via V11 may be removed to expose a portion of the surface of the first conductive layer. The sixth insulation layer, the fifth insulation layer, and the fourth insulation layer in the twelfth via V12 may be removed to expose a portion of the surface of the second conductive layer. The sixth insulation layer and the fifth insulation layer in the thirteenth via V13 and the fourteenth via V14 may be removed to expose a portion of the surface of the second semiconductor layer. The sixth insulation layer in the fifteenth via V15 to the seventeenth via V17 may be removed to expose a portion of the surface of the third conductive layer.

In some examples, as shown in FIG. 13, the plurality of vias formed in the sixth insulation layer of the second fan-out region B11 may include: a plurality of twenty-first vias V21, a plurality of twenty-second vias V22, and a plurality of twenty-third vias V23. The sixth insulation layer, the fifth insulation layer, the fourth insulation layer, the third insulation layer, the second insulation layer, and the first insulation layer in the plurality of twenty-first vias V21 may be removed to expose a portion of the surface of the bottom shielding layer. The sixth insulation layer, the fifth insulation layer, the fourth insulation layer, and the third insulation layer in the plurality of twenty-second vias V22 may be removed to expose a portion of the surface of the first conductive layer. The sixth insulation layer, the fifth insulation layer, and the fourth insulation layer in the plurality of twenty-third vias V23 may be removed to expose a portion of the surface of the second conductive layer.

(9) A fourth conductive layer is formed. In some examples, a fourth conductive thin film is deposited on the base substrate on which the aforementioned patterns are formed, and the fourth conductive thin film is patterned through a patterning process to form a fourth conductive layer on the sixth insulation layer. In some examples, the fourth conductive layer may also be referred to as a first source-drain metal layer.

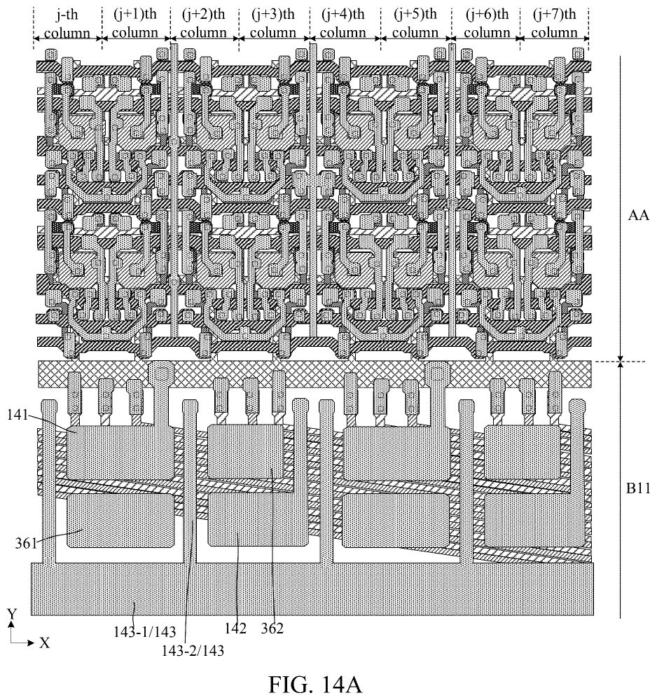

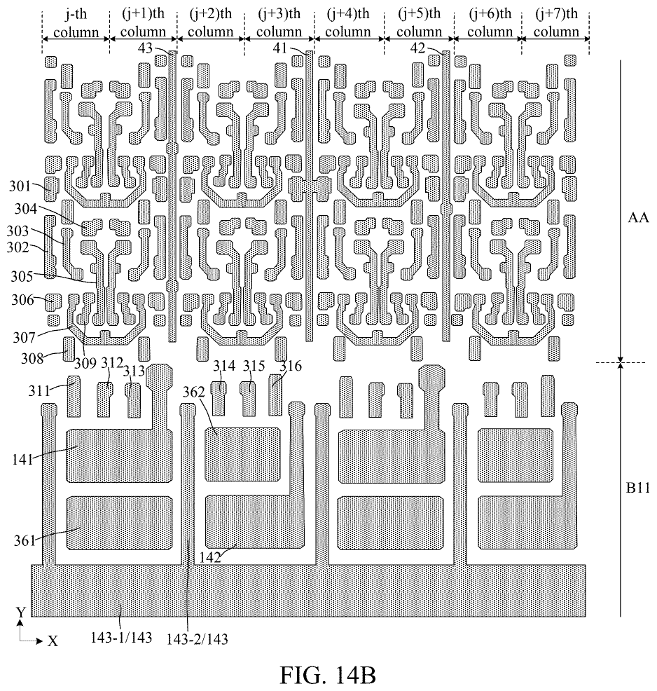

FIG. 14A is a schematic partial view of a display substrate after a fourth conductive layer is formed in FIG. 6. FIG. 14B is a schematic diagram of a fourth conductive layer in FIG. 14A. In some examples, as shown in FIGS. 14A and 14B, the fourth conductive layer of the display region AA may at least include: a plurality of pixel connection electrodes (e.g., including the first pixel connection electrode 301 to the ninth pixel connection electrode 309), a plurality of initial transmission lines (e.g., including a first initial transmission line 41, a second initial transmission line 42, and a third initial transmission line 43).

In some examples, the first pixel connection electrode 301 may be connected to the first region of the active layer T10 of the first transistor T1 through the first via V1, and may be connected to the first initial signal line INIT1 (m) through the fifteenth via V15. The second pixel connection electrode 302 may be connected to the second region of the active layer T10 of the first transistor T1 through the second via V2, may be connected to the second region of the active layer T30 of the third transistor T3 through the fourth via V4, and may be connected to the first region of the active layer T20 of the second transistor T2 through the fourteenth via V14. The second pixel connection electrode 302 may achieve electrical connections between the first transistor T1, the second transistor T2, the third transistor T3, and the sixth transistor T6, and it may serve as the third node N3 of the pixel circuit. The third pixel connection electrode 303 may be connected to the second region of the active layer T20 of the second transistor T2 through the thirteenth via V13, and may be connected to the first electrode Cst-1 of the storage capacitor through the eleventh via V11. The third pixel connection electrode 303 may achieve electrical connection between the second transistor T2, the storage capacitor, and the third transistor T3, and may serve as the first node N1 of the pixel circuit. The fourth pixel connection electrode 304 may be connected to the first region of the active layer T40 of the fourth transistor T4 through the third via V3. The fifth pixel connection electrode 305 may be connected to the second electrode Cst-2 of the storage capacitor through the twelfth via V12, and may be connected to the first region of the fifth active layer T50 of the fifth transistor T5 through the sixth via V6. The sixth pixel connection electrode 306 may be connected to the second region of the active layer T60 of the sixth transistor T6 through the seventh via V7. The seventh pixel connection electrode 307 may be connected to the third initial signal line INIT3 (m) through the sixteenth via V16, and may be connected to the first region of the active layer T80 of the eighth transistor T8 through the tenth via V10. The eighth pixel connection electrode 308 may be connected to the first region of the active layer T70 of the seventh transistor T7 through the eighth via V8, and may be connected to the second initial signal line INIT2 (m) through the seventeenth via V17. The ninth pixel connection electrode 309 may be connected to the second region of the active layer T80 of the eighth transistor T8 through the ninth via V9, and may be connected to the second region of the active layer T50 of the fifth transistor T5 through the fifth via V5.

In some examples, the first initial transmission line 41, the second initial transmission line 42, and the third initial transmission line 43 may be in the shape of a strip extending in the second direction Y. The first initial transmission line 41 may be connected to the first initial signal line INIT1 (m), and for example, the first initial transmission line 41 and two adjacent first pixel connection electrodes may have an integrated structure connected to each other, thereby achieving the connection with the first initial signal line INIT1 (m). The second initial transmission line 41 extending in the second direction Y is connected to the first initial signal line extending in the first direction X, and a mesh structure for transmitting the first initial signal may be formed in the display region AA, which is beneficial to the transmission stability and uniformity of the first initial signal. The second initial transmission line 42 extending in the second direction Y is connected to the second initial signal line extending in the first direction X, and a mesh structure for transmitting the second initial signal may be formed in the display region AA, which is beneficial to the transmission stability and uniformity of the second initial signal. The third initial transmission line 43 extending in the second direction Y is connected to the third initial signal line (for example, the third initial signal line INIT3 (m)) extending in the first direction X, and a mesh structure for transmitting the third initial signal may be formed in the display region AA, which is beneficial to transmission stability and uniformity of the third initial signal.

In some examples, the first initial transmission line 41 may be located between two adjacent groups of pixel circuits, such as between a (j+3)th column of pixel circuit and a (j+4)th column of pixel circuit. The second initial transmission line 42 may be located between two adjacent groups of pixel circuits, such as between the (j+5)th column of pixel circuits and the (j+6)th column of pixel circuits. The third initial transmission line 43 may be located between two adjacent groups of pixel circuits, such as between the pixel circuits of the (j+1)th column and the pixel circuit of the (j+2)th column.

In some examples, as shown in FIGS. 14A and 14B, the fourth conductive layer of the second fan-out region B11 may at least include: a plurality of bezel transfer electrodes (for example, including a first bezel transfer electrode 311, a second bezel transfer electrode 312, a third bezel transfer electrode 313, a fourth bezel transfer electrode 314, a fifth bezel transfer electrode 315, and a sixth bezel transfer electrode 316), a plurality of first-type voltage transfer electrodes (for example, including a plurality of first voltage transfer electrodes 141, a plurality of second voltage transfer electrodes 142, and a plurality of third voltage transfer electrodes 143), and a plurality of auxiliary electrodes (for example, including a first auxiliary electrode 361 and a second auxiliary electrode 362).

In some examples, a plurality of bezel transfer electrodes may be arranged along the first direction X and located on a side of the first-type voltage connection electrode and the plurality of auxiliary electrodes close to the display region AA. The first bezel transfer electrode 311 may be connected to a second data fan-out line 402 through two twenty-second vias V22 arranged vertically. The second bezel transfer electrode 312 may be connected to a first data fan-out line 401 through two twenty-third vias V23 arranged vertically. The fifth bezel transfer electrode 315 may be connected to a second data fan-out line 402, and the sixth bezel transfer electrode 316 may be connected to a first data fan-out line 401. The third bezel transfer electrode 313 may be connected to a second data fan-out line 402 located on the second conductive layer. The fourth bezel transfer electrode 314 may be connected to a first data fan-out line 401 located on the first conductive layer.

In some examples, the first voltage transfer electrode 141 may have a first main body portion and a first protrusion portion, and the first main body portion and the first protrusion portion have an integrated structure connected to each other. The shape of the first main body portion may be substantially rectangular, and the shape of the first protrusion portion may be substantially dumbbell-shaped extending in the second direction Y. The first main body portion may be located on a side of the first bezel transfer electrode 311, the second bezel transfer electrode 312, and the third bezel transfer electrode 313 away from the display region AA, and the first protrusion portion may be located on a side of the third bezel transfer electrode 313 in the first direction X. The first protrusion portion of the first voltage transfer electrode 141 may be connected to the second bottom structure 412 of the bottom shield layer through the twenty-first via V21.

In some examples, the second voltage transfer electrode 142 may have a second main body portion and a second protrusion portion. The second main body portion and the second protrusion portion have an integrated structure connected to each other. The shape of the second main body portion may be substantially rectangular, and the shape of the second protrusion portion may be substantially strip-shaped extending in the second direction Y. The second protrusion portion may be located on a side of the sixth bezel transfer electrode 316 in the first direction X. The second main body portion may be located on a side of the fourth bezel transfer electrode 314, the fifth bezel transfer electrode 315, and the sixth bezel transfer electrode 316 away from the display region AA.

In some examples, the third voltage transfer electrode 143 may have a third main body portion 143-1 and a plurality of third protrusion portions 143-2. The third main body portion 143-1 and the plurality of third protrusion portions 143-2 may have an integrated structure connected to each other. The third main body portion 143-1 may have a substantially strip shape extending in the first direction X. The third protrusion portion 143-2 may have a substantially strip shape extending in the second direction Y. The plurality of third protrusions 143-2 may be located on a side of the third main body portion 143-1 close to the display region AA. The plurality of third protrusion portions 143-2 and the third main body portion 143-1 may be connected to form a plurality of accommodation regions, and the first voltage transfer electrode 141 and the second voltage transfer electrode 142 may be arranged at intervals in the plurality of accommodation regions. In other words, one first voltage transfer electrode 141 or one second voltage transfer electrode 142 may be provided between two adjacent third protrusion portions 143-2. In the first direction X, the third protrusion portion 143-2, the first voltage transfer electrode 141, the third protrusion portion 143-2, and the second voltage transfer electrode 142 may be periodically arranged.

In some examples, the first auxiliary electrode 361 may be located on a side of the first voltage transfer electrode 141 away from the display region AA, and on a side of the third main body portion 143-1 of the third voltage transfer electrode 143 close to the display region AA. The first auxiliary electrode 361 may be substantially a rectangle. The second auxiliary electrode 362 may be located on a side of the second main body portion of the second voltage transfer electrode 142 close to the display region AA. The second auxiliary electrode 362 may be substantially a rectangle. In this example, by providing the first auxiliary electrode 361 and the second auxiliary electrode 362, it is advantageous to ensure the uniformity of the film pattern.

(10) A seventh insulation layer and an eighth insulation layer are formed. In some examples, a seventh insulation thin film is deposited on the base substrate on which the aforementioned patterns are formed, and the seventh insulation thin film is patterned through a patterning process to form the seventh insulation layer; subsequently, an eighth insulation thin film is coated and then patterned through a patterning process, to form an eighth insulation layer. In some examples, the seventh insulation layer may also be referred to as a passivation layer and the eighth insulation layer may also be referred to as a first planarization layer.

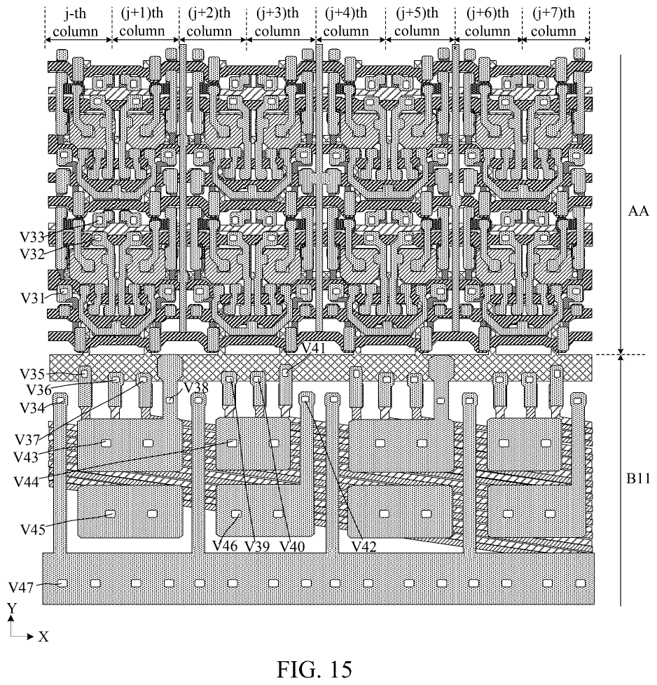

FIG. 15 is a schematic partial view of a display substrate after an eighth insulation layer is formed in FIG. 6. In some examples, as shown in FIG. 15, the plurality of vias formed in the eighth insulation layer of the display region AA may include: a thirty-first via V31 to a thirty-third via V33. The seventh insulation layer and the eighth insulation layer in the thirty-first via V31 to the thirty-third via V33 may be removed to expose a portion of the surface of the fourth conductive layer.

In some examples, as shown in FIG. 15, the plurality of vias formed in the eighth insulation layer of the second fan-out region B11 may include: a thirty-fourth via V34 to a forty-seventh via V47. The seventh insulation layer and the eighth insulation layer in the thirty-fourth via V34 to the forty-seventh via V47 may be removed to expose a portion of the surface of the fourth conductive layer.

(11) A fifth conductive layer is formed. In some examples, a fifth conductive thin film is deposited on the base substrate on which the aforementioned patterns are formed, and the fifth conductive thin film is patterned through a patterning process to form a fifth conductive layer on the eighth insulation layer. In some examples, the fifth conductive layer may also be referred to as a second source-drain metal layer.

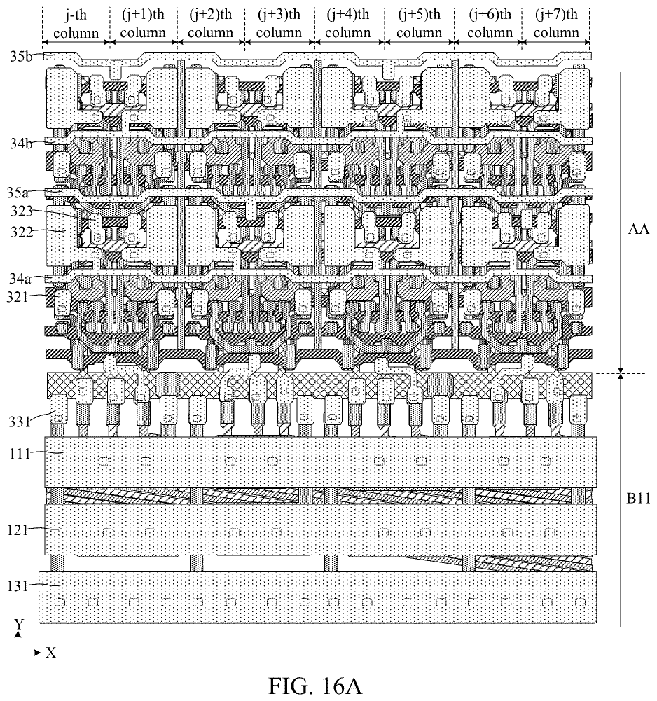

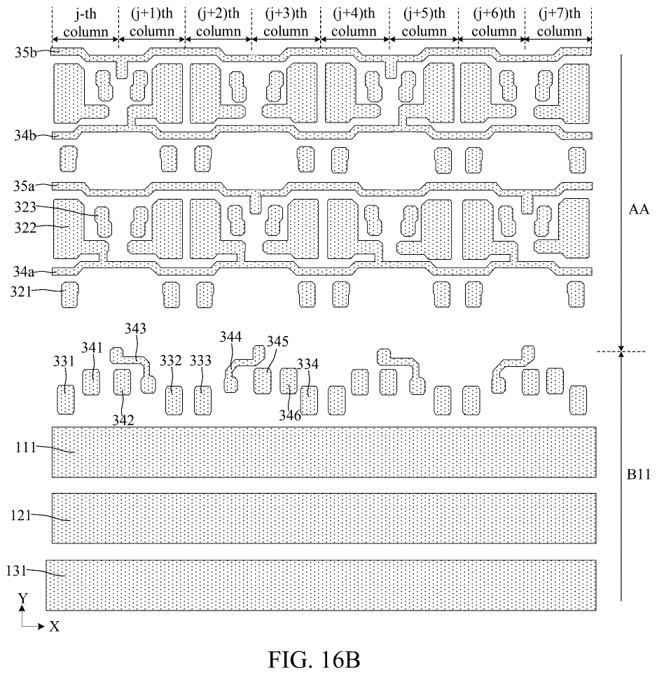

FIG. 16A is a schematic partial view of a display substrate after a fifth conductive layer is formed in FIG. 6. FIG. 16B is a schematic diagram of a fifth conductive layer in FIG. 16A. In some examples, as illustrated in FIGS. 16A and 16B, the fifth conductive layer of the display region AA may at least include: a plurality of first anode connection electrodes 321, a plurality of data connection electrodes 323, a plurality of first power connection blocks 322, a plurality of first power horizontal transmission lines (such as including first power horizontal transmission lines 34a and 34b), and a plurality of first data transfer lines (such as including first data transfer lines 35a and 35b).

In some examples, the first anode connection electrode 321 may be connected to the sixth pixel connection electrode 306 through the thirty-first via V31, thereby achieving electrical connection to the second electrode of the sixth transistor T6 of the pixel circuit. The data connection electrode 323 may be connected to the fourth pixel connection electrode 304 through the thirty-third via V33, thereby achieving electrical connection to the first electrode of the fourth transistor T4 of the pixel circuit. The first power connection block 322 may be connected to the fifth pixel connection electrode 305 through the thirty-second via V32, thereby achieving electrical connection to the fifth transistor T5 and the second electrode of the storage capacitor in the pixel circuit.

In some examples, the shape of the first power horizontal transmission lines 34a and 34b may generally be bend lines extending along the first direction X. The first power horizontal transmission line 34a and the first power connection block 322 of the pixel circuits in the j-th column, the (j+2)th column, the (j+4)th column, and the (j+6)th column of the last row may have an integrated structure connected to each other. The first power horizontal transmission line 34a may be connected to the subsequently formed first power line VDD3 in the display region AA to form a mesh structure, and is configured to transmit the first voltage signal Vdd3, so that transmission uniformity and stability of the first voltage signal Vdd3 can be ensured. The first power horizontal transmission line 34b and the first power connection lines of the pixel circuits in the (j+1)th column and the (j+5)th column of the second-to-last row may have an integrated structure connected to each other. The first power horizontal transmission line 34b may be connected to the subsequently formed first power line VDD1 in the display region AA to form a mesh structure, and is configured to transmit the first voltage signal Vdd1, thereby ensuring transmission uniformity and stability of the first voltage signal Vdd1. Similarly, the display region may further include a first power horizontal transmission line connected to the first power line VDD2. The first power horizontal transmission lines transmitting different first voltage signals may be arranged at intervals in the second direction Y.

In some examples, the shape of the first data transfer lines 35a and 35b may generally be a bend line extending along the first direction X. In this example, by providing the first data transfer line, it is possible to facilitate centralized fan-out of the data fan-out lines, which is beneficial to the narrow bezel design.

In some examples, as shown in FIGS. 16A and 16B, the fifth conductive layer of the second fan-out region B11 may at least include: a plurality of bezel transfer electrodes (including, for example, a seventh bezel transfer electrode 341, an eighth bezel transfer electrode 342, a ninth bezel transfer electrode 343, a tenth bezel transfer electrode 344, an eleventh bezel transfer electrode 345, and a twelfth bezel transfer electrode 346), a plurality of bezel power connection electrodes (including, for example, a first bezel power connection electrode 331, a second bezel power connection electrode 332, a third bezel power connection electrode 333, and a fourth bezel power connection electrode 334), and a plurality of second power supply lines (including, for example, second power supply lines 111, 121 and 131).

In some examples, the shape of the seventh bezel transfer electrode 341, the eighth bezel transfer electrode 342, the tenth bezel transfer electrode 344, and the eleventh bezel transfer electrode 345 may be generally rectangular; and the ninth bezel transfer electrode 343 and the twelfth bezel transfer electrode 346 may have a substantially L-shaped shape. The seventh bezel transfer electrode 341 may be connected to the first bezel transfer electrode 311 through the thirty-fifth via V35. The eighth bezel transfer electrode 342 may be connected to the second bezel transfer electrode 312 through the thirty-sixth via V36. The ninth bezel transfer electrode 343 may be connected to the third bezel transfer electrode 313 through the thirty-seventh via V37. The tenth bezel transfer electrode 344 may be connected to the fourth bezel transfer electrode 314 through the thirty-ninth via V39. The eleventh bezel transfer electrode 345 may be connected to the fifth bezel transfer electrode 315 through the fortieth via V40. The twelfth bezel transfer electrode 346 may be connected to the sixth bezel transfer electrode 316 through the forty-first via V41.

In some examples, the shape of the first bezel power connection electrode 331, the second bezel power connection electrode 332, the third bezel power connection electrode 333, and the fourth bezel power connection electrode 334 may be substantially rectangular. The first bezel power connection electrode 331 may be connected to one of the third protrusion portions 143-2 of the third voltage transfer electrode 143 through the thirty-fourth via V34. The second bezel power connection electrode 332 may be connected to the first voltage transfer electrode 141 through the thirty-eighth via V38. The third bezel power connection electrode 333 may be connected to another third protrusion portion 143-2 of the third voltage transfer electrode 143. The fourth bezel power connection electrode 334 may be connected to the second voltage transfer electrode 142 through the forty-second via V42.

In some examples, the second power supply lines 111, 121, and 131 may be generally strip-shaped and extend along the first direction X. The second power supply line 111 may be connected to the first main body portion of the first voltage transfer electrode 141 through the plurality of forty-third vias V43, and may be connected to the second auxiliary electrode 362 through the plurality of forty-fourth vias V44. The second power supply line 121 may be connected to the first auxiliary electrode 361 through a plurality of forty-fifth vias V45, or may be connected to the second main body portion of the second voltage transfer electrode 142 through a plurality of forty-sixth vias V46. The second power supply line 131 may be connected to the third main body portion of the third voltage transfer electrode 143 through the plurality of forty-seventh vias V47.

(12) A ninth insulation layer is formed. In some examples, an ninth insulation thin film is coated on the base substrate on which the aforementioned patterns are formed, and the ninth insulation thin film is patterned through a patterning process to form a ninth insulation layer. In some examples, the ninth insulation layer may also be referred to as a second planarization layer.

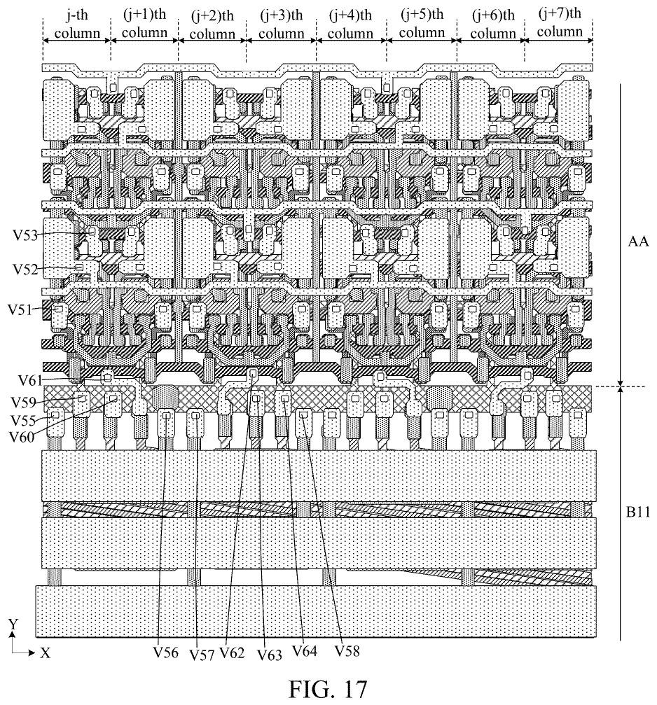

FIG. 17 is a schematic partial view of a display substrate after a ninth insulation layer is formed in FIG. 6. In some examples, as shown in FIG. 17, the plurality of vias formed in the ninth insulation layer of the display region AA may include: a fifty-first via V51 to a fifty-third via V53. The plurality of vias provided on the ninth insulation layer of the second fan-out region B11 may include a fifty-fifth via V55 to a sixty-fourth via V64. The ninth insulation layer in the fifty-first via V51 to the fifty-third via V53 and the fifty-fifth via V55 to the sixty-fourth via V64 may be removed to expose a portion of the surface of the fifth conductive layer.

(13) A sixth conductive layer is formed. In some examples, a sixth conductive thin film is deposited on the base substrate on which the aforementioned patterns are formed, the sixth conductive thin film is patterned through a patterning process to form a sixth conductive layer on the ninth insulation layer. In some examples, the sixth conductive layer may also be referred to as a third source-drain metal layer.

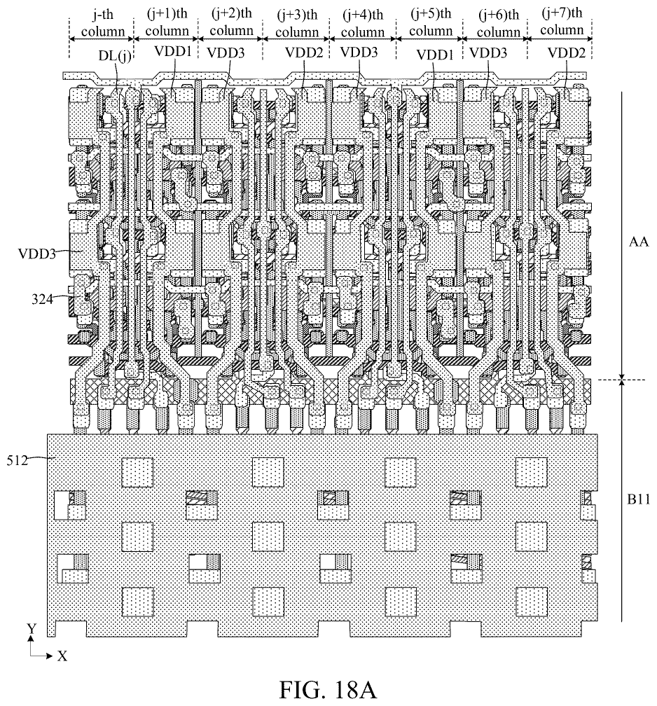

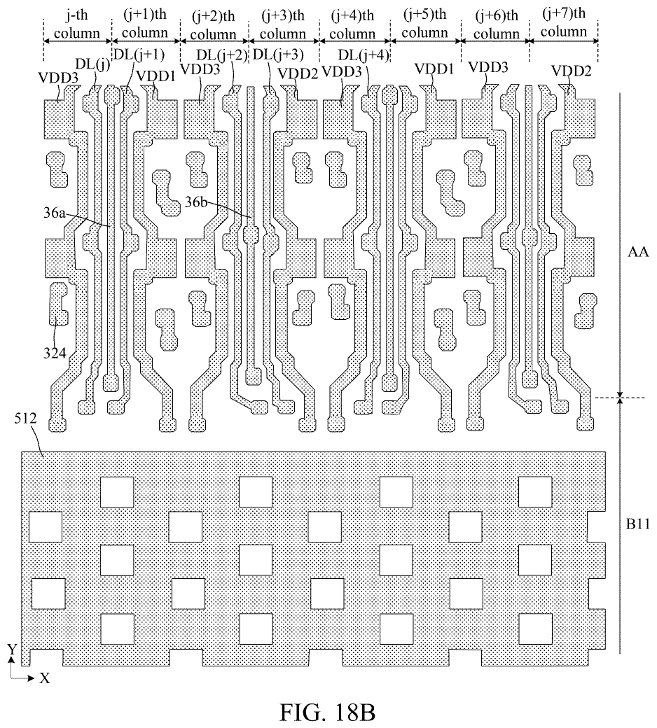

FIG. 18A is a schematic partial view of a display substrate after a sixth conductive layer is formed in FIG. 6. FIG. 18B is a schematic diagram of a sixth conductive layer in FIG. 18A. In some examples, as shown in FIGS. 18A and 18B, the sixth conductive layer of the display region AA may at least include: a plurality of second anode connection electrodes 324, a plurality of data lines (e.g., including data lines DL (j), DL (j+1), DL (j+2), DL (j+3), DL (j+4)), a plurality of first power supply lines (e.g., including first power lines VDD1, VDD2, and VDD3), and a plurality of second data transfer lines (e.g., including second data transfer lines 36a and 36b).

In some examples, the second anode connection electrode 324 may be connected to the first anode connection electrode 321 through the fifty-first via V51, thereby achieving electrical connection to the sixth transistor T6 of the pixel circuit. The plurality of data lines may generally be in a bend line shape extending along the second direction Y. For example, the data line DL (j) may be connected to the data connection electrode 323 through the fifty-third via V53, thereby achieving electrical connection to the fourth transistor T4 of the pixel circuit. The second data transfer lines 36a and 36b may have a straight line shape extending in the second direction Y. For example, the second data transfer line 36b may be connected to the first data transfer line 35a, and the second data transfer line 36a may be connected to the first data transfer line 35b.

In some examples, the first power lines VDD1, VDD2, and VDD3 may be substantially bend lines extending in the second direction Y, and the first power lines VDD1, VDD2, and VDD3 may be non-equal width lines. The first power line VDD3 located in the j-th column may be electrically connected to the first power supply connection block 322 through the fifty-second via V52, and may achieving electrical connection to the first power horizontal transmission line 34a, the fifth transistor T5 and the storage capacitor of the pixel circuit.

In some examples, as shown in FIGS. 18A and 18B, the sixth conductive layer of the second fan-out region B11 may include at least a second sub-line 512 of the second voltage fan-out line. The second voltage fan-out line may be a double-layer line, for example, including a first sub-line located in a fifth conductive layer and a second sub-line 512 located in the sixth conductive layer. The second sub-line 512 may have a plurality of first hollow portions, and an orthographic projection of the first hollow portion on the base substrate may be substantially rectangular. In this example, by providing a plurality of first hollow portions in the second sub-line 512, it is possible to facilitate the exhaust of the ninth insulation layer below a large area of metal block.

In some examples, the data line DL (j) connected to the pixel circuit of the j-th column may extend to the second fan-out region B11 and is connected to the seventh bezel transfer electrode 341 through the fifty-ninth via V59. The data line DL (j+1) connected to the pixel circuit of the (j+1)th column may extend to the second fan-out region B11 and be connected to the eighth bezel transfer electrode 342 through the sixtieth via V60. The second data transfer line 36a located between the data lines DL (j) and DL (j+1) may be connected to the ninth bezel transfer electrode 343 through the sixty-first via V61. The data line DL (j+2) connected to the pixel circuit of the (j+2)th column may extend to the second fan-out region B11 and be connected to the eleventh bezel transfer electrode 345 through the sixty-third via V63. The data line DL (j+3) connected to the pixel circuit of the (j+3)th column may extend to the second fan-out region B11 and be connected to the twelfth bezel transfer electrode 346 through the sixty-fourth via V64. The second data transfer line 36b located between the data lines DL (j+2) and DL (j+3) may be connected to the tenth bezel transfer electrode 344 through the sixty-second via V62. In this example, the data line and the second data transfer line may be connected to the first data fan-out line located in the first conductive layer or the second data fan-out line located in the second conductive layer through the bezel transfer electrodes located in the fifth conductive layer and the fourth conductive layer.

In some examples, the first power line VDD3 connected to the pixel circuit of the j-th column may extend to the second fan-out region B11 and be connected to the first bezel power connection electrode 331 through the fifty-fifth via V55 to achieve the connection with a third protrusion portion 143-2 of the third voltage transfer electrode 143. The first power line VDD1 connected to the pixel circuit of the (j+1)th column may extend to the second fan-out region B11, and may be connected to the second bezel power connection electrode 332 through the fifty-sixth via V56 to achieve the connection with the first protrusion portion of the first voltage transfer electrode 141. The first power line VDD3 connected to the (j+2)th column of pixel circuit may extend to the second fan-out region B11 and be connected to the third bezel power connection electrode 333 through the fifty-seventh via V57 to achieve the connection with another third protrusion portion 143-2 of the third voltage transfer electrode 143. The first power line VDD2 connected to the (j+3)th column of pixel circuit may extend to the second fan-out region B11, and may be connected to the fourth bezel power connection electrode 333 through the fifty-eighth via V58 to achieve the connection with the second protrusion of the second voltage transfer electrode 142.

In some examples, the first power line VDD3 connected to the pixel circuit of the j-th column may be connected to the second power supply line 131 located in the fifth conductive layer through the first bezel power connection electrode 331 located in the fifth conductive layer and the third voltage transfer electrode 143 located in the fourth conductive layer sequentially. The first power line VDD1 connected to the pixel circuit of the (j+1)th column may be connected to the second power supply line 111 located in the fifth conductive layer through the second bezel power connection electrode 332 located in the fifth conductive layer and the first voltage transfer electrode 141 located in the fourth conductive layer sequentially. The first power line VDD3 connected to the (j+2)th column of pixel circuit may be connected to the second power supply line 131 located in the fifth conductive layer through the third bezel power connection electrode 333 located in the fifth conductive layer and the third voltage transfer electrode 143 located in the fourth conductive layer sequentially. The first power line VDD2 connected to the (j+3)th column of pixel circuit may be connected to the second power supply line 121 located in the fifth conductive layer through the fourth bezel power connection electrode 334 located in the fifth conductive layer and the second voltage transfer electrode 142 located in the fourth conductive layer sequentially.

(14) A tenth insulation layer and an anode layer are formed. In some examples, a tenth insulation film is coated on the base substrate on which the aforementioned patterns are formed, and the tenth insulation film is patterned through a patterning process to form a tenth insulation layer. The tenth insulation layer may be provided with a plurality of vias. Subsequently, an anode thin film is deposited, and the anode thin film is patterned through a patterning process to form an anode layer. In some examples, the tenth insulation layer may also be referred to as a third planarization layer.

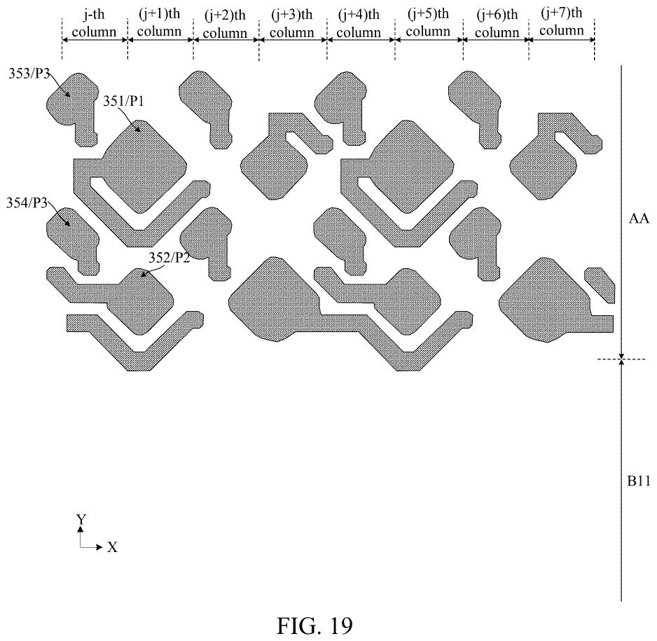

FIG. 19 is a schematic diagram of an anode layer in FIG. 6. In some examples, as shown in FIG. 19, the anode layer may include anodes of a plurality of light emitting elements (such as including an anode 351 of the first light emitting element PX1-2 in the first sub-pixel group P1, an anode 352 of the second light emitting element PX2-2 in the second sub-pixel group P2, an anode 353 of the third light emitting element PX3-2 in the third sub-pixel group P3, and an anode 354 of the fourth light emitting element PX4-2). The anode 353 of the third light emitting element PX 3-2 may be connected to the pixel circuit in the j-th column of the second-to-last row through a via provided on the tenth insulation layer. The anode 354 of the fourth light emitting element PX 4-2 may be connected to the pixel circuit of the j-th column in the last row through a via provided on the tenth insulation layer. The anode 351 of the first light emitting element PX1-2 may be connected to a pixel circuit in the (j+1)th column of the second-to-last row. The anode 352 of the second light emitting element PX2-2 may be connected to the pixel circuit of the (j-1)th column of the last row. In the present example, the anodes of the first light emitting element and the second light emitting element may be connected to the corresponding pixel circuits by a winding, for example, the winding and the anodes to which it is connected to may have an integrated structure connected to each other.

In some examples, the pixel circuits in the same column may be connected to light emitting elements emitting light of the same color, such that different first power lines may provide first voltage signals to light emitting elements emitting light of different colors. For example, the pixel circuit of the j-th column is connected to the first power line VDD 3 and is connected to a plurality of light emitting elements emitting light of a third color (for example, green light). The pixel circuit of the (j+1)th column is connected to the first power line VDD1 and to a plurality of light emitting elements emitting light of a first color (for example, blue light). The (j+2)th column of pixel circuit is connected to the first power line VDD 3 and to a plurality of light emitting elements emitting light of a third color (for example, green light). The (j+3)th column of pixel circuits are connected to the first power line VDD 2 and to a plurality of light emitting elements emitting light of a second color (for example, red light).

In some examples, after the anode layer is formed, a pixel define layer, an organic light emitting layer, and a cathode layer may be sequentially provided.

In some examples, the first conductive layer, the second conductive layer, the third conductive layer, the fourth conductive layer, the fifth conductive layer, and the sixth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The first insulation layer, the second insulation layer, the third insulation layer, the fourth insulation layer, the fifth insulation layer, the sixth insulation layer, and the seventh insulation layer may be made of any one or more of Silicon Oxide (SiOx, x>0), Silicon Nitride (SiNy, y>0), and Silicon OxyNitride (SiON), and may be a single layer, a multi-layer, or a composite layer. The eighth insulation layer to the tenth insulation layer may be made of an organic material, such as polyimide, acrylic, or polyethylene terephthalate. However, the present embodiment is not limited thereto.

The structure and the preparation process of the display substrate of the embodiments are merely illustrative. In some examples, a corresponding structure may be changed and a patterning process may be added or reduced according to actual needs. For example, the fifth conductive layer or the sixth conductive layer may be omitted. As another example, providing the bottom shield layer may be omitted. Preparation processes in the exemplary embodiment may be implemented using an existing mature preparation device, and may be compatible well with existing preparation processes, simple in process implementation, easy to implement, high in a production efficiency, low in a production cost, and high in a yield.

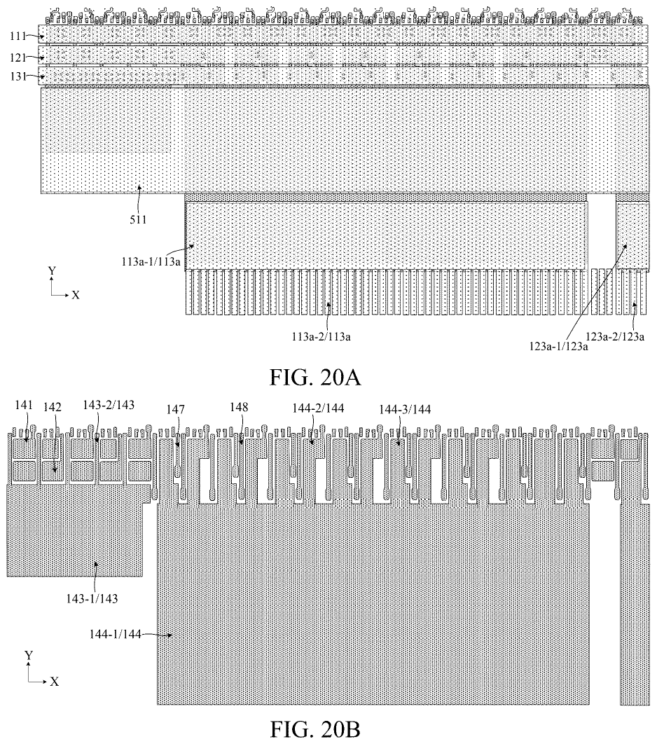

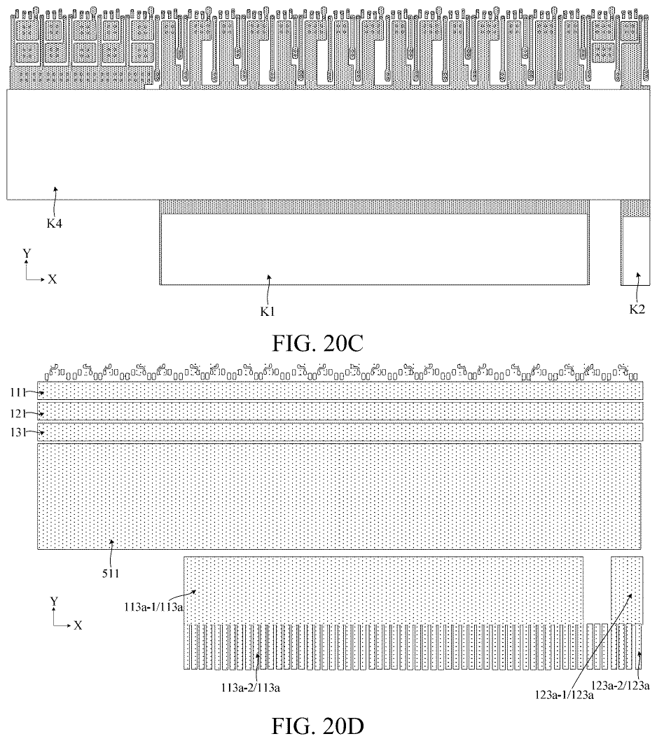

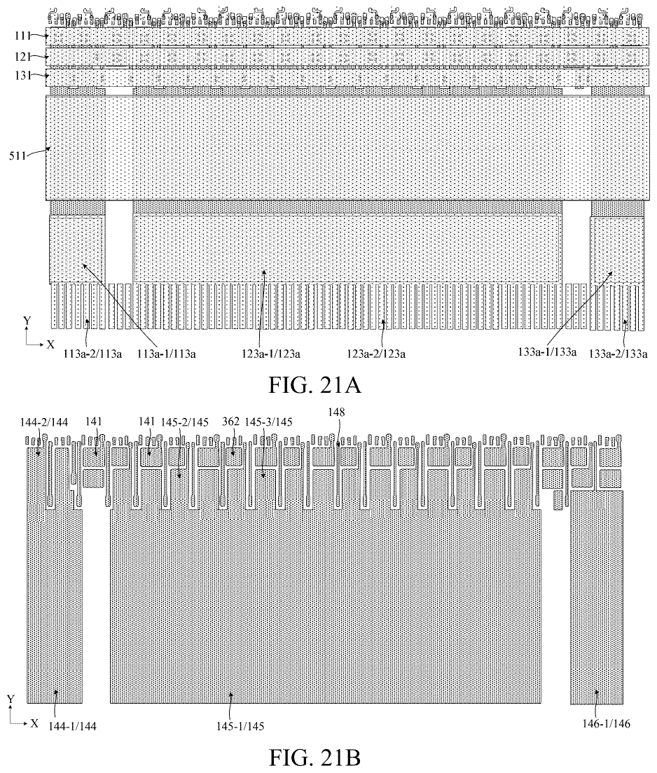

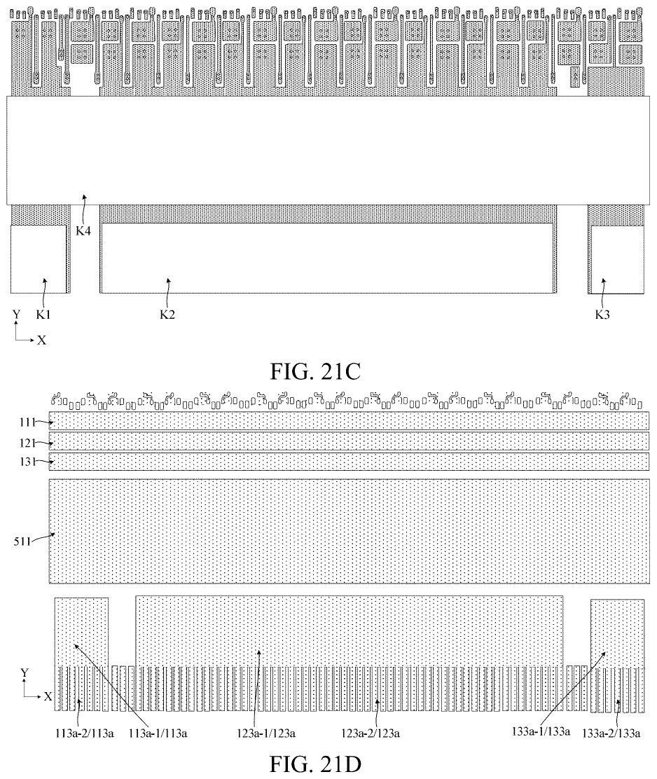

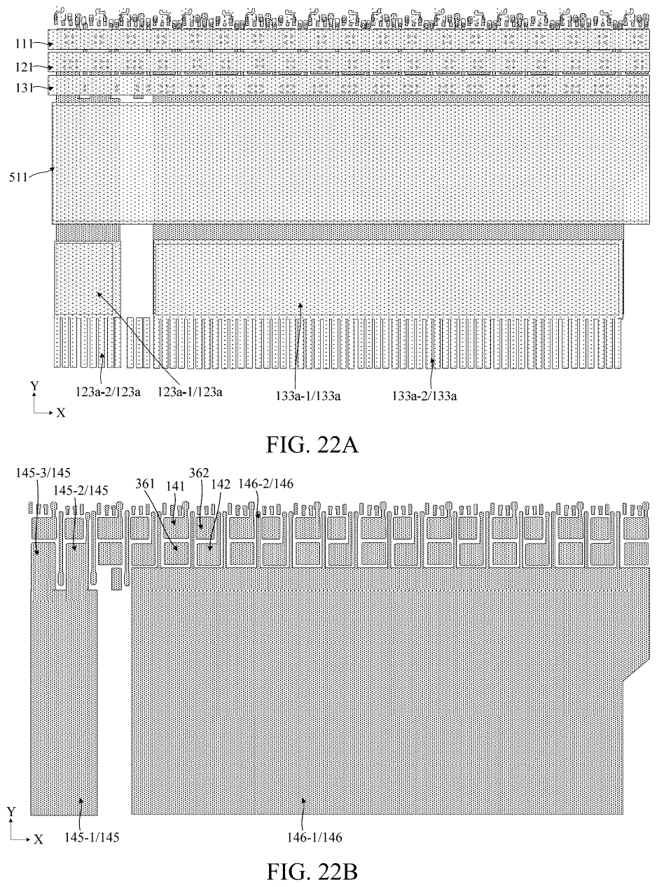

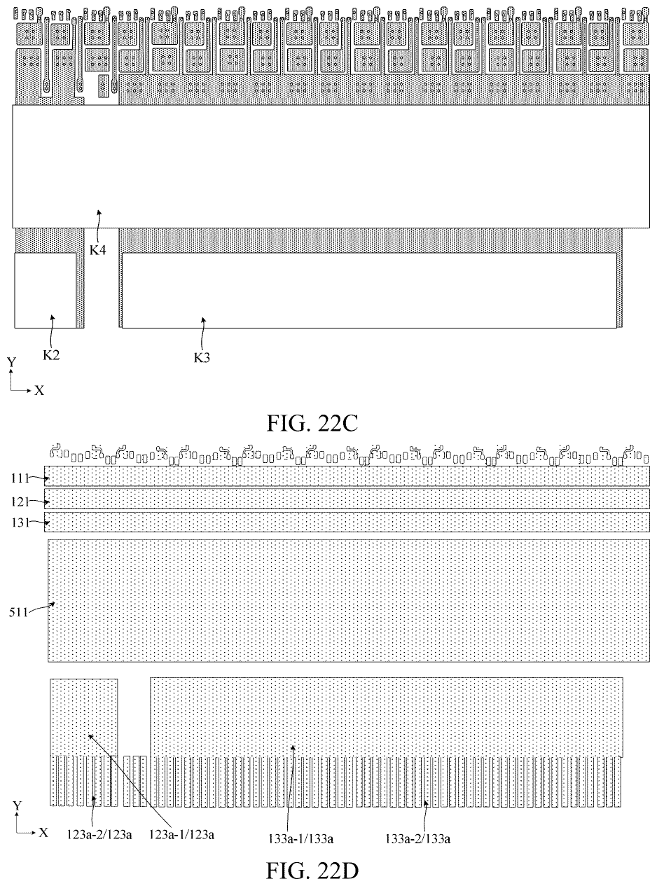

FIGS. 20A, 21A, and 22A are partially enlarged schematic diagrams of C2 region in FIG. 5. FIGS. 20A, 21A, and 22A mainly illustrate the structures of the fourth conductive layer and the fifth conductive layer of C2 region. Wherein, FIG. 20A mainly illustrates a transfer region between the second power supply line 111 and the first power supply bend line 113a in the second fan-out region; FIG. 21A mainly illustrates a transfer region between the second power supply line 121 and the first power supply bend line 123a in the second fan-out region; FIG. 22A mainly illustrates a transfer region between the second power supply line 131 and the first power supply bend line 133a in the second fan-out region.

FIG. 20B is a schematic diagram of a fourth conductive layer in FIG. 20A. FIG. 20C is a schematic diagram of FIG. 20A after an eighth insulation layer is formed. FIG. 20D is a schematic diagram of a fifth conductive layer in FIG. 20A. FIG. 21B is a schematic diagram of a fourth conductive layer in FIG. 21A. FIG. 21C is a schematic diagram of FIG. 21A after an eighth insulation layer is formed. FIG. 21D is a schematic diagram of a fifth conductive layer in FIG. 21A. FIG. 22B is a schematic diagram of a fourth conductive layer in FIG. 22A. FIG. 22C is a schematic diagram of FIG. 22A after an eighth insulation layer is formed. FIG. 22D is a schematic diagram of a fifth conductive layer in FIG. 22A.

In some examples, as shown in FIGS. 20B, 21B, and 22B, the fourth conductive layer of the second fan-out region may at least include: a plurality of first-type voltage transfer electrodes (e.g., including a first voltage transfer electrode 141, a second voltage transfer electrode 142, a third voltage transfer electrode 143), a plurality of second-type voltage transfer electrodes (e.g., including a fourth voltage transfer electrode 144, a fifth voltage transfer electrode 145, a sixth voltage transfer electrode 146), and a plurality of auxiliary connection electrodes (e.g., including a first auxiliary connection electrode 147 and a second auxiliary connection electrode 148). The first type of voltage transfer electrode in the present example may achieve the connection between the first power line and the second power supply line, and the second-type voltage transfer electrode may achieve the connection between the first power line, the second power supply line, and the first power supply bend line.

In some examples, the first voltage transfer electrode 141 may be connected to the first power line VDD1 of the display region, the second voltage transfer electrode 142 may be connected to the first power line VDD2 of the display region, and the third voltage transfer electrode 143 may be connected to the first power line VDD3 of the display region.

In some examples, the first auxiliary connection electrode 147 and the second auxiliary connection electrode 148 may be substantially strip-shaped extending in the second direction Y, and a length of the second auxiliary connection electrode 148 in the second direction Y may be greater than a length of the first auxiliary connection electrode 147 in the second direction Y. A first auxiliary connection electrode 147 may be connected to a first power line VDD2 of the display region, and a second auxiliary connection electrode 148 may be connected to a second power line VDD3 of the display region.

In some examples, as shown in FIG. 20B, the fourth voltage transfer electrode 144 may include a fourth main body portion 144-1 and a plurality of fourth protrusion portions 144-2 and a plurality of fifth protrusion portions 144-3. The fourth main body portion 144-1, the plurality of fourth protrusion portions 144-2, and the plurality of fifth protrusion portions 144-3 may have an integrated structure connected to each other. The fourth main body portion 144-1 may be substantially rectangular, the fourth protrusion portion 144-2 may be substantially L-shaped, and the fifth protrusion portion 144-3 may be substantially rectangular. The fourth protrusion portion 144-2 and the fifth protrusion portion 144-3 may be located on a side of the fourth main body portion 144-1 close to the display region, and the fourth protrusion portion 144-2 and the fifth protrusion portion 144-3 may be provided at intervals along the first direction X. A second auxiliary connection electrode 148 may be provided between the fourth protrusion portion 144-2 and the adjacent fifth protrusion portion 144-3 in the first direction X, and a first auxiliary connection electrode 147 and a second auxiliary connection electrode 148 arranged in the first direction X may be provided between the fifth protrusion portion 144-3 and the adjacent fourth protrusion portion 144-2 in the first direction X. The fourth protrusion portion 144-2 may be configured to be connected to the first power line VDD1 of the display region, and the fifth protrusion portion 144-3 may be configured not to be directly connected to the first power line.

In some examples, as shown in FIG. 21B, the fifth voltage transfer electrode 145 may include a fifth body portion 145-1, a plurality of sixth protrusion portions 145-2, and a plurality of seventh protrusions 145-3. The fifth main body portion 145-1, the plurality of sixth protrusion portions 145-2, and the plurality of seventh protrusions 145-3 may have an integrated structure connected to each other. The fifth main body portion 145-1 may be substantially rectangular, the sixth protrusion portion 145-2 may be substantially L-shaped, and the seventh protrusion portion 145-3 may be substantially rectangular. The sixth protrusion portion 145-2 and the seventh protrusion portion 145-3 may be located on a side of the fifth main body 145-1 close to the display region. A second auxiliary electrode 362 may be provided on a side of the sixth protrusion portion 145-2 close to the display region, and a first voltage transfer electrode 141 may be provided on a side of the seventh protrusion portion 145-3 close to the display region. The sixth protrusion portion 145-2 and the seventh protrusion portion 145-3 may be disposed at intervals along the first direction X, and a second auxiliary connection electrode 148 may be provided between the adjacent sixth protrusion portion 145-2 and the seventh protrusion portion 145-3. One sixth protrusion portion 145-2 may be configured to be connected to one first power line VDD2 of the display region, and the seventh protrusion portion 145-3 may be configured not to be directly connected to the first power line.

In some examples, as shown in FIG. 22B, the sixth voltage transfer electrode 146 may include a sixth main body portion 146-1 and a plurality of eighth protrusion portions 146-2. The sixth main body portion 146-1 and the plurality of eighth protrusion portions 146-2 may have an integrated structure connected to each other. The sixth main body portion 146-1 may have a substantially rectangular shape, and the eighth protrusion portion 146-2 may have a substantially strip shape extending in the second direction Y. The eighth protrusion portion 146-2 may be located on a side of the sixth main body portion 146-1 close to the display region. A first voltage transfer electrode 141 and a first auxiliary electrode 361 arranged in the second direction Y may be provided between the two adjacent eighth projections 146-2, or a second voltage transfer electrode 142 and a second auxiliary electrode 362 arranged in the second direction Y may be provided.

In some examples, as shown in FIGS. 20D, 21D, and 22D, the fifth conductive layer of the first bezel region may include at least second power supply lines 111, 121, and 131, a first sub-line 511 of the second voltage fan-out line, and first power supply bend lines 113a, 123a, and 133a. The first power supply bend line 113a may extend from the bend region to the second fan-out region and be connected to the fourth voltage transfer electrode 144 in the second fan-out region. The first power supply bend line 123a may extend from the bend region to the second fan-out region and be connected to the fifth voltage transfer electrode 145 in the second fan-out region. The first power supply bend line 133a may extend from the bend region to the second fan-out region and be connected to the sixth voltage transfer electrode 146 in the second fan-out region.

In some examples, as shown in FIGS. 20C, 21C, and 22C, the first bezel region may be provided with at least a first opening K1, a second opening K2, a third opening K3, and a first groove K4. The eighth insulation layer and the seventh insulation layer in the first opening K1, the second opening K2, and the third opening K3 may be removed to expose a portion of the surface of the fourth conductive layer. The eighth insulation layer in the first groove K4 may be removed, and the seventh insulation layer may be retained.

In some examples, the second power supply lines 111, 121, and 131 may be generally straight line-shaped and extend along the first direction X. The second power supply lines 111, 121, and 131 may be sequentially arranged in a direction opposite to the second direction Y. The first sub-line 511 of the second voltage fan-out line may be located on a side of the second power supply line 131 away from the display region. An orthographic projection of the first sub-line 511 of the second voltage fan-out line on the base substrate may cover an orthographic projection of the first groove K4 on the base substrate. By retaining the seventh insulation layer in the first groove K4, insulation between the first sub-line 511 of the second voltage fan-out line and the voltage transfer electrode may be achieved.

In some examples, the second power supply line 111 may be connected to the first voltage transfer electrode 141, the second auxiliary electrode 362, the fourth protrusion portion 144-2, and the fifth protrusion portion 144-3 of the fourth voltage transfer electrode 144. The second power supply line 121 may be connected to the second voltage transfer electrode 142, the first auxiliary electrode 361, the first auxiliary connection electrode 147, and the sixth protrusion portion 145-2 and the seventh protrusion portion 145-3 of the fifth voltage transfer electrode 145. The second power supply line 131 may be connected to the third voltage transfer electrode 143, the second auxiliary connection electrode 148, and the sixth main body portion 146-1 of the sixth voltage transfer electrode 146.

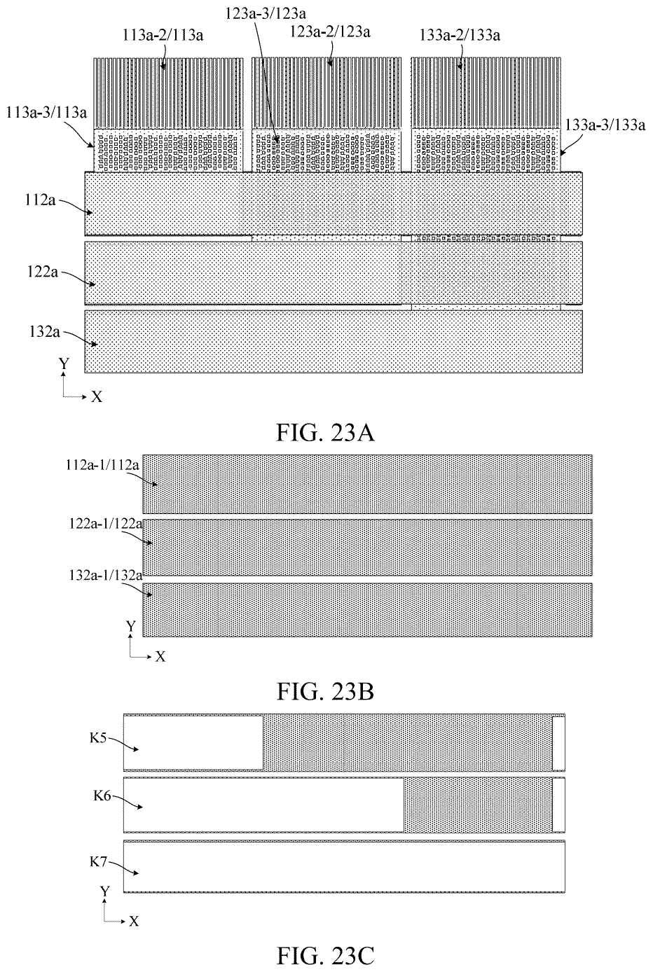

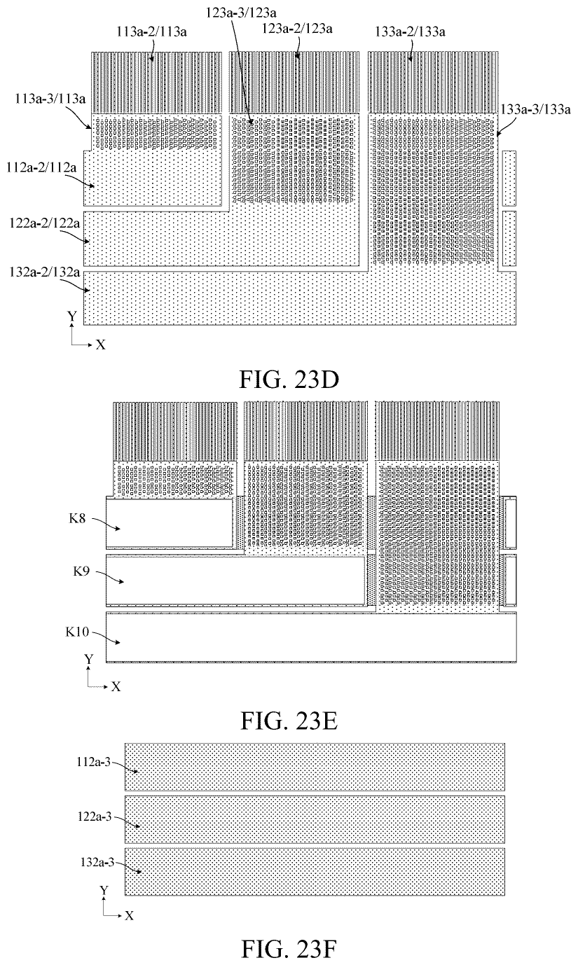

In some examples, as shown in FIGS. 20A and 20D, the first power supply bend line 113a may at least include: a first connection portion 113a-1, a bend portion 113a-2, and a second connection portion 113a-3 (as shown in FIG. 23A). The first connection portion 113a-1, the bend portion 113a-2, and the second connection portion 113a-3 may have an integrated structure connected to each other. The first connection portion 113a-1 may be substantially in a shape of a rectangle. The first connection portion 113a-1 may be located on a side of the first sub-line 511 of the second voltage fan-out line away from the display region. The first connection portion 113a-1 may be connected to the fourth main body portion 144-1 of the fourth voltage transfer electrode 144 through the first opening K1. The bend portion 113a-2 may include a plurality of bend lines sequentially arranged in the first direction X. In this example, electrical connection between the second power supply line 111 and the first power supply bend line 113a may be achieved by the fourth voltage transfer electrode 144.

In some examples, as shown in FIGS. 21A and 21D, the first power supply bend line 123a may include a first connection portion 123a-1, a bend portion 123a-2, and a second connection portion 123a-3 (as shown in FIG. 23A). The first connection portion 123a-1, the bend portion 123a-2, and the second connection portion 123a-3 may have an integrated structure connected to each other. The first connection portion 123a-1 may be substantially in a shape of a rectangle. The first connection portion 123a-1 may be located on a side of the first sub-line 511 of the second voltage fan-out line away from the display region. The first connection portion 123a-1 may be connected to the fifth main body portion 145-1 of the fifth voltage transfer electrode 145 through the second opening K2. The bend portion 113a-2 may include a plurality of bend lines sequentially arranged in the first direction X. In this example, electrical connection between the second power supply line 121 and the first power supply bend line 123a may be achieved by the fifth voltage transfer electrode 145.

In some examples, as shown in FIGS. 22A and 22D, the first power supply bend line 133a may at least include: a first connection portion 133a-1, a bend portion 133a-2, and a second connection portion 133a-3 (as shown in FIG. 23A). The first connection portion 133a-1, the bend portion 133a-2, and the second connection portion 133a-3 may have an integrated structure connected to each other. The first connection portion 133a-1 may be substantially in a shape of a rectangle. The first connection portion 133a-1 may be located on a side of the first sub-line 511 of the second voltage fan-out line away from the display region. The first connection portion 133a-1 may be connected to the sixth main body portion 146-1 of the sixth voltage transfer electrode 146 through the third opening K3. The bend portion 133a-2 may include a plurality of bend lines sequentially arranged in the first direction X. In this example, electrical connection between the second power supply line 131 and the first power supply bend line 133a may be achieved by the sixth voltage transfer electrode 146.

Regarding the connection method between the first power line and the second power supply line in this example, reference may be made to the description in the foregoing embodiments, and thus details are not repeated herein.

FIG. 23A is a partially enlarged schematic diagram of C3 region in FIG. 5. FIG. 23A illustrates the structures of the fourth conductive layer, the fifth conductive layer, and the sixth conductive layer in the C3 region. FIG. 23B is a schematic diagram of a fourth conductive layer in FIG. 23A. FIG. 23C is a schematic diagram of FIG. 23A after an eighth insulation layer is formed. FIG. 23D is a schematic diagram of a fifth conductive layer in FIG. 23A. FIG. 23E is a schematic diagram of FIG. 23A after a ninth insulation layer is formed. FIG. 23F is a schematic diagram of a sixth conductive layer in FIG. 23A.

In some examples, as shown in FIGS. 23A to 23F, the first power supply lines 112a, 122a, and 132a of the first fan-out region may be a three-layer wiring structure. Each of the first power supply lines may include a first line located in the fourth conductive layer, a second line located in the fifth conductive layer, and a third line located in the sixth conductive layer. For example, the first power supply line 112a may include: a first line 112a-1 located in the fourth conductive layer, a second line 112a-2 located in the fifth conductive layer, and a third line 112a-3 located in the sixth conductive layer. The first power supply line 122a may include: a first line 122a-1 located in the fourth conductive layer, a second line 122a-2 located in the fifth conductive layer, and a third line 122a-3 located in the sixth conductive layer. The first power supply line 132a may include a first line 132a-1 located in the fourth conductive layer, a second line 132a-2 located in the fifth conductive layer, and a third line 132a-3 located in the sixth conductive layer.

In some examples, as shown in FIG. 23C, the eighth insulation layer of the first fan-out region may be provided with a fifth opening K5, a sixth opening K6, and a seventh opening K7. The eighth insulation layer and the seventh insulation layer in the fifth opening K5, the sixth opening K6, and the seventh opening K7 may be removed to expose a portion of the surface of the fourth conductive layer. As shown in FIG. 23E, the ninth insulation layer of the first fan-out region may be provided with an eighth opening K8, a ninth opening K9, and a tenth opening K10. The ninth insulation layer in the eighth opening K8, the ninth opening K9, and the tenth opening K10 may be removed to expose a portion of the surface of the fifth conductive layer.

In some examples, as shown in FIGS. 23A-23F, the second connection portion 113a-3 of the first power supply bend line 113a may extend to the first fan-out region and be connected to the first power supply line 112a of the first fan-out region. The second connection portion 113a-3 located in the fifth conductive layer and the second wiring 112a-2 of the first power supply line 112a may have an integrated structure connected to each other. The second line 112a-2 may be connected to the first line 112a-1 located in the fourth conductive layer through the fifth opening K5. The third line 112a-3 located in the sixth conductive layer may be connected to the second line 112a-2 located in the fifth conductive layer through the eighth opening K8. An orthographic projection of the third line 112a-3 on the base substrate may partially overlap with an orthographic projection of the second connection portion 123a-3 of the first power supply bend line 123a and the second connection portion 133a-3 of the first power supply bend line 133a on the base substrate.

In some examples, as shown in FIGS. 23A-23F, the second connection portion 123a-3 of the first power supply bend line 123a may extend to the first fan-out region and be connected to the first power supply line 122a of the first fan-out region. The second connection portion 123a-3 located in the fifth conductive layer and the second line 122a-2 of the first power supply line 122a may have an integrated structure connected to each other. The second line 122a-2 may be connected to the first sub-line 122a-1 located in the fourth conductive layer through the sixth opening K6. The third line 122a-3 located in the sixth conductive layer may be connected to the second line 122a-2 located in the fifth conductive layer through the ninth opening K9. An orthographic projection of the third line 122a-3 on the base substrate and an orthographic projection of the second connection portion 133a-3 of the first power supply bend line 133a on the base substrate may partially overlap.

In some examples, as shown in FIGS. 23A-23F, the second connection portion 133a-3 of the first power supply bend line 133a may extend to the first fan-out region and be connected to the first power supply line 132a of the first fan-out region. The second connection portion 123a-3 located in the fifth conductive layer and the second line 132a-2 of the first power supply line 132a may have an integrated structure connected to each other. The second line 132a-2 may be connected to the first line 132a-1 located in the fourth conductive layer through the seventh opening K7. The third sub-line 132a-3 located in the sixth conductive layer may be connected to the second line 132a-2 located in the fifth conductive layer through the tenth opening K10.

In some examples, as shown in FIG. 23D, the second connection portion 113a-3 of the first power supply bend line 113a, the second connection portion 123a-3 of the first power supply bend line 123a, and the region where the second connection portion 133a-3 of the first power supply bend line 133a overlaps with the eighth insulation layer may be provided with a plurality of hollow portions to facilitate exhaust of the eighth insulation layer.

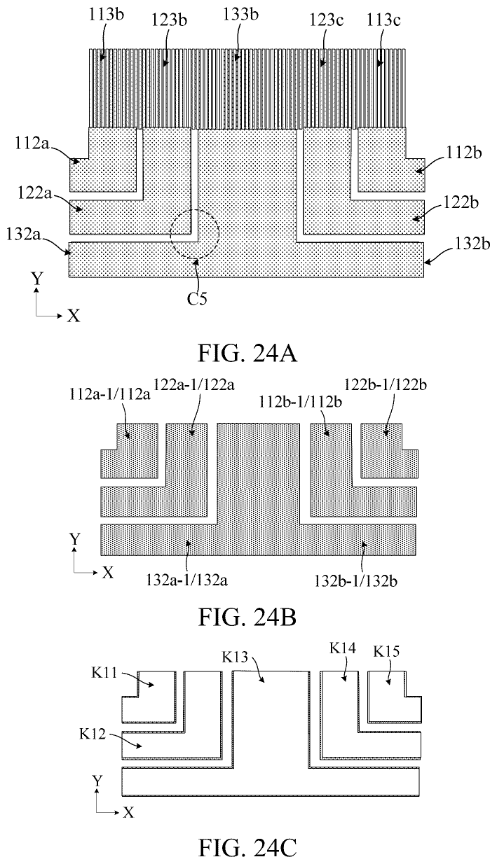

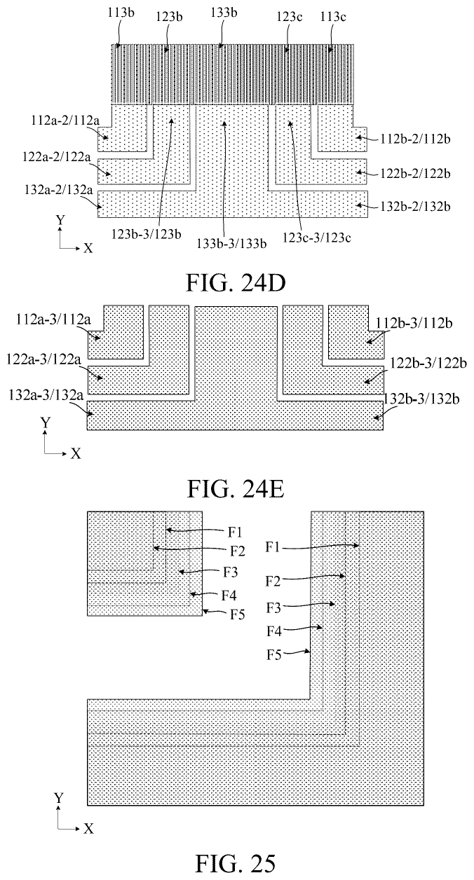

FIG. 24A is a partially enlarged schematic diagram of C4 region in FIG. 5. FIG. 24B is a schematic diagram of a fourth conductive layer in FIG. 24A. FIG. 24C is a schematic diagram of FIG. 24A after an eighth insulation layer is formed. FIG. 24D is a schematic diagram of a fifth conductive layer in FIG. 24A. FIG. 24E is a schematic diagram of a sixth conductive layer in FIG. 24A.

In some examples, as shown in FIGS. 24A-24E, the first power supply lines 112a and 112b of the first fan-out region may be disposed substantially symmetrically with respect to the centerline of the first fan-out region in the first direction X. The first power supply lines 122a and 122b may be disposed substantially symmetrically with respect to the centerline of the first fan-out region in the first direction X. The first power supply lines 132a and 132b may be disposed substantially symmetrically with respect to the centerline of the first fan-out region in the first direction X.

In some examples, the first power supply lines 132a and 132b may be an integrated structure connected to each other. As shown in FIG. 24B, the first line 132a-1 of the first power supply line 132a located in the fourth conductive layer and the first line 132b-1 of the first power supply line 132b located in the fourth conductive layer may have an integrated structure connected to each other. As shown in FIG. 24D, the second line 132a-2 of the first power supply line 132a located in the fifth conductive layer, the second line 132b-2 of the first power supply line 132b located in the fifth conductive layer, and the first power supply bend line 133b may have an integrated structure connected to each other. As shown in FIG. 24E, the third line 132a-3 of the first power supply line 132a located in the sixth conductive layer and the third line 132b-3 of the first power supply line 132b located in the sixth conductive layer may have an integrated structure connected to each other.

In some examples, as shown in FIG. 24D, the second line 112a-2 of the first power supply line 112a and the first power supply bend line 113b may be an integrated structure connected to each other. The second line 122a-2 of the first power supply line 122a and the first power supply bend line 123b may be an integrated structure connected to each other. The second line 112b-2 of the first power supply line 112b and the first power supply bend line 113c may be an integrated structure connected to each other. The second line 122b-2 of the first power supply line 122b and the first power supply bend line 123c may have an integrated structure connected to each other.

In some examples, as illustrated in FIG. 24C, the eighth insulation layer of the first fan-out region may be provided with an eleventh opening K11, a twelfth opening K12, a thirteenth opening K13, a fourteenth opening K14, and a fifteenth opening K15. The eighth insulation layer and the seventh insulation layer in the eleventh opening K11, the twelfth opening K12, the thirteenth opening K13, the fourteenth opening K14, and the fifteenth opening K15 may be removed to expose a portion of the surface of the fourth conductive layer. The ninth insulation layer may be provided with an opening exposing a portion of the surface of the fifth conductive layer.

In some examples, as shown in FIGS. 24A to 24E, the second line 112a-2 of the first power supply line 112a may be connected to the first line 112a-1 through the eleventh opening K11. The second line 122a-2 of the first power supply line 122a may be connected to the first line 122a-1 through the twelfth opening K12. The second line 132a-2 of the first power supply line 132a may be connected to the first line 132a-1 through the thirteenth opening K13. The second line 11ba-2 of the first power supply line 112b may be connected to the first line 112b-1 through the fourteenth opening K14. The second line 122b-2 of the first power supply line 122b may be connected to the first line 122b-1 through the fifteenth opening K15. The third line 112a-3 of the first power supply line 112a may be connected to the second line 112a-2 through an opening of the ninth insulation layer; the third line 122a-3 of the first power supply line 122a may be connected to the second line 122a-2 through an opening of the ninth insulation layer; the third line 132a-3 of the first power supply line 132a may be connected to the second line 132a-2 through an opening of the ninth insulation layer; the third line 112b-3 of the first power supply line 112b may be connected to the second line 112b-2 through an opening of the ninth insulation layer; the third line 122b-3 of the first power supply line 122b may be connected to the second line 122b-2 through an opening of the ninth insulation layer.

FIG. 25 is a partially enlarged schematic diagram of C5 region in FIG. 24A. In some examples, the third line of the sixth conductive layer of the first power supply line may have a fifth edge F5, the second line of the fifth conductive layer may have a fourth edge F4, the first line of the fourth conductive layer may have a third edge F3, the opening of the seventh insulation layer may have a first edge F1, and the opening of the eighth insulation layer may have a second edge F2. An orthographic projection of the opening of the seventh insulation layer on the base substrate may cover an orthographic projection of the corresponding opening of the eighth insulation layer on the base substrate. An orthographic projection of the third line on the base substrate may cover an orthographic projection of the corresponding second line on the base substrate, and the orthographic projection of the second line on the base substrate may cover an orthographic projection of the corresponding first line on the base substrate.

In the display substrate provided in the present embodiment, three first voltage power supply groups are provided in the first bezel region, and the first voltage signals required by the blue sub-pixel, the red sub-pixel, and the green sub-pixel may be separately designed to provide different first voltage signals to the blue sub-pixel, the red sub-pixel, and the green sub-pixel, thereby achieving power consumption reduction.

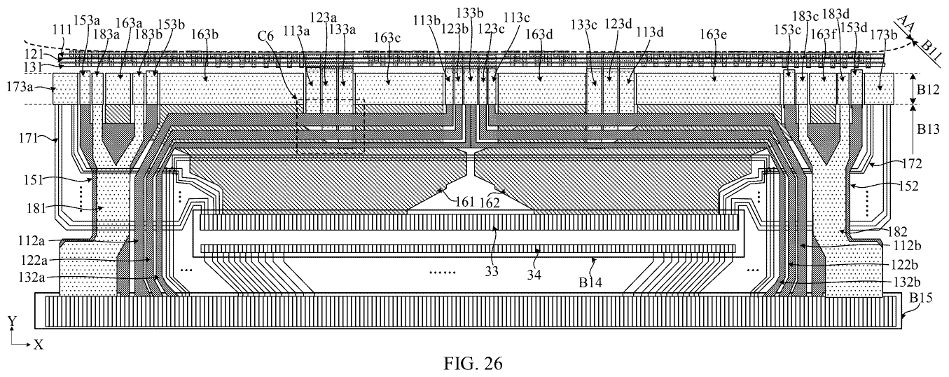

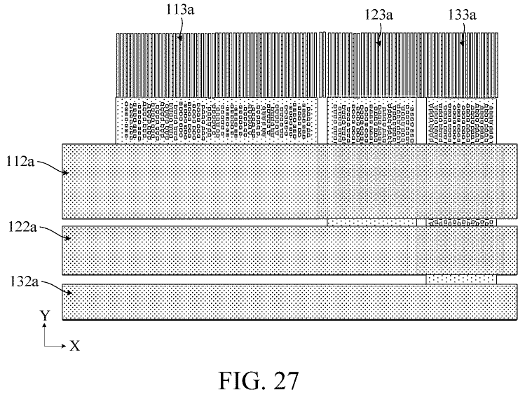

FIG. 26 is another schematic diagram of wiring of a first bezel region according to at least one embodiment of the present disclosure. FIG. 27 is a partially enlarged schematic diagram of C6 region in FIG. 26. In some examples, as shown in FIGS. 26 and 27, the first fan-out region B14 may include a plurality of first power supply lines (such as including first power supply lines 112a and 112b, 122a and 122b, 132a and 132b). The widths of the line segments of the plurality of first power supply lines in the same extending direction may be different, that is, the plurality of first power supply lines may be designed to have a non-equal width. For example, the width (i.e., a length along the second direction Y) of the line segments of the first power supply lines 112a and 112b extending in the first direction X may be greater than the width of the line segments of the first power supply lines 122a and 122b extending in the first direction X, and the width of the line segments of the first power supply lines 122a and 122b extending in the first direction X may be greater than the width of the line segments of the first power supply lines 132a and 132b extending in the first direction X. The width (i.e., the length along the first direction X) of the line segments of the first power supply lines 112a and 112b extending in the second direction Y may be greater than the width of the line segments of the first power supply lines 122a and 122b extending in the second direction Y, and the width of the line segments of the first power supply lines 122a and 122b extending in the second direction Y may be greater than the width of the line segments of the first power supply lines 132a and 132b extending in the second direction Y.

In some examples, the first power supply lines 112a and 112b may be configured to transmit a first type of first voltage signal Vdd1, the first power supply lines 122a and 122b may be configured to transmit a second type of first voltage signal Vdd2, and the first power supply lines 132a and 132b may be configured to transmit a third type of first voltage signal Vdd3. A first voltage signal Vdd1 is configured to be provided to a first sub-pixel group (including a plurality of blue sub-pixels), a first voltage signal Vdd2 is configured to be provided to a second sub-pixel group (including a plurality of red sub-pixels), and a first voltage signal Vdd3 is configured to be provided to a third sub-pixel group (including a plurality of green sub-pixels). Because the current of the blue sub-pixel is large, the impedance may be reduced by reducing the IR voltage drop of the first voltage signal Vdd1. In this example, by setting the widths of the first power supply lines 112a and 112b to be greater than the widths of the remaining first power supply lines, the impedance of the first voltage signal Vdd1 may be reduced, thereby ensuring the display effect of the first sub-pixel group.

In other examples, to avoid increasing the dimensions of the first bezel region and to avoid the limited layout space for the plurality of first power supply lines providing different first voltage signals, a same-layer wiring may be adopted to reduce the transmission voltage drop of the first voltage signals. For example, due to the larger pixel current in blue sub-pixels, the resulting voltage drop of the first voltage signal is more significant, which can easily affect the display uniformity of blue sub-pixels. By adopting a multi-layer metal wiring design for the first power supply lines 112a and 112b, the transmission voltage drop of the first voltage signal Vdd1 can be reduced, thereby improving the display uniformity of blue sub-pixels. For example, the quantity of line layers included in the first power supply lines 112a and 112b may be greater than the quantity of line layers included in the first power supply lines 122a, 122b, 132a and 132b. In some examples, the first power supply lines 122a, 122b, 132a, and 132b may have a structure of three-layer wiring respectively in a fourth conductive layer, a fifth conductive layer, and a sixth conductive layer. The first power supply lines 112a and 112b may have a structure of four-layer wiring respectively in a bottom shield layer, a fourth conductive layer, a fifth conductive layer, and a sixth conductive layer. A line located at the bottom shield layer may be disposed in a region not shielded by the first conductive layer and the second conductive layer in the first fan-out region, for example, may be located below the first line of the fourth conductive layer in region 6. However, the present embodiment is not limited thereto. In other examples, the portion of the first power supply lines 112a and 112b located at the bottom shield layer may be located at a side region of the horizontally extending drive lead-out line close to the second fan-out region B11.

Rest of a structure of the display substrate according to this example may be referred to the description of the aforementioned embodiments, which will not be described here in detail.

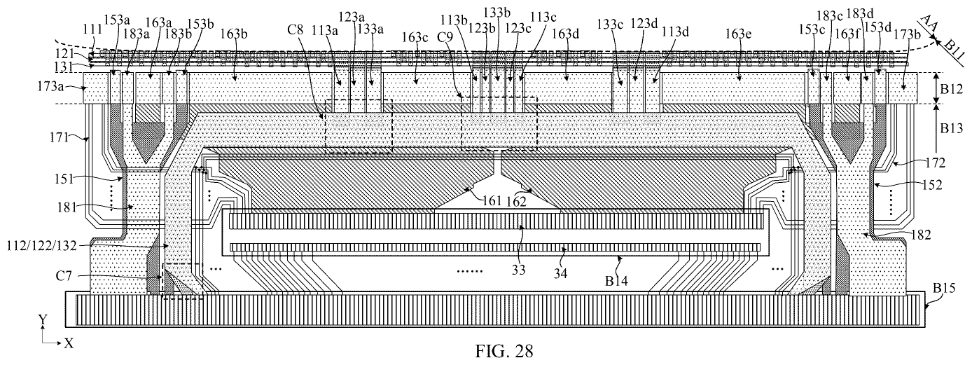

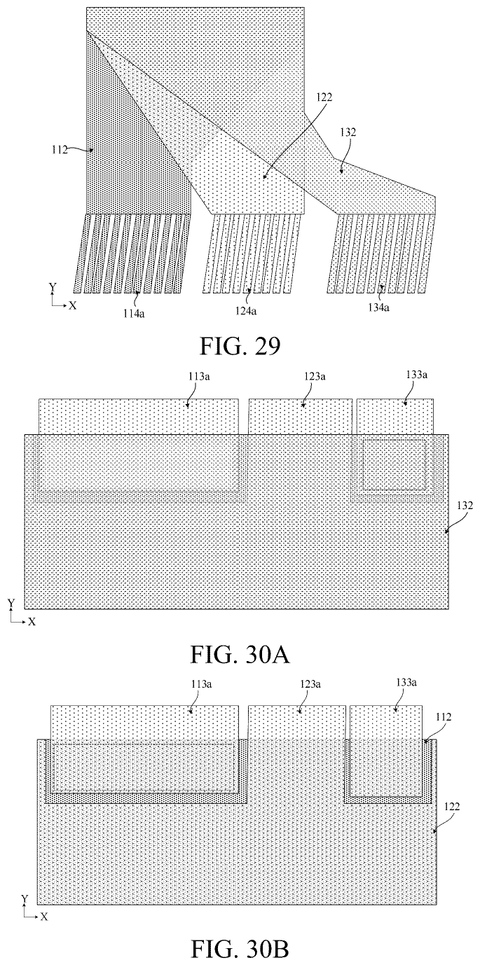

FIG. 28 is another schematic diagram of line of a first bezel region according to at least one embodiment of the present disclosure. FIG. 29 is a partially enlarged schematic diagram of C7 region in FIG. 28. In some examples, as shown in FIGS. 28 and 29, the first fan-out region B14 may include a plurality of first power supply lines 112, 122, and 132. The first power supply line 112 is configured to transmit the first voltage signal Vdd1, the first power supply line 122 is configured to transmit the first voltage signal Vdd2, and the first power supply line 132 is configured to transmit the first voltage signal Vdd3. The widths of the line segments of the first power supply lines 112, 122, and 132 in the same extending direction may be substantially the same.

In some examples, as shown in FIGS. 28 and 29, the first power supply lines 112, 122, and 132 may be located on different conductive layers. For example, the first power supply line 112 may be located in the fourth conductive layer, the first power supply line 122 may be located in the fifth conductive layer, and the first power supply line 132 may be located in the sixth conductive layer. A seventh insulation layer and an eighth insulation layer may be provided between the first power supply line 112 and the first power supply line 122, and a ninth insulation layer may be provided between the first power supply lines 122 and 132. The first power supply lines 122 and 132 may be provided with a plurality of hollow portions to facilitate exhaust of the organic insulation layer (including the eighth insulation layer and the ninth insulation layer). In FIGS. 28 and 29, a plurality of hollow portions on the first power supply lines 122 and 132 are omitted.

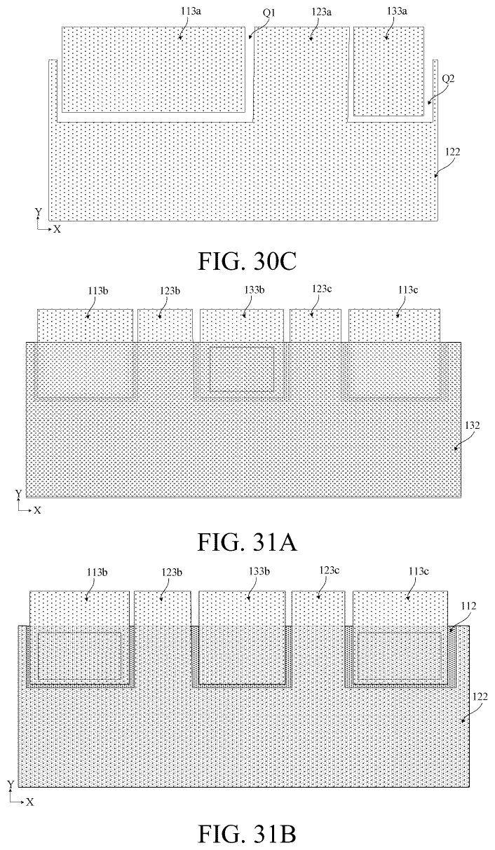

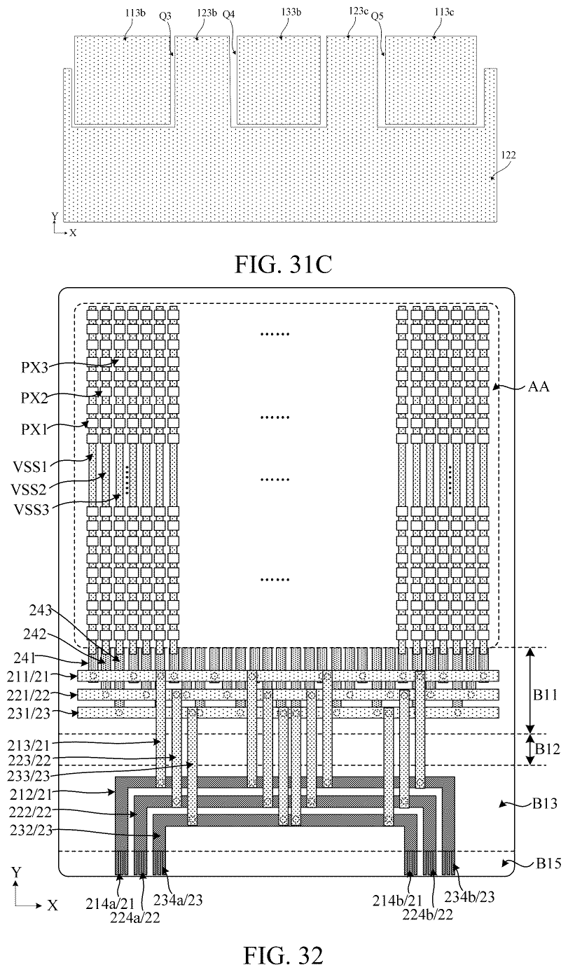

FIG. 30A is a partially enlarged schematic diagram of C8 region in FIG. 28. FIG. 30A illustrates the structures of the fourth conductive layer, the fifth conductive layer, and the sixth conductive layer in the C8 region. FIG. 30B is a schematic diagram of a fourth conductive layer and a fifth conductive layer of FIG. 30A. FIG. 30C is a schematic diagram of a fifth conductive layer in FIG. 30A. FIG. 31A is a partially enlarged schematic diagram of C9 region in FIG. 28. FIG. 31A illustrates the structures of the fourth conductive layer, the fifth conductive layer, and the sixth conductive layer in C9 region. FIG. 31B is a schematic view of the fourth conductive layer and the fifth conductive layer in FIG. 31A. FIG. 31C is a schematic diagram of a fifth conductive layer in FIG. 31A.

In some examples, as shown in FIGS. 30A to 31C, the first power supply line 122 located in the fifth conductive layer may be provided with a plurality of notches on a side close to the bend region, such as a first notch Q1, a second notch Q2, a third notch Q3, a fourth notch Q4, and a fifth notch Q5. The first power supply line 122 and the first power supply bend lines 123a, 123b, and 123c may have an integrated structure connected to each other. The first notch Q1 and the second notch Q2 may be located on two sides of the first power supply bend line 123a in the first direction X, the third notch Q3 and the fourth notch Q4 may be located on two sides of the first power supply bend line 123b in the first direction X, and the fourth notch Q4 may be located between the first power supply bend lines 123b and 123c. The fifth notch Q5 may be located on a side of the first power supply bend line 123c away from the fourth notch Q4.

In some examples, as shown in FIG. 30B, the first power supply bend line 113a located in the fifth conductive layer may extend into the first notch Q1 and be connected to the first power supply line 112 located in the fourth conductive layer through openings of the eighth insulation layer and the seventh insulation layer. As shown in FIG. 31B, the first power supply bend line 113b located in the fifth conductive layer may extend into the third notch Q3, and be connected to the first power supply line 112 located in the fourth conductive layer through openings of the eighth insulation layer and the seventh insulation layer. The first power supply bend line 113c located in the fifth conductive layer may extend into the fifth notch Q5 and be connected to the first power supply line 112 located in the fourth conductive layer through openings of the eighth insulation layer and the seventh insulation layer.

In some examples, as shown in FIG. 30A, the first power supply bend line 133a located in the fifth conductive layer may extend into the second notch Q2, and the first power supply line 132 located in the sixth conductive layer may be connected to the first power supply bend line 133a through the opening of the ninth insulation layer. As shown in FIG. 31A, the first power supply bend line 133b located in the fifth conductive layer may extend into the fourth notch Q4, and the first power supply line 132 located in the sixth conductive layer may be connected to the first power supply bend line 133b through the opening of the ninth insulation layer.

In some examples, orthographic projections of the first power supply lines 112, 122, and 132 on the base substrate may partially overlap. For example, an orthographic projection of the line segment of the first power supply line 132 located in the sixth conductive layer extending in the first direction X on the base substrate may cover an orthographic projection of the first power supply line 122 located in the fifth conductive layer extending in the first direction X on the base substrate. An orthographic projection of the line segment of the first power supply line 122 located in the fifth conductive layer extending in the first direction X on the base substrate may cover an orthographic projection of the first power supply line 112 located in the fourth conductive layer extending in the first direction X.

In this example, by arranging a plurality of first power supply lines in different conductive layers, the line width of the first power supply lines does not have to be reduced, which is beneficial to reducing the impedance of the first power supply lines and ensure the display uniformity of the sub-pixels.

In some examples, the brightness of sub-pixels emitting different colors of light, such as blue sub-pixels, red sub-pixels, and green sub-pixels, may be controlled by the magnitude of the second voltage signal. For example, based on the different turn-on voltages of RGB sub-pixels, providing different second voltage signals to RGB sub-pixels enables the pixel circuit to supply the same voltage to the anodes of the light emitting elements emitting light of different colors to turn on the light emitting elements. Consequently, the maximum range of data signals for RGB sub-pixels can remain identical, allowing precise grouped brightness control of RGB sub-pixels and achieving power savings for the second voltage signal.

FIG. 32 is a schematic diagram of transmission of a second voltage signal according to at least one embodiment of the present disclosure. In some examples, as shown in FIG. 32, the plurality of sub-pixels of the display region AA may be divided into three sub-pixel groups, for example, the first sub-pixel group may include a plurality of first sub-pixels PX1 emitting first color light (e.g., blue light), the second sub-pixel group may include a plurality of second sub-pixels PX2 emitting second color light (e.g., red light), and the third sub-pixel group may include a plurality of third sub-pixels PX3 emitting third color light (e.g., green light). The first sub-pixel group may be connected to the second power line VSS1, the second sub-pixel group may be connected to the second power line VSS2, and the third sub-pixel group may be connected to the second power line VSS3. The second power line VSS1 may be configured to transmit a first type of second voltage signal Vss1, the second power line VSS2 may be configured to transmit a second type of second voltage signal Vss2, and the second power line VSS3 may be configured to transmit a third type of second voltage signal Vss3. The second voltage signals Vss1, Vss2, and Vss3 may be second voltage signals having different voltage values. For example, the second voltage signal Vss1 may be less than the second voltage signal Vss2, and the second voltage signal Vss2 may be less than the second voltage signal Vss3.

In some examples, the cathodes of the light emitting elements of one column of the first sub-pixels PX1 of the first sub-pixel group may have an integrated structure connected to each other as one second power line VSS1. The cathodes of the light emitting elements of one column of the second sub-pixels PX2 of the second sub-pixel group may have an integrated structure connected to each other as a second power line VSS2. The cathodes of the light emitting elements of the column of the third sub-pixels PX3 of the third sub-pixel group may have an integrated structure connected to each other as a second power line VSS3.

In some examples, as shown in FIG. 32, the first bezel region B1 may include L second voltage power supply groups, such as including a first second voltage power supply group 21, a second second voltage power supply group 22, and a third second voltage power supply group 23. Each second voltage power supply group may be configured to provide a corresponding second voltage signal to at least one sub-pixel group. In the present example, the second voltage power supply group 21 may be configured to provide the second voltage signal Vss1 to the first sub-pixel group, the second voltage power supply group 22 may be configured to provide the second voltage signal Vss2 to the second sub-pixel group, and the second voltage power supply group 23 may be configured to provide the second voltage signal Vss3 to the third sub-pixel group.

In some examples, as shown in FIG. 32, the second voltage power supply group 21 may include a third power supply line 211 located in the second fan-out region B11, a fourth power supply line 212 located in the first fan-out region B13, a second power supply bend line 213 located in the bend region B12, and second voltage contact pads 214a and 214b located in the first signal access region B15. The second voltage power supply group 22 may include a third power supply line 221 located in the second fan-out region B11, a fourth power supply line 222 located in the first fan-out region B13, a second power supply bend line 223 located in the bend region B12, and second voltage contact pads 224a and 224b located in the first signal access region B15. The second voltage power supply group 23 may include a third power supply line 231 located in the second fan-out region B11, a fourth power supply line 232 located in the first fan-out region B13, a second power supply bend line 233 located in the bend region B12, and second voltage contact pads 234a and 234b located in the first signal access region B15.

In some examples, as illustrated in FIG. 32, the third power supply lines 211, 221, and 231 located in the second fan-out region B11 may be sequentially arranged in a direction opposite to the second direction Y. The third power supply lines 211, 221, and 231 may be at least lines extending in the first direction X. The third power supply line may be connected to the second power supply line through a third-type voltage transfer electrode, and the third-type voltage transfer electrode may include a seventh voltage transfer electrode 241, an eighth voltage transfer electrode 242, and a ninth voltage transfer electrode 243. Wherein, the third power supply line 211 may be connected to the second power line VSS1 through the seventh voltage transfer electrode 241, the third power supply line 221 may be connected to the second power line VSS2 through the eighth voltage transfer electrode 242, and the third power supply line 231 may be connected to the second power line VSS3 through the ninth voltage transfer electrode 243.

In this example, three second voltage power supply groups are provided in the first bezel region to provide three different second voltage signals, and different requirements for the second voltage signals of three sub-pixel groups emitting different color lights in the display region may be met, thereby achieving the purpose of saving power consumption of the second voltage signal.

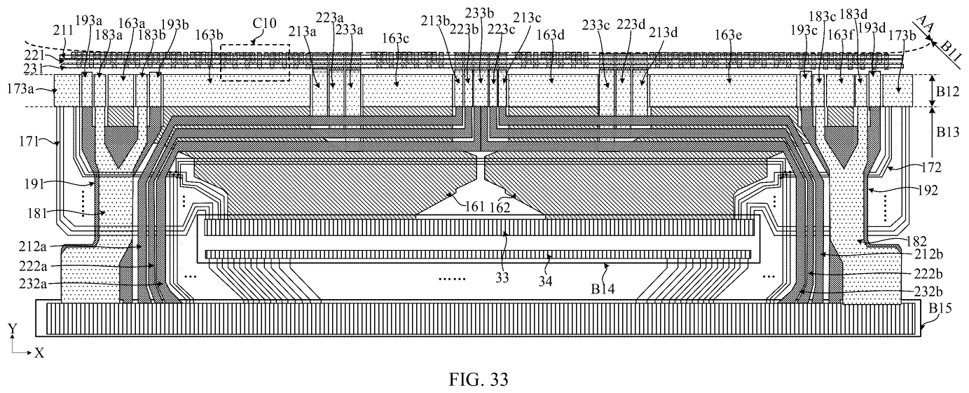

FIG. 33 is a schematic diagram of line of a first bezel region according to at least one embodiment of the present disclosure. FIG. 33 mainly illustrates three third power supply lines 211, 221, and 231 of the second fan-out region B11, a plurality of bend connection lines of the bend region B12, and some lines of the first fan-out region B13 (including, for example, first power supply lines 212a and 212b, 222a and 222b, and 232a and 232b). In FIG. 33, a plurality of adjacent lines of the same type is shown as a whole.

In some examples, as shown in FIG. 33, the second fan-out region B11 may at least include: three third power supply lines 211, 221, and 231, a first voltage fan-out line (not shown), a plurality of data fan-out lines (not shown), a plurality of drive fan-out lines (not shown), and a plurality of touch fan-out lines (not shown). The first voltage fan-out line may be configured to transmit a first voltage signal.

In some examples, as shown in FIG. 33, the plurality of bend connection lines of the bend region B12 may include: a plurality of data bend lines (such as including a first group of data bend lines 163a, a second group of data bend lines 163b, a third group of data bend lines 163c, a fourth group of data bend lines 163d, a fifth group of data bend lines 163e, and a sixth group of data bend lines 163f), a plurality of drive bend lines (such as including a first group of drive bend lines 173a, a second group of drive bend lines 173b), a plurality of touch bend lines (such as including a first group of touch bend lines 183a, a second group of touch bend lines 183b, a third group of touch bend lines 183c, and a fourth group of touch bend lines 183d), a plurality of first power supply bend lines (such as including first power bend lines 193a, 193b, 193c and 193d), and a plurality of second power supply bend lines (such as including second power supply bend lines 213a, 213b, 213c, and 213d; 223a, 223b, 223c, and 223d; 233a, 233b, and 233c).

In some examples, as shown in FIG. 33, within the bend region B12, the first group of drive bend lines 173a, the first power supply bend line 193a, the first group of touch bend lines 183a, the first group of data bend lines 163a, the second group of touch bend lines 183b, the first power supply bend line 193b, the second group of data bend lines 163b, the second power supply bend lines 213a, 223a, and 233a, the third group of data bend lines 163c, the second power supply bend lines 213b, 223b, 223c, and 213c, the fourth group of data bend lines 163d, the second power supply bend lines 213c, 223d, and 213d, the fifth group of data bend lines 163c, the first power supply bend line 193c, the third group of touch bend lines 183c, the sixth group of data bend lines 163f, the fourth group of touch bend lines 183d, the first power supply bend line 193d, and the second group of drive bend lines 173b may be sequentially arranged in the first direction X.

In some examples, as shown in FIG. 33, the first fan-out region B13 may include a plurality of fourth power supply lines (such as including two fourth power supply lines 212a and 212b, two fourth power supply lines 222a and 222b, and two fourth power supply lines 232a and 232b), two first voltage lead-out lines (such as including first voltage lead-out lines 191 and 192), a plurality of data lead-out lines (including a first group of data lead-out lines 161 and a second group of data lead-out lines 162), a plurality of drive lead-out lines (including a first group of drive lead-out lines 171 and a second group of drive lead-out lines 172), and a plurality of touch lead-out lines (including a first group of touch lead-out lines 181 and a second group of touch lead-out lines 182). The first voltage lead-out line 191 may be connected to the first voltage fan-out line in the second fan-out region B11 through the first voltage bend lines 193a and 193b, and the first voltage lead-out line 192 may be connected to the first voltage fan-out line in the second fan-out region B11 through the first voltage bend lines 193c and 193d. The first voltage lead-out lines 191 and 192 may be configured to transmit a first voltage signal.

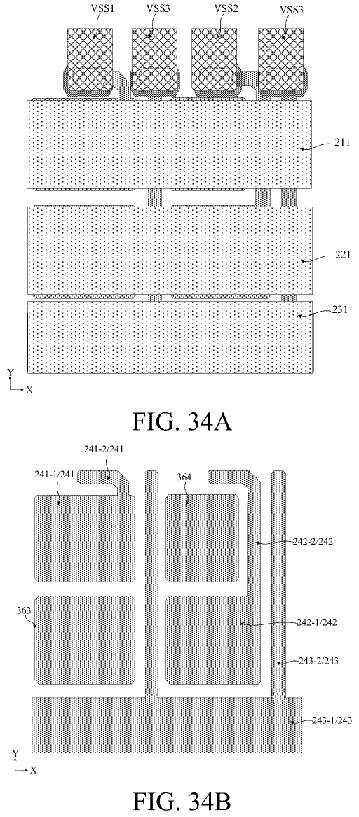

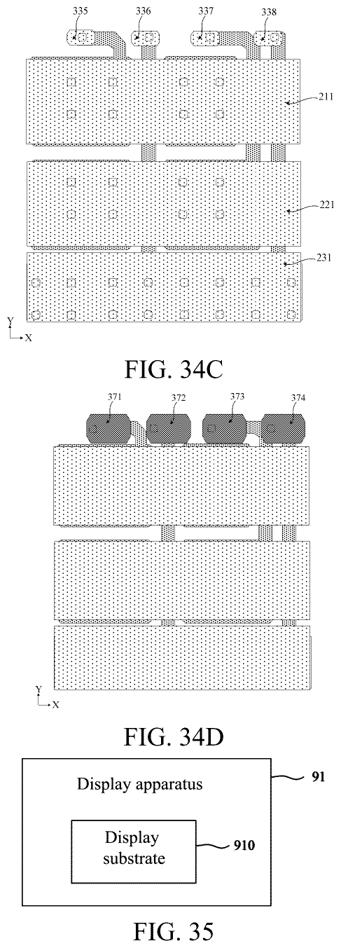

FIG. 34A is a partially enlarged schematic diagram of C10 region in FIG. 33. FIG. 34A schematically illustrates a portion of films at a junction between the display region AA and the first bezel region B1. FIG. 34B is a schematic diagram of a fourth conductive layer in FIG. 34A. FIG. 34C is a schematic diagram after a fifth conductive layer is formed in FIG. 34A. FIG. 34D is a schematic diagram after an anode layer is formed in FIG. 34A.

In some examples, as shown in FIG. 34B, the fourth conductive layer of the first bezel region may at least include: a third-type voltage transfer electrode (such as including a seventh voltage transfer electrode 241, an eighth voltage transfer electrode 242, and a ninth voltage transfer electrode 243), a plurality of auxiliary electrodes (such as including a third auxiliary electrode 363, and a fourth auxiliary electrode 364).

In some examples, the seventh voltage transfer electrode 241 may include a seventh main body portion 241-1 and a ninth protrusion portion 241-2, and the seventh main body portion 241-1 and the ninth protrusion portion 241-2 may be an integrated structure connected to each other. The shape of the seventh main body portion 241-1 may be substantially rectangular, and the shape of the ninth protrusion portion 241-2 may be substantially L-shaped. The ninth protrusion portion 241-2 is located on a side of the seventh main body portion 241-1 close to the display region. The eighth voltage transfer electrode 242 may include an eighth main body portion 242-1 and a tenth protrusion portion 242-2. The shape of the eighth main body portion 242-1 may be substantially rectangular, and the shape of the tenth protrusion portion 242-2 may be substantially L-shaped. The eighth main body portion 242-1 and the tenth protrusion portion 242-2 may be an integrated structure connected to each other. The ninth voltage transfer electrode 243 may include a ninth main body portion 243-1 and a plurality of eleventh protrusion portions 243-2. The shape of the ninth main body portion 243-1 may be substantially rectangular, and the shape of the eleventh protrusion portion 243-2 may be substantially strip-shaped extending in the second direction Y. The ninth main body portion 243-1 and the plurality of eleventh protrusion portions 243-2 may have an integrated structure connected to each other.

In some examples, the third auxiliary electrode 363 and the fourth auxiliary electrode 364 may be substantially rectangular in shape. The seventh voltage transfer electrode 241 and the third auxiliary electrode 363 are arranged in alignment in the second direction Y, and the third auxiliary electrode 363 is located on a side of the seventh voltage transfer electrode 241 away from the display region, and is located between the two eleventh protrusion portions 243-2 of the ninth voltage transfer electrode 243. The eighth voltage transfer electrode 242 and the fourth auxiliary electrode 364 are arranged in alignment in the second direction Y, and the fourth auxiliary electrode 364 may be located on a side of the eighth voltage transfer electrode 242 close to the display region and between the two eleventh protrusion portions 243-2 of the ninth voltage transfer electrode 243.

In some examples, as shown in FIG. 34C, the fifth conductive layer of the first bezel region may at least include: third power supply lines 211, 221, and 231, and a plurality of bezel power connection electrodes (such as including a fifth bezel power connection electrode 335, a sixth bezel power connection electrode 336, a seventh bezel power connection electrode 337, and an eighth bezel power connection electrode 338). The fifth bezel power connection electrode 335, the sixth bezel power connection electrode 336, the seventh bezel power connection electrode 337, and the eighth bezel power connection electrode 338 may be arranged along the first direction X, and may be located on a side of the third power supply line 211 close to the display region. The fifth bezel power connection electrode 335 may be connected to the ninth protrusion portion 241-2 of the seventh voltage transfer electrode 241 through vias provided on the eighth insulation layer and the seventh insulation layer. The sixth bezel power connection electrode 336 may be connected to one eleventh protrusion portion 243-2 of the ninth voltage transfer electrode 243. The seventh bezel power connection electrode 337 may be connected to the tenth protrusion portion 242-2 of the eighth voltage transfer electrode 242. The eighth bezel power connection electrode 338 may be connected to another eleventh protrusion portion 243-2 of the ninth voltage transfer electrode 243.

In some examples, as shown in FIG. 34D, the anode layer of the first bezel region at least include: a plurality of bezel power connection electrodes (such as including a ninth bezel power connection electrode 371, a tenth bezel power connection electrode 372, an eleventh bezel power connection electrode 373, and a twelfth bezel power connection electrode 374). The ninth bezel power connection electrode 371, the tenth bezel power connection electrode 372, the eleventh bezel power connection electrode 373, and the twelfth bezel power connection electrode 374 may be arranged along the first direction X, and may be located on a side of the third power supply line 211 close to the display region. The ninth bezel power connection electrode 371 may be connected to the fifth bezel power connection electrode 335, the tenth bezel power connection electrode 372 may be connected to the sixth bezel power connection electrode 336, the eleventh bezel power connection electrode 373 may be connected to the seventh bezel power connection electrode 337, and the twelfth bezel power connection electrode 374 may be connected to the eighth bezel power connection electrode 338.

In some examples, as shown in FIG. 34A, the cathode layer of the display substrate may include a plurality of second power lines (e.g., including second power lines VSS1, VSS2, and VSS3). The cathode of the display region may be patterned as a plurality of strip patterns extending in the second direction Y, and each strip pattern may serve as a second power line. The second power line VSS1 may be connected to the ninth bezel power connection electrode 371 of the anode layer through a via provided on the pixel define layer, so as to be connected to the third power supply line 211 through the seventh voltage transfer electrode 241 to receive the second voltage signal Vss1. A second power line VSS3 may be connected to the tenth bezel power connection electrode 372 of the anode layer through a via provided on the pixel define layer, so as to be connected to the third power supply line 231 through the ninth voltage transfer electrode 243 to receive the second voltage signal Vss3. Another second power line VSS3 may be connected to the twelfth bezel power connection electrode 374 of the anode layer through a via provided on the pixel define layer, so as to be connected to the third power supply line 231 through the ninth voltage transfer electrode 243 to receive the second voltage signal Vss3. The second power line VSS2 may be connected to the eleventh bezel power connection electrode 373 of the anode layer through a via provided on the pixel define layer, so as to be connected to the third power supply line 221 through the eighth voltage transfer electrode 242 to receive the second voltage signal Vss2.

In this example, electrical connection between the second power supply line located in the cathode layer and the third power supply line located in the fifth conductive layer may be achieved by using the bezel power connection electrode located in the anode layer and the fifth conductive layer and the third-type voltage transfer electrode located in the fourth conductive layer. In other examples, when the cathode of the display region is patterned as a plurality of strip patterns extending in the first direction X, and each strip pattern serves as a second power line (in other words, when the second power line extends in the first direction X), the structure shown in FIG. 34A may be rotated 90 degrees, and the third power supply line may be adjusted to extend in the second direction Y, so that the second power line and the third power supply line are electrically connected in the second bezel region. The present embodiment is not limited thereto.

Regarding the wiring arrangement, width, and cross-line configuration within the second voltage supply group in this embodiment, reference may be made to the relevant content of the first voltage supply group in the aforementioned embodiments, which will not be reiterated here.

In other examples, the line segments of the fourth power supply lines of the three second voltage power supply groups provided in the first bezel region along the same extending direction may be different, for example, the embodiment shown in FIG. 26 may be referred to, and thus the description thereof will not be repeated here.

In other examples, the fourth power supply lines of the three second voltage power supply groups provided in the first bezel region may be arranged in different conductive layers, for example, the embodiment shown in FIG. 28 may be referred to, and thus the description thereof will not be repeated here.

In other examples, three different first voltage signals and three different second voltage signals may be provided by setting three first voltage power supply groups and three second voltage power supply groups in the first bezel region, so as to meet different requirements for the first voltage signal and the second voltage signal of three sub-pixel groups emitting light of different colors in the display region, and thereby achieving the purpose of saving power consumption of the first voltage signal and the second voltage signal.

The present embodiment further provides a display substrate, including a base substrate, a plurality of sub-pixels, a plurality of second power lines, and L second voltage power supply groups. The base substrate includes a display region and a first bezel region located on a side of the display region. A plurality of sub-pixels and a plurality of second power lines are located in the display region, the plurality of sub-pixels are divided into N sub-pixel groups, each sub-pixel group includes a plurality of sub-pixels emitting light of a same color, different sub-pixel groups are configured to emit light of different colors. At least one sub-pixel includes: a pixel circuit and a light emitting element connected to the pixel circuit. Each second power line is connected to the light emitting elements of the plurality of sub-pixels emitting light of the same color. L second voltage power supply groups are located in the first bezel region, the L second voltage power supply groups are configured to provide different second voltage signals. Each second voltage power supply group is configured to provide a second voltage signal to a light emitting element in at least one sub-pixel group through at least one second power line; wherein, L and N are both integers greater than 1, and L is less than or equal to N.

In some examples, the quantity of sub-pixel groups may be the same as the quantity of the second voltage power supply groups, i.e., L may be equal to N. Each second voltage power supply group may provide a second voltage signal to one sub-pixel group. Wherein, different sub-pixel groups receive different second voltage signals. In other examples, L may be less than N, and at least one second voltage power supply group may provide a first voltage signal to at least two sub-pixel groups. Wherein, the second voltage signals received by at least two sub-pixel groups may be the same. For example, one of the L second voltage power supply groups may be configured to provide the same second voltage signal to two sub-pixel groups.

However, the present embodiment is not limited thereto.

In some examples, each of the L second voltage power supply groups may be configured to provide a second voltage signal different from the remaining second voltage power supply groups. In other words, the L second voltage power supply groups may provide L different second voltage signals. In other examples, at least two of the L second voltage power supply groups may be configured to provide different second voltage signals. For example, the L second voltage power supply groups may be configured to provide L-1 different second voltage signals, two of the L second voltage power supply groups may provide the same second voltage signal, and the remaining second voltage power supply groups may be configured to provide different second voltage signals. The present embodiment is not limited thereto.

In some examples, the display region may include a plurality of second power lines, and each second power line may be connected to a light emitting element of a plurality of sub-pixels emitting light of the same color. For example, the light emitting element of the sub-pixel may include an anode and a cathode. The cathode of the light emitting element may be connected to the second power line. A plurality of light emitting elements in a sub-pixel group may be connected to a plurality of second power lines, and a second voltage power supply group may be configured to provide a second voltage signal to the light emitting elements in the sub-pixel group through the plurality of second power lines. In other examples, a plurality of light emitting elements in a sub-pixel group may be connected to a second power line, and a second voltage power supply group may be configured to provide a second voltage signal to the light emitting elements in the sub-pixel group through the second power line. The present embodiment is not limited thereto.

In this embodiment, three second voltage power supply groups are provided in the first bezel region to provide three different second voltage signals, and different requirements for the second voltage signals of three sub-pixel groups emitting different color lights in the display region may be met, thereby achieving the purpose of saving power consumption of the second voltage signal.

In some exemplary implementations, N sub-pixel groups may include: a first sub-pixel group emitting light of a first color, a second sub-pixel group emitting light of a second color, and a third sub-pixel group emitting light of a third color. The L second voltage power supply groups may include: a first second voltage power supply group providing a first type of second voltage signal, a second second voltage power supply group providing a second type of second voltage signal, and a third second voltage power supply group providing a third type of second voltage signal. The first second voltage power supply group is configured to provide a first type of second voltage signal to the first sub-pixel group. The second second voltage power supply group is configured to provide a second type of second voltage signal to the second sub-pixel group. The third second voltage power supply group is configured to provide a third type of second voltage signal to the third sub-pixel group. However, the present embodiment is not limited thereto. In other examples, the quantity of sub-pixel groups may be three, the quantity of second voltage power supply groups may be two. A first second voltage power supply group may be configured to provide a first type of second voltage signal to a first sub-pixel group (e.g. including blue sub-pixels), and a second second voltage power supply group may be configured to provide a second type of second voltage signal to a second sub-pixel group (e.g. including red sub-pixels) and a third sub-pixel group (e.g. including green sub-pixels). In this example, grouping control of the RGB brightness may be achieved through the grouping design of the second voltage signal, so as to achieve the purpose of saving power consumption of the second voltage signal.

In some exemplary embodiments, the first color light may be blue light, the second color light may be red light, and the third color light may be green light. The first type of second voltage signal may be less than the second type of second voltage signal, and the second type of second voltage signal may be less than the third type of second voltage signal.

Remaining description of the display substrate in this example may be referred to the description in the aforementioned embodiments, which is not repeated here.

FIG. 35 is a schematic diagram of a display apparatus according to at least one embodiment of the present disclosure. As shown in FIG. 35, the embodiment provides a display apparatus 91 including a display substrate 910 of the aforementioned embodiments. In some examples, the display substrate 910 may be a flexible OLED display substrate, a QLED display substrate, a Micro-LED display substrate, or a Mini-LED display substrate. The display apparatus may be a product capable of displaying images (including static images or dynamic images, wherein dynamic images may be video). For example, the display apparatus may be any one of a display, a television, a billboard, a digital photo frame, a laser printer with display function, a telephone, a mobile phone, a picture screen, a personal digital assistant (PDA), a digital camera, a portable camcorder, a viewfinder, a navigator, a vehicle, a large-area wall, an information inquiry equipment (such as e-government, business inquiry equipment in departments of banks, hospitals, power), a monitor, or the like. For another example, the display apparatus may be any one product of a micro-display, a Virtual Reality (VR) device or an Augmented Reality (AR) device including a micro-display.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. It should be noted that the above examples or embodiments are exemplary only but not restrictive. Therefore, the present disclosure is not limited to what is specifically shown and described herein. Various modifications, substitutions, or omissions may be made in forms and details of implementations without departing from the scope of the present disclosure.

1. A display substrate, comprising:
a base substrate, comprising a display region and a first bezel region located at a side of the display region;
a plurality of sub-pixels and a plurality of first power lines, located in the display region, the plurality of sub-pixels are divided into N sub-pixel groups, each sub-pixel group comprises a plurality of sub-pixels emitting light of a same color, different sub-pixel groups are configured to emit light of different colors, at least one of the plurality of sub-pixels comprises: a pixel circuit and a light emitting element connected to the pixel circuit, each first power line is connected to pixel circuits of the plurality of sub-pixels emitting light of the same color; and
M first voltage power supply groups, located in the first bezel region, the M first voltage power supply groups are configured to provide different first voltage signals; and each first voltage power supply group is configured to provide a first voltage signal to the pixel circuit in at least one sub-pixel group through at least one first power line, wherein M and N are both integers greater than 1, and M is less than or equal to N.

2. The display substrate according to claim 1, wherein the first bezel region comprises: a first fan-out region and a first signal access region disposed sequentially along a direction away from the display region; and
each first voltage power supply group at least comprises: at least one first power supply line located in the first fan-out region and at least one first voltage contact pad located in the first signal access region; and the at least one first power supply line is connected to the at least one first voltage contact pad.

3. The display substrate according to claim 2, wherein the first bezel region further comprises: a second fan-out region and a bend region, the second fan-out region and the bend region are located on a side of the first fan-out region close to the display region, and the bend region is connected to the first fan-out region and the second fan-out region; and
each first voltage power supply group further comprises: at least one second power supply line located in the second fan-out region, at least one first power supply bend line located in the bend region; the at least one second power supply line is connected to a plurality of first power lines that transmit a same first voltage signal, and the at least one first power supply bend line is connected to the at least one first power supply line and the at least one second power supply line.

4. The display substrate according to claim 3, wherein the second power supply line is extended at least along a first direction, the first power supply bend line is extended at least along a second direction, the first power line is extended at least along the second direction, and the first direction is intersected with the second direction; the at least one first power supply line is disposed symmetrically with respect to a centerline of the first bezel region along the first direction.

5. The display substrate according to claim 3, wherein the second power supply line is connected to the plurality of first power lines through a first-type voltage transfer electrode, and the at least one first power supply bend line is connected to the second power supply line and the plurality of first power lines through a second-type voltage transfer electrode; wherein the first-type voltage transfer electrode and the second-type voltage transfer electrode are in a same layer.

6. The display substrate according to claim 2, wherein a distance between orthographic projections of first power supply lines of at least two of the M first voltage power supply groups is greater than 0, and the first power supply lines comprise at least two lines connected to each other.

7. The display substrate according to claim 6, wherein in a direction perpendicular to the display substrate, the display substrate comprises: a first semiconductor layer, a first gate metal layer, a second gate metal layer, a second semiconductor layer, a third gate metal layer, a first source-drain metal layer, a second source-drain metal layer, and a third source-drain metal layer disposed on the base substrate; and
the first power supply line of at least one of the M first voltage power supply groups comprises lines located at at least two metal layers of the first source-drain metal layer, the second source-drain metal layer, and the third source-drain metal layer.

8. The display substrate according to claim 2, wherein first power supply lines of different first voltage power supply groups are located on different conductive layers, and orthographic projections of the first power supply lines of at least two first voltage power supply groups on the base substrate are partially overlapped-; or
wherein line segments of first power supply lines of the M first voltage power supply groups in a same extending direction have a same width; or
wherein line segments of first power supply lines of at least two adjacent first voltage power supply groups in a same extending direction have different widths.

9-10. (canceled)

11. The display substrate according to claim 1, wherein the N sub-pixel groups comprise: a first sub-pixel group emitting light of a first color, a second sub-pixel group emitting light of a second color, and a third sub-pixel group emitting light of a third color;
the M first voltage power supply groups comprise: a first first voltage power supply group providing a first type of first voltage signal, a second first voltage power supply group providing a second type of first voltage signal, and a third first voltage power supply group providing a third type of first voltage signal;
the first first voltage power supply group is configured to provide a first type of first voltage signal to the first sub-pixel group;
the second first voltage power supply group is configured to provide a second type of first voltage signal to the second sub-pixel group; and
the third first voltage power supply group is configured to provide a third type of first voltage signal to the third sub-pixel group.

12. The display substrate according to claim 11, wherein the light of the first color is blue light, the light of the second color is red light, and the light of the third color is green light; the first type of first voltage signal is greater than the second type of first voltage signal, and the second type of first voltage signal is greater than the third type of first voltage signal.

13. The display substrate according to claim 11, further comprising: a bottom shield layer connected to the first first voltage power supply group.

14. The display substrate according to claim 11, wherein the first bezel region comprises: a first fan-out region and a first signal access region disposed sequentially along a direction away from the display region;
each first voltage power supply group at least comprises: at least one first power supply line located in the first fan-out region and at least one first voltage contact pad located in the first signal access region; and the at least one first power supply line is connected to the at least one first voltage contact pad; and
an average width of first power supply lines of the first first voltage power supply group is greater than an average width of first power supply lines of the second first voltage power supply group; and the average width of the first power supply lines of the second first voltage power supply group is greater than an average width of first power supply lines of the third first voltage power supply group.

15. The display substrate according to claim 11, wherein the first bezel region comprises: a first fan-out region and a first signal access region disposed sequentially along a direction away from the display region;
each first voltage power supply group at least comprises: at least one first power supply line located in the first fan-out region and at least one first voltage contact pad located in the first signal access region; and the at least one first power supply line is connected to the at least one first voltage contact pad; and
the first power supply line of the first first voltage power supply group, the first power supply line of the second first voltage power supply group, and the first power supply line of the third first voltage power supply group are single-layer lines, and orthographic projections of the first power supply line of the first first voltage power supply group, the first power supply line of the second first voltage power supply group, and the first power supply line of the third first voltage power supply group on the base substrate are partially overlapped.

16. The display substrate according to claim 15, wherein in a direction perpendicular to the display substrate, the display substrate comprises at least: a first source-drain metal layer, a second source-drain metal layer, and a third source-drain metal layer disposed on the base substrate; the first power supply line of the first first voltage power supply group is located in the first source-drain metal layer, the first power supply line of the second first voltage power supply group is located in the second source-drain metal layer, and the first power supply line of the third first voltage power supply group is located in the third source-drain metal layer.

17. The display substrate according to claim 1, further comprising: L second voltage power supply groups located in the first bezel region, the L second voltage power supply groups are configured to provide different second voltage signals, each second voltage power supply group is configured to provide a second voltage signal to a light emitting element in at least one sub-pixel group, wherein L is an integer greater than 1 and L is less than or equal to N; and the second voltage signal is different from the first voltage signal.

18. The display substrate according to claim 17, wherein the N sub-pixel groups comprise: a first sub-pixel group emitting light of a first color, a second sub-pixel group emitting light of a second color, and a third sub-pixel group emitting light of a third color;
the L second voltage power supply groups comprise: a first second voltage power supply group providing a first type of second voltage signal, a second second voltage power supply group providing a second type of second voltage signal, and a third second voltage power supply group providing a third type of second voltage signal;
the first second voltage power supply group is configured to provide a first type of second voltage signal to the first sub-pixel group;
the second second voltage power supply group is configured to provide a second type of second voltage signal to the second sub-pixel group; and
the third second voltage power supply group is configured to provide a third type of second voltage signal to the third sub-pixel group.

19. The display substrate according to claim 18, wherein the light of the first color is blue light, the light of the second color is red light, and the light of the third color is green light; the first type of second voltage signal is less than the second type of second voltage signal, and the second type of second voltage signal is less than the third type of second voltage signal.

20. The display substrate according to claim 17, wherein the light emitting element comprises an anode and a cathode; cathodes of a plurality of light emitting elements emitting light of a same color are connected to each other and are connected to a second voltage power supply group through at least a third-type voltage transfer electrode.

21. A display apparatus, comprising a display substrate of claim 1.

22. A display substrate, comprising:
a base substrate, comprising a display region and a first bezel region located at a side of the display region;
a plurality of sub-pixels and a plurality of second power lines located in the display region, the plurality of sub-pixels are divided into N sub-pixel groups, each sub-pixel group comprises a plurality of sub-pixels emitting light of a same color, different sub-pixel groups are configured to emit light of different colors, at least one of the plurality of sub-pixels comprises: a pixel circuit and a light emitting element connected to the pixel circuit, each second power line is connected to light emitting elements of the plurality of sub-pixels emitting light of the same color; and
L second voltage power supply groups located in the first bezel region, the L second voltage power supply groups are configured to provide different second voltage signals, each second voltage power supply group is configured to provide a second voltage signal to the light emitting element in at least one sub-pixel group through at least one second power line; wherein, L and N are both integers greater than 1, and L is less than or equal to N.

23-24. (canceled)
